(19) United States
(12) Patent Application Publication
(10) Pub. No.: US 2008/0305429 A1
(43) Pub. Date: Dec. 11, 2008

(54) RESIST COMPOSITION AND PATTERN FORMING METHOD USING THE RESIST COMPOSITION

(75) Inventors: Hiroshi SAEGUSA, Haibara-gun (JP); Kenji WADA, Haibara-gun (JP)

Correspondence Address: SUGHRUE-265550, 2100 PENNSYLVANIA AVE. NW, WASHINGTON, DC, 20037-3213, US

(73) Assignee: FUJIFILM CORPORATION, Tokyo (JP)

(21) Appl. No.: 12/135,578

(22) Filed: Jun. 9, 2008

(30) Foreign Application Priority Data
Jun. 8, 2007 (JP) 2007-152804

(51) Int. Cl. G03F 7/20; G03F 7/004

(52) U.S. Cl. 430/270.1; 430/322

(57) ABSTRACT

A resist composition, includes: (A) a resin of which solubility in an alkali developer increases under an action of an acid; (B) a compound capable of generating an acid upon irradiation with actinic rays or radiation; (C) a hydrophobic resin; and (D) a solvent, wherein a difference between a weight average molecular weight of the resin (A) and a weight average molecular weight of the hydrophobic resin (C) satisfies the following formula: weight average molecular weight of resin (A)−weight average molecular weight of hydrophobic resin (C)≧about 3,000; and a pattern forming method uses the resist composition.

### BACKGROUND OF THE INVENTION

1. Field of the Invention

The present invention relates to a resist composition for use in the production process of a semiconductor such as IC, in the production of a circuit substrate of liquid crystal, thermal head or the like, and in the lithography process of other photo-fabrications, and a pattern forming method using the resist composition. More specifically, the present invention relates to a resist composition suitable for exposure by an immersion-type projection exposure apparatus using a light source of emitting far ultraviolet light at a wavelength of 300 nm or less, and a pattern forming method using the resist composition.

2. Description of the Related Art

With the miniaturization of semiconductor devices, the trend is moving into shorter wavelength of the exposure light source and higher numerical aperture (high NA) of the projection lens. At present, an exposure machine with NA of 0.84 has been developed, where an ArF excimer laser having a wavelength of 193 nm is used as the light source. As commonly well known, these can be expressed by the following formulae:

(Resolving power)=k₁·(λ/NA)

(Focal depth)=±k₂·λ/NA²

wherein λ is the wavelength of the exposure light source, NA is the numerical aperture of the projection lens, and k₁ and k₂ are constants related to the process.

Conventionally, a so-called immersion method of filling a high refractive-index liquid (hereinafter sometimes referred to as an “immersion liquid”) between the projection lens and the sample has been known as a technique of increasing the resolving power in an optical microscope.

As for the “effect of immersion”, assuming that NA₀=sin θ, the above-described resolving power and focal depth when immersed can be expressed by the following formulae:

(Resolving power)=k₁·(λ₀/n)/NA₀

(Focal depth)=±k₂·(λ₀/n)/NA₀²

wherein λ₀ is the wavelength of exposure light in air, n is the refractive index of the immersion liquid to air, and θ is the convergence half-angle of beam.

That is, the effect of immersion is equal to use of an exposure wavelength of 1/n. In other words, in the case of a projection optical system with the same NA, the focal depth can be made n times larger by the immersion. This is effective for all pattern profiles and can be combined with a super-resolution technique such as phase-shift method and modified illumination method which are being studied at present.

Examples of the apparatus where this effect is applied to the transfer of a fine image pattern of a semiconductor device are described in JP-A-57-153433 (the term “JP-A” as used herein means an “unexamined published Japanese patent application”) and JP-A-7-220990.

Recent progress of the immersion exposure technique is reported, for example, in SPIE Proc., 4688, 11 (2002), J. Vac. Sci. Tecnol. B, 17 (1999), SPIE Proc., 3999, 2 (2000) and JP-A-10-303 114. In the case of using an ArF excimer laser as the light source, in view of safety on handling as well as transmittance and refractive index at 193 nm, pure water (refractive index at 193 nm: 1.44) is considered to be a most promising immersion liquid.

Since the advent of a resist for a KrF excimer laser (248 nm), an image forming method called chemical amplification is used as the image forming method for a resist so as to compensate the reduction in the sensitivity due to light absorption. This image forming method is, for example, in the case of using positive chemical amplification, an image forming method where an acid generator in the exposed area decomposes upon exposure to generate an acid, the acid generated is used as a reaction catalyst in the baking after exposure (PEB: post exposure bake) to convert the alkali-insoluble group into an alkali-soluble group, and the exposed area is removed by an alkali developer.

A resist for an ArF excimer laser (wavelength: 193 nm) using this chemical amplification mechanism is becoming mainstream at present, but there are still insufficient points, and an improvement of the performance in terms of resist pattern collapse is demanded.

Also, it is pointed out that when the chemical amplification resist is applied to immersion exposure, the resist layer comes into contact with the immersion liquid at the exposure and this brings out deterioration of the resist layer or allows a component adversely affecting the immersion liquid to bleed out from the resist layer. International Publication WO2004-068242, pamphlet describes a case where when the resist for ArF exposure is dipped in water before and after exposure, the resist performance is changed, which is indicated as a problem in the immersion exposure.

Furthermore, in the immersion exposure process, when exposure is performed using a scan-type immersion exposure machine, unless the immersion liquid moves following the movement of lens, the exposure speed decreases and this may affect the productivity. In the case where the immersion liquid is water, the resist film is preferably hydrophobic because of good followability of water, but when the resist film is hydrophobed, there may arise an adverse effect on the image performance of the resist, such as increase of scum generation, and an improvement is demanded.

### SUMMARY OF THE INVENTION

An object of the present invention is to provide a resist composition ensuring less profile deterioration, improved pattern collapse and suppressed scum generation not only in normal exposure (dry exposure) but also in immersion exposure, and a pattern forming method using the resist composition.

The present invention provides a resist composition having the following constructions and a pattern forming method using the resist composition. The above-described object of the present invention can be attained by these resist composition and pattern forming method.

(1) A resist composition, comprising:

(A) a resin of which solubility in an alkali developer increases under an action of an acid;

(B) a compound capable of generating an acid upon irradiation with actinic rays or radiation;

(C) a hydrophobic resin; and

(D) a solvent,

wherein a difference between a weight average molecular weight of the resin (A) and a weight average molecular weight of the hydrophobic resin (C) satisfies the following formula:

weight average molecular weight of resin (A)−weight average molecular weight of hydrophobic resin (C)≧about 3,000.

(2) The resist composition as described in (1) above,

wherein the hydrophobic resin (C) has at least one of a fluorine atom and a silicon atom.

(3) The resist composition as described in (1) or (2) above,

wherein the difference between the weight average molecular weight of the resin (A) and the weight average molecular weight of the hydrophobic resin (C) satisfies the following formula:

weight average molecular weight of resin (A)−weight average molecular weight of hydrophobic resin (C)≧about 4,000.

(4) The resist composition as described in any of (1) to (3) above,

wherein the difference between the weight average molecular weight of the resin (A) and the weight average molecular weight of the hydrophobic resin (C) satisfies the following formula:

weight average molecular weight of resin (A)−weight average molecular weight of hydrophobic resin (C)≧about 5,000.

(5) The resist composition as described in any of (1) to (4) above,

wherein the hydrophobic resin (C) has a group represented by formula (F3a):

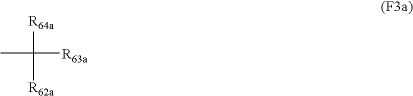

wherein R₆₂ₐ and R₆₃ₐ each independently represents an alkyl group with at least one hydrogen atom being substituted by a fluorine atom, and R₆₂ₐ and R₆₃ₐ may combine with each other to form a ring; and

R₆₄ₐ represents a hydrogen atom, a fluorine atom or an alkyl group.

(6) The resist composition as described in (5) above,

wherein the hydrophobic resin (C) contains a repeating unit including an acrylate or methacrylate having a group represented by formula (F3a).

(7) The resist composition as described in any of (1) to (4) above,

wherein the hydrophobic resin (C) has a group represented by any one of formulae (CS-1) to (CS-3):

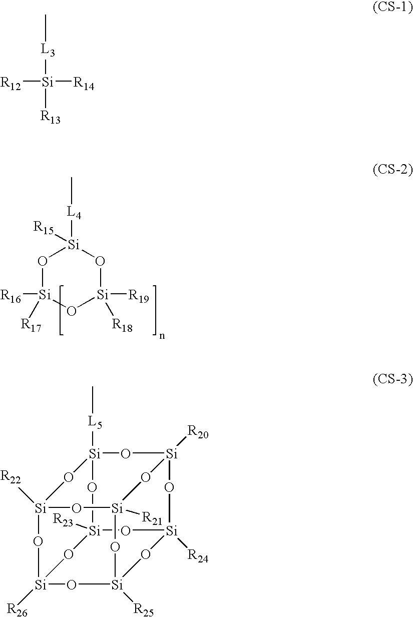

wherein R₁₂ to R₂₆ each independently represents an alkyl group or a cycloalkyl group;

L₃ to L₅ each independently represents a single bond or a divalent linking group; and

n represents an integer of 1 to 5.

(8) The resist composition as described in any of (1) to (4) above,

wherein the hydrophobic resin (C) is any one resin selected from the group consisting of the following resins (C-1) to (C-6):

(C-1) a resin containing (a) a repeating unit having a fluoroalkyl group;

(C-2) a resin containing (b) a repeating unit having a trialkylsilyl group or a cyclic siloxane structure;

(C-3) a resin containing (a) a repeating unit having a fluoroalkyl group and (c) a repeating unit having a branched alkyl group, a cycloalkyl group, a branched alkenyl group, a cycloalkenyl group or an aryl group;

(C-4) a resin containing (b) a repeating unit having a trialkylsilyl group or a cyclic siloxane structure and (c) a repeating unit having a branched alkyl group, a cycloalkyl group, a branched alkenyl group, a cycloalkenyl group or an aryl group;

(C-5) a resin containing (a) a repeating unit having a fluoroalkyl group and (b) a repeating unit having a trialkylsilyl group or a cyclic siloxane structure; and

(C-6) a resin containing (a) a repeating unit having a fluoroalkyl group, (b) a repeating unit having a trialkylsilyl group or a cyclic siloxane structure and (c) a repeating unit having a branched alkyl group, a cycloalkyl group, a branched alkenyl group, a cycloalkenyl group or an aryl group.

(9) The resist composition as described in any of (1) to (4) above,

wherein the hydrophobic resin (C) has a repeating unit represented by formula (Ia):

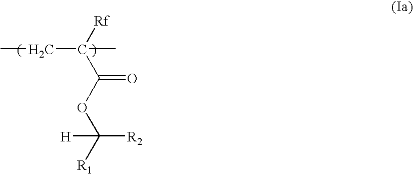

wherein Rf represents a fluorine atom or an alkyl group with at least one hydrogen atom being substituted by a fluorine atom;

R₁ represents an alkyl group; and

R₂ represents a hydrogen atom or an alkyl group.

(10) The resist composition as described in any of (1) to (4) above,

wherein the hydrophobic resin (C) has a repeating unit represented by formula (II) and a repeating unit represented by formula (III):

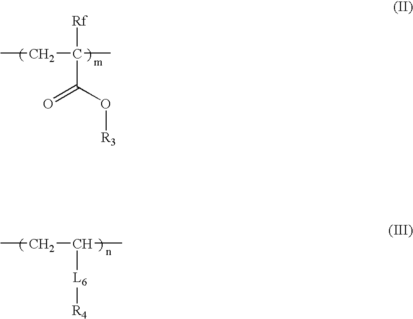

wherein Rf represents a fluorine atom or an alkyl group with at least one hydrogen atom being substituted by a fluorine atom;

R₃ represents an alkyl group, a cycloalkyl group, an alkenyl group or a cycloalkenyl group;

R₄ represents an all group, a cycloalkyl group, an alkenyl group, a cycloalkenyl group, a trialkylsilyl group or a group having a cyclic siloxane structure;

L₆ represents a single bond or a divalent linking group; and

m and n define ratio of repeating units and represent numerals of 0<m<100 and 0<n<100.

(11) A pattern forming method, comprising:

forming a resist film from the resist composition as described in any of (1) to (10) above; and

exposing and developing the resist film.

Preferred embodiments of the present invention are further set forth below.

(12) The resist composition as described in any of (1) to (10) above,

wherein the hydrophobic resin (C) contains a repeating unit having an alkali-soluble group or a group of which solubility in a developer increases under an action of an acid or alkali, and

a total amount of the repeating unit having an alkali-soluble group or a group of which solubility in a developer increases under an action of an acid or an alkali is 20 mol % or less based on all repeating units constituting the hydrophobic resin (C).

(13) The resist composition as described in any of (1) to (10) and (12) above,

wherein when the resist composition is formed into a film, a receding contact angle of water for the film is 70° or more.

(14) The resist composition as described in any of (1) to (10), (12) and (13) above,

wherein an amount of the hydrophobic resin (C) added is from 0.1 to 5 mass % based on the entire solid content in the resist composition.

(15) The resist composition as described in any of (1) to (10) and (12) to (14) above, which further comprises: (E) a basic compound.

(16) The resist composition as described in any of (1) to (10) and (12) to (15) above, which further comprises: (F) at least one of a fluorine-containing surfactant and a silicon-containing surfactant.

(17) The resist composition as described in any one of (1) to (10) and (12) to (16) above,

wherein the solvent (D) is a mixed solvent of two or more species including propylene glycol monomethyl ether acetate.

(18) The resist composition for immersion exposure as described in any of (1) to (10) and (12) to (17) above,

wherein the resin (A) contains a repeating unit having an alicyclic structure which leaves under an action of an acid.

(19) The resist composition for immersion exposure as described in any of (1) to (10) and (12) to (18) above,

wherein the resin (A) contains a repeating unit having a lactone structure.

(20) The resist composition as described in any of (1) to (10) and (12) to (17) above,

wherein the resin (A) is a copolymer containing at least three kinds of repeating units consisting of: a (meth)acrylate-based repeating unit having a lactone ring; a (meth)acrylate-based repeating unit having an organic group substituted by at least one of a hydroxyl group and a cyano group; and a (meth)acrylate-based repeating unit having an acid-decomposable group.

(21) The resist composition as described in any of (1) to (10) and (12) to (20) above,

wherein the weight average molecular weight of the resin (A) is from 5,000 to 10,000 and a dispersity of the resin (A) is from 1.2 to 2.0.

(22) The resist composition as described in any of (1) to (10) and (12) to (21) above,

wherein the compound (B) is a compound capable of generating a fluorine atom-containing aliphatic sulfonic acid or a fluorine atom-containing benzenesulfonic acid upon irradiation with actinic rays or radiation.

(23) The resist composition as described in any of (1) to (10) and (12) to (22) above,

wherein the compound (B) has a triphenylsulfonium structure.

(24) The resist composition as described in (23),

wherein the compound (B) is a triphenylsulfonium salt compound having a non-fluorine-substituted alkyl or cycloalkyl group in a cation moiety.

(25) The resist composition as described in any of (1) to (10) and (12) to (24) above,

wherein the entire solid content concentration in the resist composition is from 1.0 to 6.0 mass %.

(26) The resist composition as described in any of (1) to (10) and (12) to (25) above,

wherein the resin (A) does not have a fluorine atom and a silicon atom.

(27) The pattern forming method as described in (11) above,

wherein the exposure is performed by exposure to light at a wavelength of 1 to 200 nm.

(28) The pattern forming method as described in (11) or (27) above, which comprises: an immersion exposure step.

### DETAILED DESCRIPTION OF THE INVENTION

The present invention is described in detail below.

In the present invention, when a group (atomic group) is denoted without specifying whether substituted or unsubstituted, the group includes both a group having no substituent and a group having a substituent. For example, an “alkyl group” includes not only an alkyl group having no substituent (unsubstituted alkyl group) but also an alkyl group having a substituent (substituted alkyl group).

(A) Resin of which Solubility in an Alkali Developer Increases under the Action of an Acid

The resin for use in the positive resist composition of the present invention is a resin which decomposes under the action of an acid to increase the solubility in an alkali developer, and this is a resin having a group capable of decomposing under the action of an acid to produce an alkali-soluble group (hereinafter sometimes referred to as an “acid-decomposable group”) in the main or side chain or both the main and side chains of the resin (sometimes referred to as an “acid-decomposable resin”, an “acid-decomposable resin (A)” or a “resin (A)”).

Examples of the alkali-soluble group include groups having a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)-imide group, a tris(alkylcarbonyl)methylene group or a tris(alkylsulfonyl)methylene group.

Among these alkali-soluble groups, preferred are a carboxylic acid group, a fluorinated alcohol group (preferably hexafluoroisopropanol) and a sulfonic acid group.

The group capable of decomposing under the action of an acid (acid-decomposable group) is preferably a group obtained by replacing a hydrogen atom of such an alkali-soluble group with a group which leaves by the effect of an acid.

Examples of the group which leaves by the effect of an acid include —C(R₃₆)(R₃₇)(R₃₈), —C(R₃₆)(R₃₇)(OR₃₉) and —C(R₀₁)(R₀₂)(OR₃₉).

In the formulae, R₃₆ to R₃₉ each independently represents an alkyl group, a cycloalkyl group, an aryl group, an aralkyl group or an alkenyl group, and R₃₆ and R₃₇ may combine with each other to form a ring.

R₀₁ and R₀₂ each independently represents a hydrogen atom, an alkyl group, a cycloalkyl group, an aryl group, an aralkyl group or an alkenyl group.

Preferred examples of the acid-decomposable group include a cumyl ester group, an enol ester group, an acetal ester group and a tertiary alkyl ester group, with a tertiary alkyl ester group being more preferred.

In the case of irradiating ArF excimer laser light on the positive resist composition of the present invention, the acid-decomposable resin is preferably a resin having a monocyclic or polycyclic alicyclic hydrocarbon structure and being capable of decomposing under the action of an acid to increase the solubility in an alkali developer.

The resin having a monocyclic or polycyclic alicyclic hydrocarbon structure and being capable of decomposing under the action of an acid to increase the solubility in an alkali developer (hereinafter sometimes referred to as an “alicyclic hydrocarbon-based acid-decomposable resin”) is preferably a resin containing at least one repeating unit selected from the group consisting of a repeating unit having an alicyclic hydrocarbon-containing partial structure represented by any one of the following formulae (pI) to (pV) and a repeating unit represented by the following formula (II-AB):

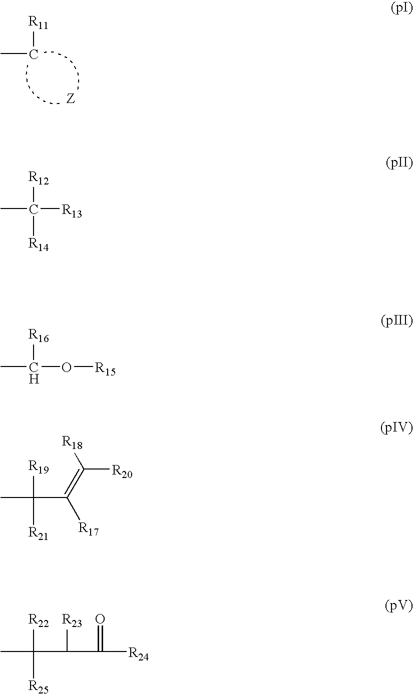

In formulae (pI) to (pV), R₁₁ represents a methyl group, an ethyl group, an n-propyl group, an isopropyl group, an n-butyl group, an isobutyl group or a sec-butyl group. Z represents an atomic group necessary for forming a cycloalkyl group together with the carbon atom.

R₁₂ to R₁₆ each independently represents a linear or branched alkyl group having a carbon number of 1 to 4 or a cycloalkyl group, provided that at least one of R₁₂ to R₁₄ or either one of R₁₅ and R₁₆ represents a cycloalkyl group.

R₁₇ to R₂₁ each independently represents a hydrogen atom, a linear or branched alkyl group having a carbon number of 1 to 4 or a cycloalkyl group, provided that at least one of R₁₇ to R₂₁ represents a cycloalkyl group and that either one of R₁₉ and R₂₁ represents a linear or branched alkyl group having a carbon number of 1 to 4 or a cycloalkyl group.

R₂₂ to R₂₅ each independently represents a hydrogen atom, a linear or branched alkyl group having a carbon number of 1 to 4 or a cycloalkyl group, provided that at least one of R₂₂ to R₂₅ represents a cycloalkyl group. R₂₃ and R₂₄ may combine with each other to form a ring.

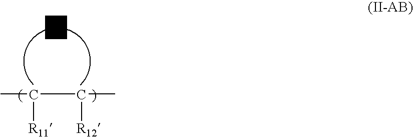

In formula (II-AB), R₁₁′ and R₁₂′ each independently represents a hydrogen atom, a cyano group, a halogen atom or an alkyl group.

Z′ represents an atomic group for forming an alicyclic structure, containing two bonded carbon atoms (C—C).

Formula (II-AB) is preferably the following formula (II-AB1) or (II-AB2):

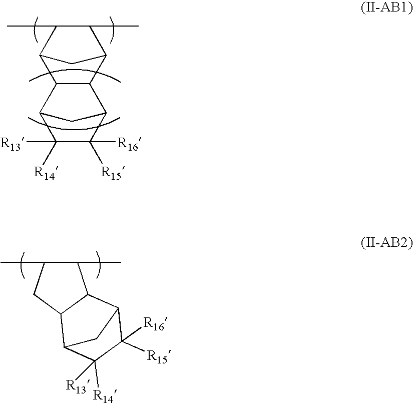

In formulae (II-AB1) and (II-AB2), R₁₃′ to R₁₆′ each independently represents a hydrogen atom, a halogen atom, a cyano group, —COOH, —COOR₅, a group capable of decomposing under the action of an acid, —C(═O)—X-A′-R₁₇′, an alkyl group or a cycloalkyl group, and at least two members out of R₁₃′ to R₁₆′ may combine to form a ring.

R₅ represents an alkyl group, a cycloalkyl group or a group having a lactone structure.

X represents an oxygen atom, a sulfur atom, —NH—, —NHSO₂— or —NHSO₂NH—.

A′ represents a single bond or a divalent linking group.

R₁₇′ represents —COOH, —COOR₅, —CN, a hydroxyl group, an alkoxy group, —CO—NH—R₆, —CO—NH—SO₂—R₆ or a group having a lactone structure.

R₆ represents an alkyl group or a cycloalkyl group.

n represents 0 or 1.

In formulae (pI) to (pV), the alkyl group of R₁₂ to R₂₅ is a linear or branched alkyl group having a carbon number of 1 to 4.

The cycloalkyl group of R₁₁ to R₂₅ and the cycloalkyl group formed by Z together with the carbon atom may be monocyclic or polycyclic. Specific examples thereof include a group having a carbon number of 5 or more and having a monocyclo, bicyclo, tricyclo or tetracyclo structure. The carbon number thereof is preferably from 6 to 30, more preferably from 7 to 25. These cycloalkyl groups each may have a substituent.

Preferred examples of the cycloalkyl group include an adamantyl group, a noradamantyl group, a decalin residue, a tricyclodecanyl group, a tetracyclododecanyl group, a norbornyl group, a cedrol group, a cyclopentyl group, a cyclohexyl group, a cycloheptyl group, a cyclooctyl group, a cyclodecanyl group and a cyclododecanyl group. Among these, more preferred are an adamantyl group, a norbornyl group, a cyclohexyl group, a cyclopentyl group, a tetracyclododecanyl group and a tricyclodecanyl group.

Examples of the substituent which these alkyl group and cycloalkyl group may further have include an alkyl group (having a carbon number of 1 to 4), a halogen atom, a hydroxyl group, an alkoxy group (having a carbon number of 1 to 4), a carboxyl group and an alkoxycarbonyl group (having a carbon number of 2 to 6). Examples of the substituent which these alkyl group, alkoxy group, alkoxycarbonyl group and the like may further have include a hydroxyl group, a halogen atom and an alkoxy group.

The structures represented by formulae (pI) to (pV) each can be used for the protection of an alkali-soluble group in the resin. Examples of the alkali-soluble group include various groups known in this technical field.

Specific examples thereof include a structure where the hydrogen atom of a carboxylic acid group, a sulfonic acid group, a phenol group or a thiol group is substituted by the structure represented by any one of formulae (pI) to (pV). Among these, preferred is a structure where the hydrogen atom of a carboxylic acid group or a sulfonic acid group is substituted by the structure represented by any one of formulae (pI) to (pV).

The repeating unit having an alkali-soluble group protected by the structure represented by any one of formulae (pI) to (pV) is preferably a repeating unit represented by the following formula (pA):

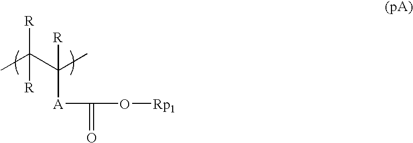

In the formula, R represents a hydrogen atom, a halogen atom or a linear or branched alkyl group having a carbon number of 1 to 4, and a plurality of R's may be the same or different.

A represents a single bond, or a sole group or a combination of two or more groups, selected from the group consisting of an alkylene group, an ether group, a thioether group, a carbonyl group, an ester group, an amido group, a sulfonamido group, a urethane group and a ureylene group. A is preferably a single bond.

Rp₁ represents any one group of formulae (pI) to (pV).

The repeating unit represented by formula (pA) is preferably a repeating unit comprising a 2-alkyl-2-adamantyl (meth)acrylate or a dialkyl(1-adamantyl)methyl (meth)acrylate.

Specific examples of the repeating unit having an acid-decomposable group are set forth below, but the present invention is not limited thereto.

(In the formulae Rx represents H, CH₃ or CH₂OH, and Rxa and Rxa each represents an alkyl group having a carbon number of 1 to 4.)

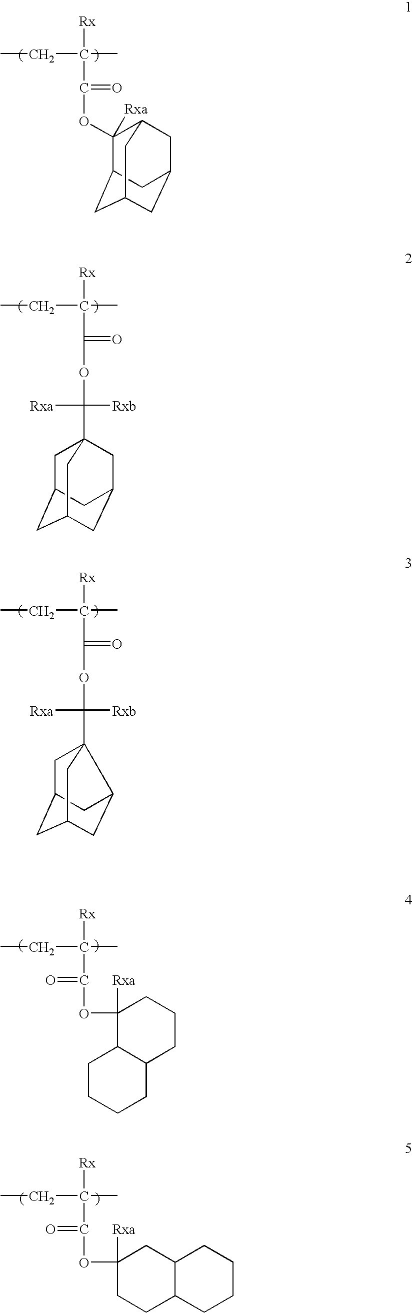

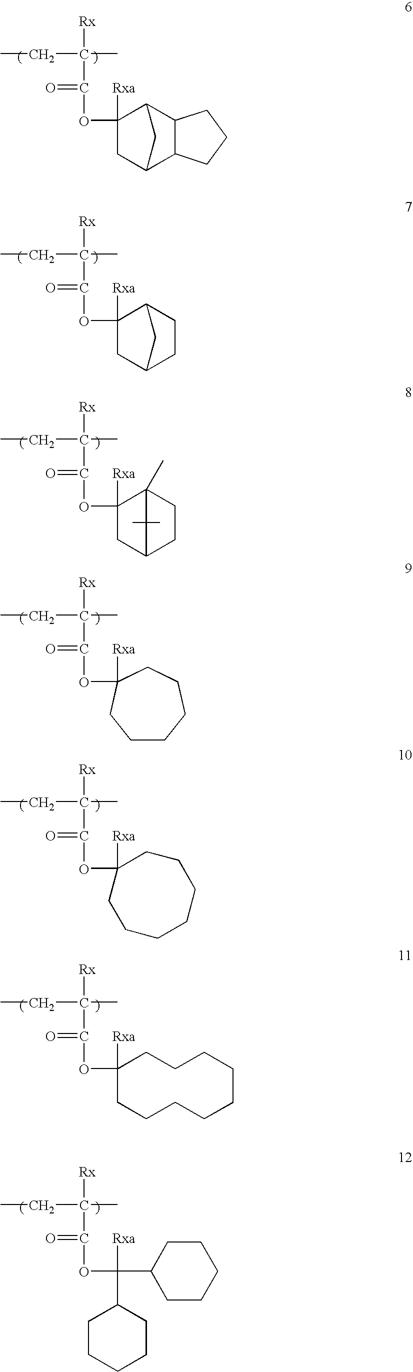

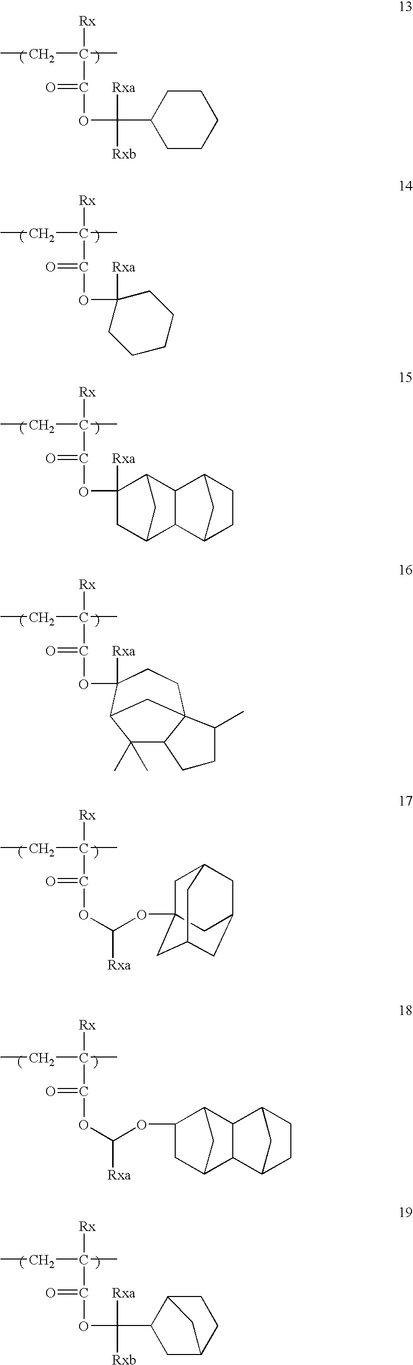

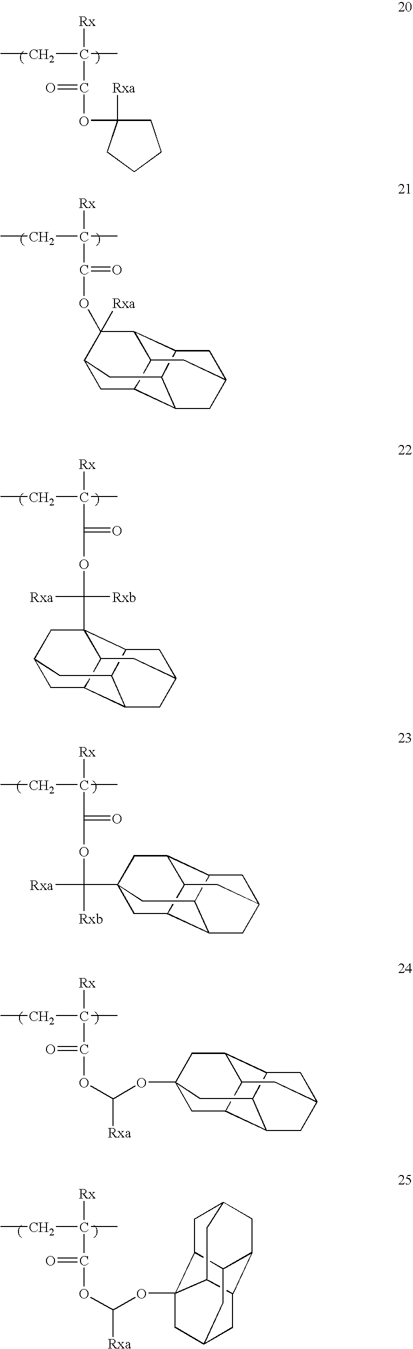

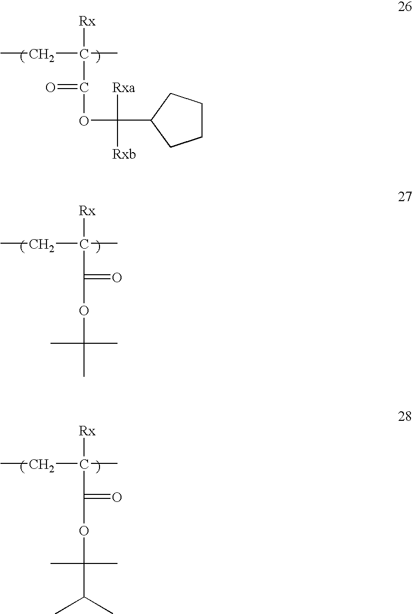

Examples of the halogen atom of R₁₁′ and R₁₂′ in formula (II-AB) include a chlorine atom, a bromine atom, a fluorine atom and an iodine atom.

The alkyl group of R₁₁′ and R₁₂′ includes a linear or branched alkyl group having a carbon number of 1 to 10.

The atomic group of Z′ for forming an alicyclic structure is an atomic group for forming, in the resin, an alicyclic hydrocarbon repeating unit which may have a substituent. In particular, an atomic group for forming a crosslinked alicyclic structure to form a crosslinked alicyclic hydrocarbon repeating unit is preferred.

Examples of the skeleton of the alicyclic hydrocarbon formed are the same as those of the alicyclic hydrocarbon group of R₁₂ to R₂₅ in formulae (pI) to (pVI).

The alicyclic hydrocarbon skeleton may have a substituent, and examples of the substituent include R₁₃′ to R₁₆′ in formulae (II-AB1) and (II-AB2).

In the alicyclic hydrocarbon-based acid-decomposable resin for use in the present invention, the group capable of decomposing under the action of an acid may be contained in at least one repeating unit out of the repeating unit having an alicyclic hydrocarbon-containing partial structure represented by any one of formulae (pI) to (pV), the repeating unit represented by formula (II-AB), and the repeating unit comprising a copolymerization component described later.

Various substituents R₁₃′ to R₁₆′ in formulae (II-AB1) and (II-AB2) may work out to a substituent of an atomic group for forming an alicyclic structure in formula (II-AB) or an atomic group Z′ for forming a crosslinked alicyclic structure.

Specific examples of the repeating units represented by formulae (II-AB1) and (II-AB2) are set forth below, but the present invention is not limited thereto.

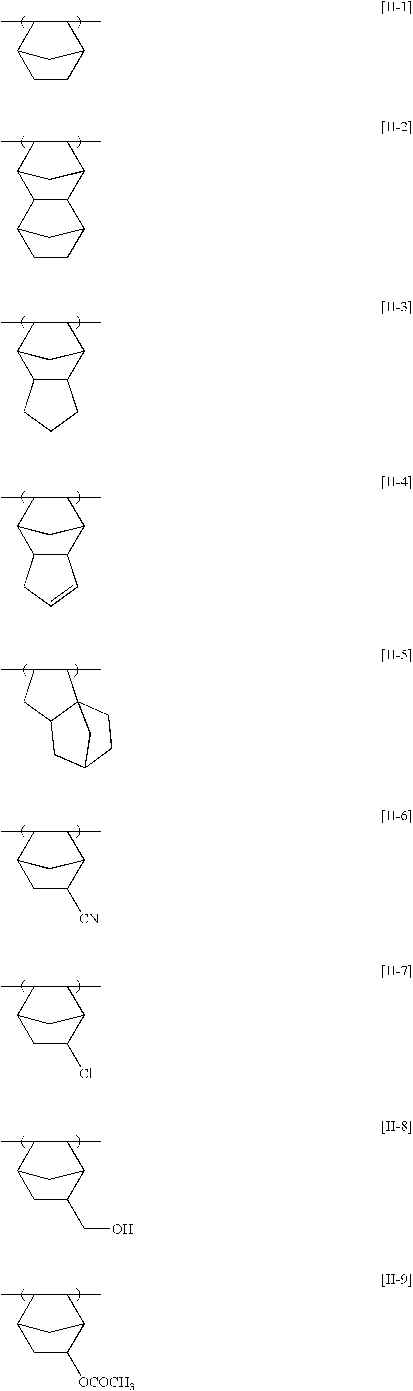

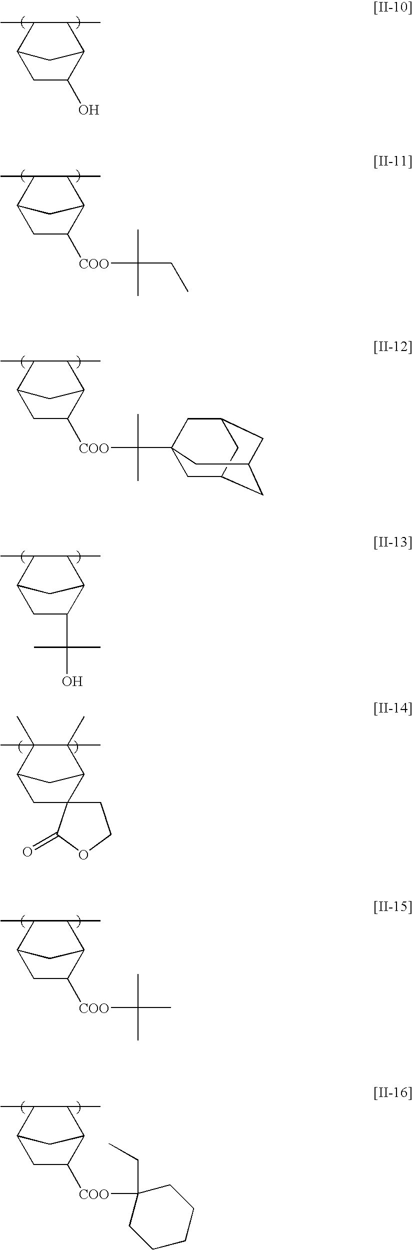

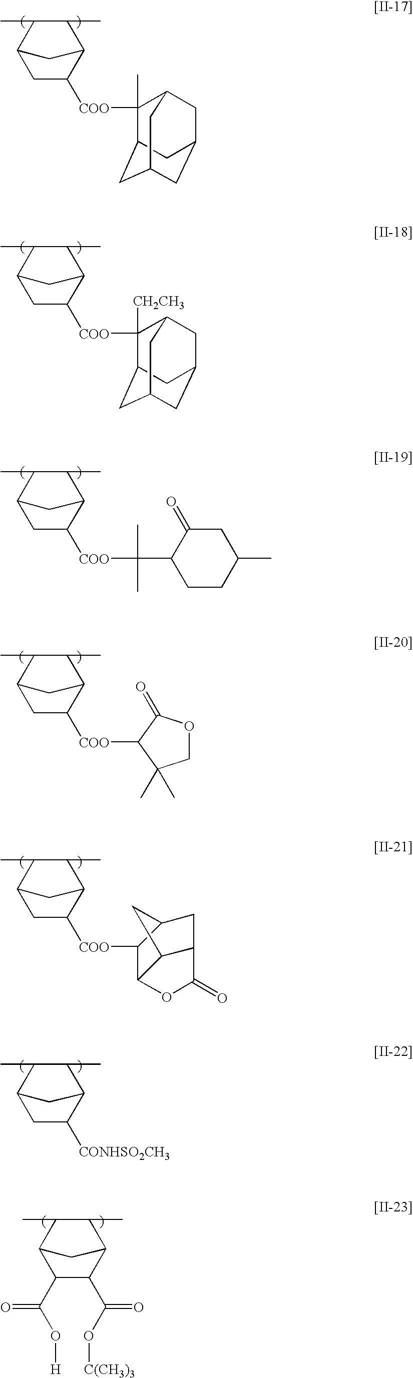

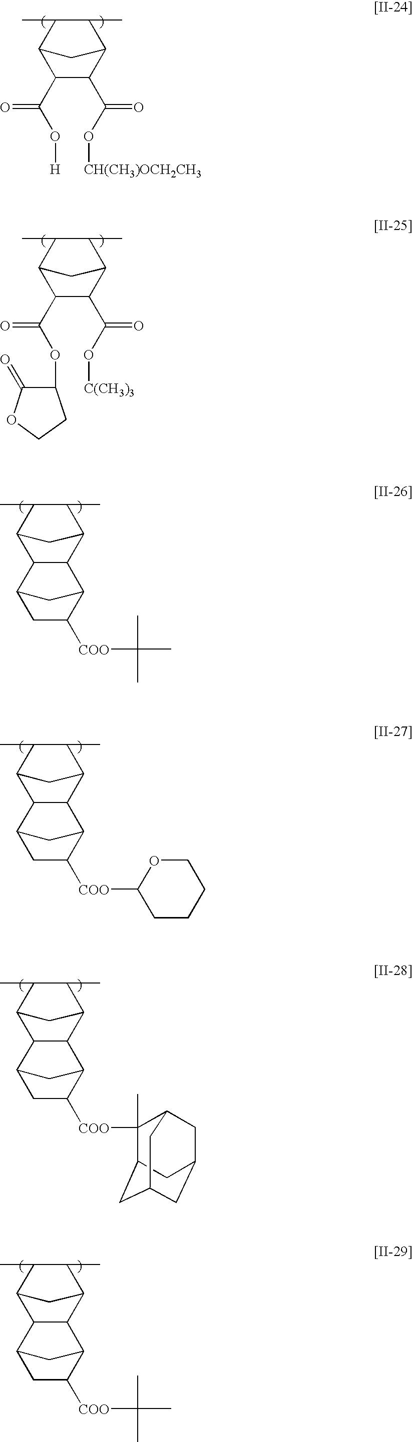

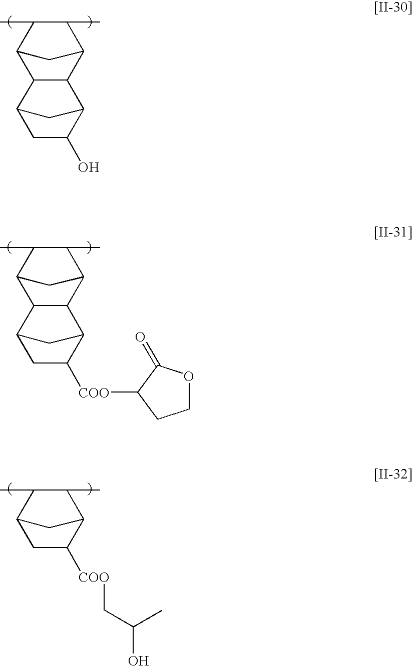

The acid-decomposable resin (A) for use in the present invention preferably has a lactone group. As for the lactone group, any group may be used as long as it has a lactone structure, but a group having a 5- to 7-membered ring lactone structure is preferred. The 5- to 7-membered ring lactone structure is preferably condensed with another ring structure in the form of forming a bicyclo or spiro structure. It is more preferred to contain a repeating unit having a lactone structure-containing group represented by any one of the following formulae (LC1-1) to (LC1-16). The group having a lactone structure may be bonded directly to the main chain. Among these lactone structures, preferred are the groups represented by formulae (LC1-1), (LC1-4), (LC1-5), (LC1-6), (LC1-13) and (LC1-14). By virtue of using a specific lactone structure, the line edge roughness and development defect are improved.

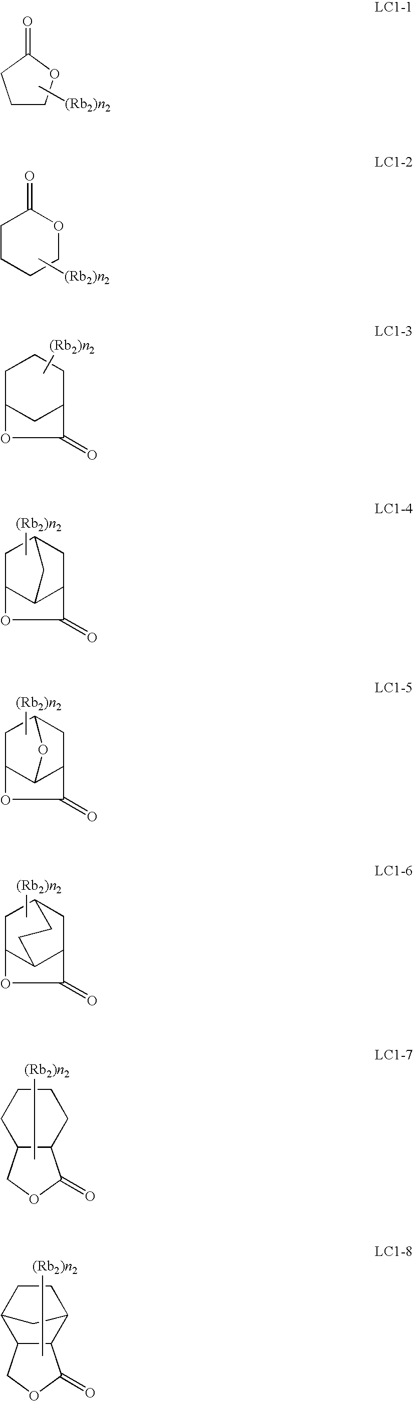

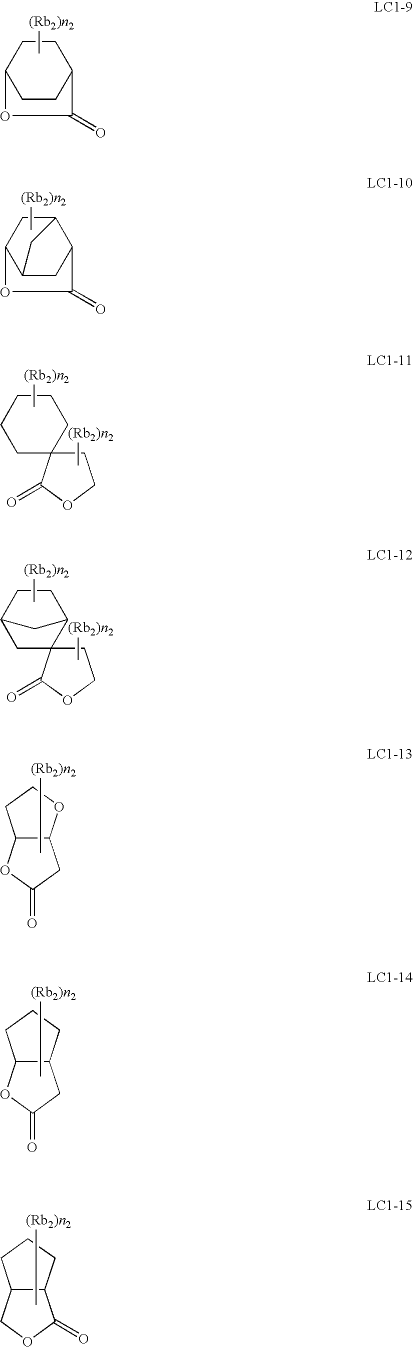

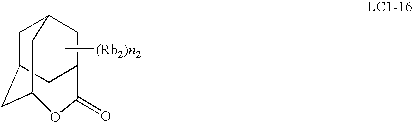

The lactone structure moiety may or may not have a substituent (Rb₂). Preferred examples of the substituent (Rb₂) include an alkyl group having a carbon number of 1 to 8, a cycloalkyl group having a carbon number of 4 to 7, an alkoxy group having a carbon number of 1 to 8, an alkoxycarbonyl group having a carbon number of 2 to 8, a carboxyl group, a halogen atom, a hydroxyl group, a cyano group and an acid-decomposable group. n₂ represents an integer of 0 to 4. When n₂ is an integer of 2 or more, the plurality of Rb₂'s may be the same or different and also, the plurality of Rb₂'s may combine with each other to form a ring.

Examples of the repeating unit having a lactone structure-containing group represented by any one of formulae (LC1-1) to (LC1-16) include a repeating unit where at least one of R₁₃′ to R₁₆′ in formula (II-AB1) or (II-AB2) has a group represented by any one of formulae (LC1-1) to (LC1-16) (for example, R₅ of —COOR₅ is a group represented by any one of formulae (LC1-1) to (LC1-16)), and a repeating unit represented by the following formula (AI):

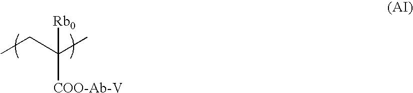

In formula (AI), Rb₀ represents a hydrogen atom, a halogen atom or an alkyl group having a carbon number of 1 to 4.

Preferred examples of the substituent which the alkyl group of Rb₀ may have include a hydroxyl group and a halogen atom.

Examples of the halogen atom of Rb₀ include a fluorine atom, a chlorine atom, a bromine atom and an iodine atom.

Rb₀ is preferably a hydrogen atom, a methyl group, a hydroxymethyl group or a trifluoromethyl group, particularly preferably a hydrogen atom or a methyl group.

Ab represents a single bond, an alkylene group, a divalent linking group having a monocyclic or polycyclic alicyclic hydrocarbon structure, an ether group, an ester group, a carbonyl group, or a divalent group comprising a combination thereof, and is preferably a single bond or a linking group represented by -Ab₁-CO₂—. Ab₁ is a linear or branched alkylene group or a monocyclic or polycyclic cycloalkylene group, preferably a methylene group, an ethylene group, a cyclohexylene group, an adamantylene group or a norbornylene group.

V represents a group represented by any one of formulae (LC1-1) to (LC1-16).

The repeating unit having a lactone structure usually has an optical isomer, but any optical isomer may be used. One optical isomer may be used alone or a mixture of a plurality of optical isomers may be used. In the case of mainly using one optical isomer, the optical purity (ee) thereof is preferably 90 or more, more preferably 95 or more.

Specific examples of the repeating unit having a lactone structure-containing group are set forth below, but the present invention is not limited thereto.

(In the formulae, Rx is H CH₃, CH₂OH or CF₃.)

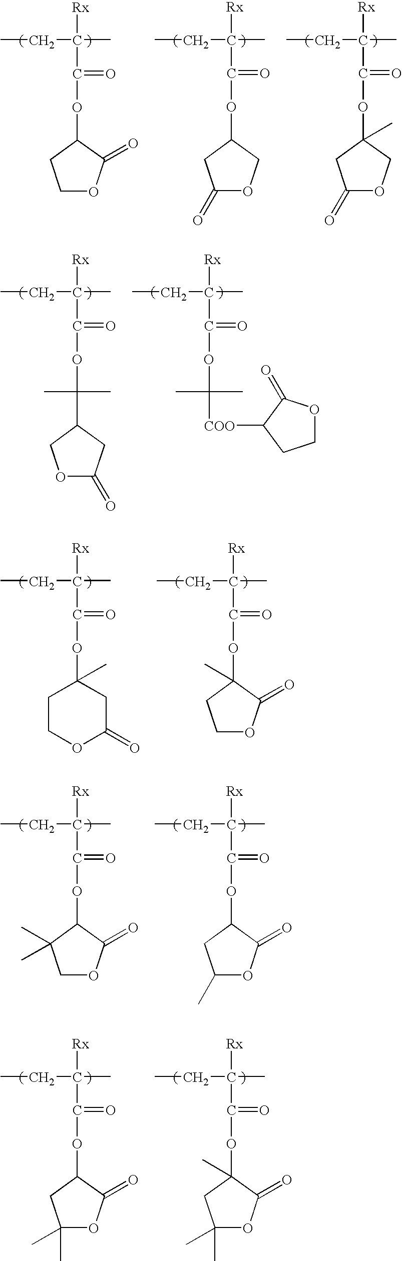

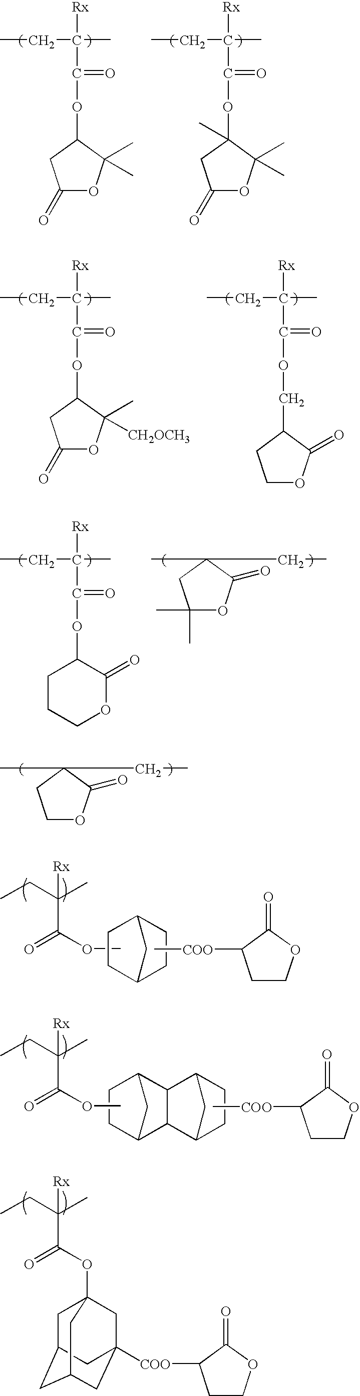

(In the formulae, Rx is H, CH₃, CH₂OH or CF₃.)

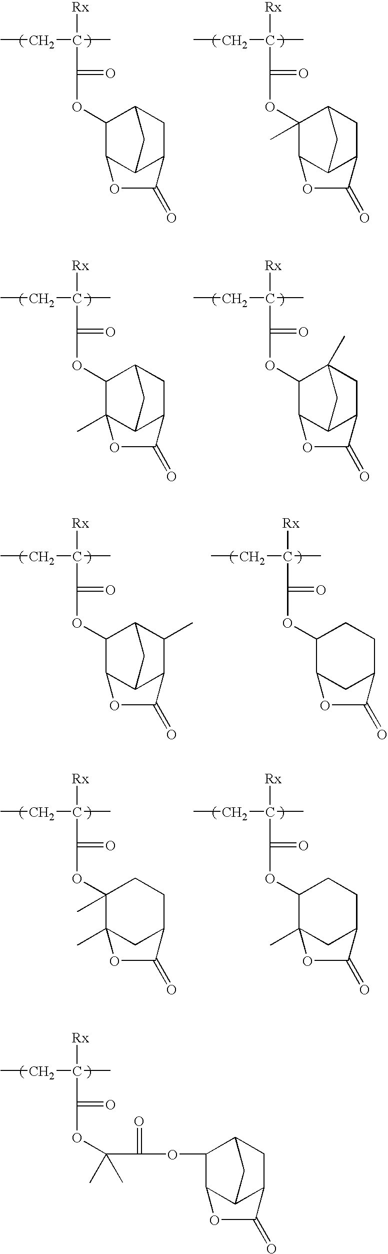

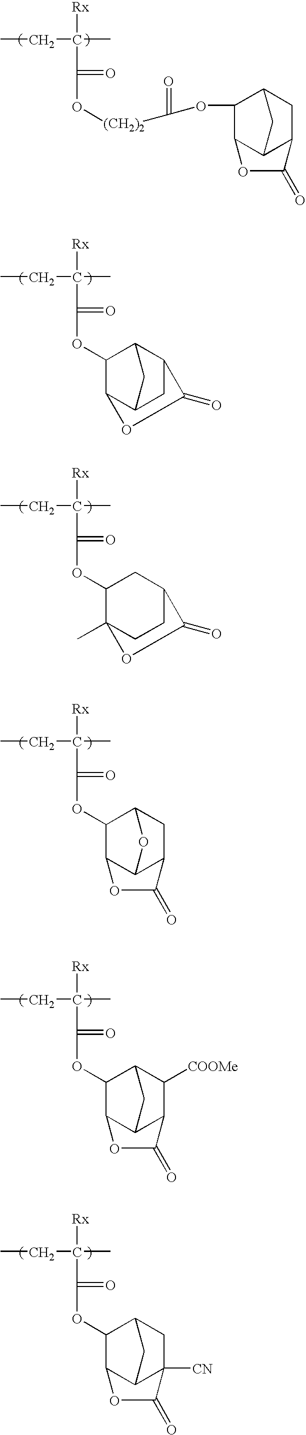

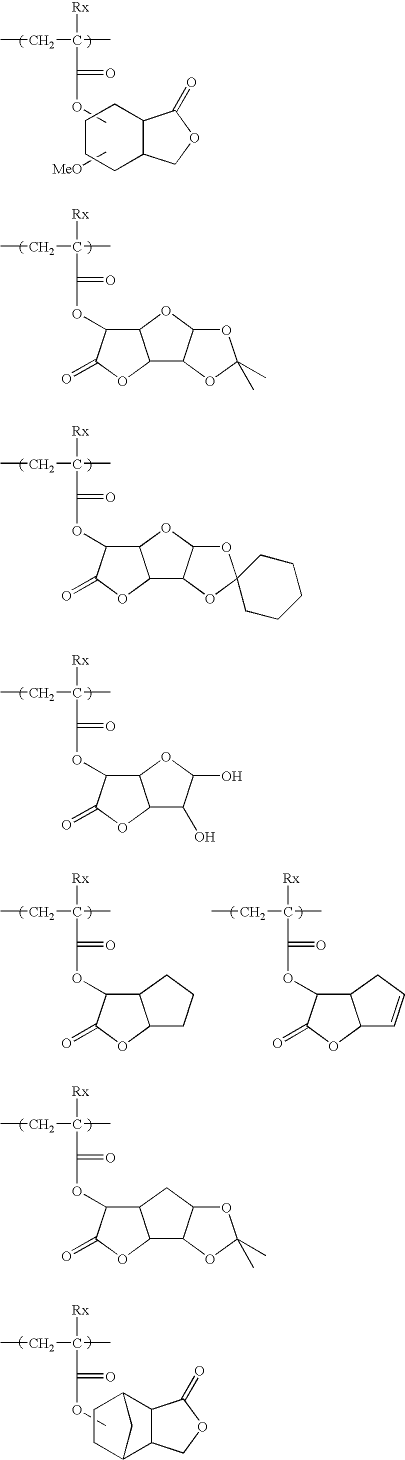

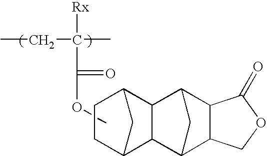

(In the formulae, Rx is H, CH₃, CH₂OH or CF₃.)

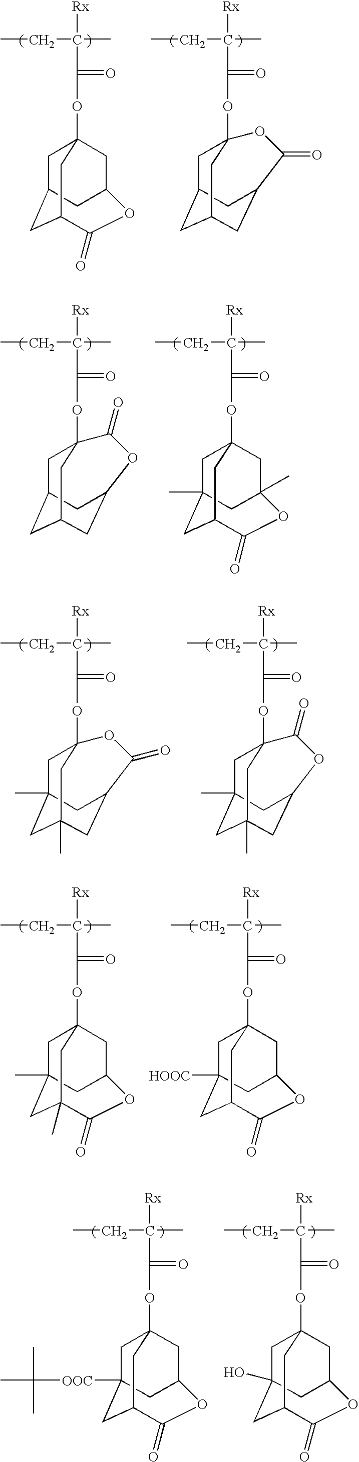

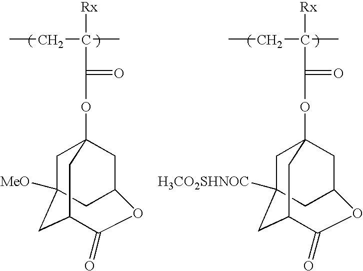

The acid-decomposable resin (A) for use in the present invention preferably contains a repeating unit having a polar group-containing organic group, more preferably a repeating unit having an alicyclic hydrocarbon structure substituted by a polar group. By virtue of this repeating unit, the adhesion to substrate and the affinity for developer are enhanced. The alicyclic hydrocarbon structure of the alicyclic hydrocarbon structure substituted by a polar group is preferably an adamantyl group, a diamantyl group or a norbornane group. The polar group is preferably a hydroxyl group or a cyano group.

The alicyclic hydrocarbon structure substituted by a polar group is preferably a partial structure represented by any one of the following formulae (VIIa) to (VIId):

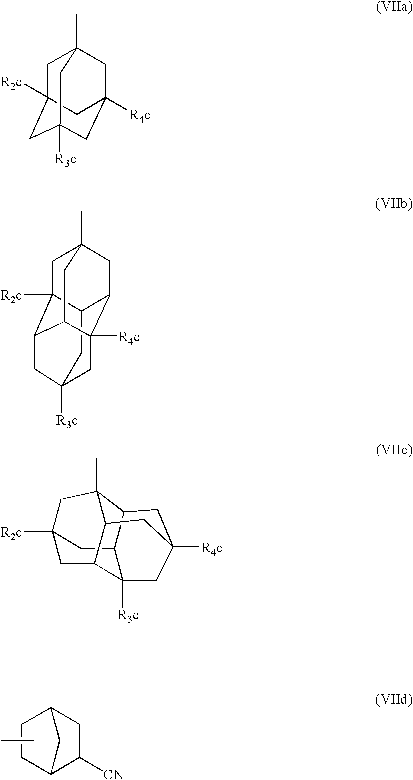

In formulae (VIIa) to (VIIc), R_{2c} to R_{4c} each independently represents a hydrogen atom, a hydroxyl group or a cyano group, provided that at least one of R_{2c} to R_{4c} represents a hydroxyl group or a cyano group. A structure where one or two member(s) out of R_{2c} to R_{4c} is(are) a hydroxyl group with the remaining being a hydrogen atom is preferred.

In formula (VIIa), it is more preferred that two members out of R_{2c} to R_{4c} are a hydroxyl group and the remaining is a hydrogen atom.

Examples of the repeating unit having a group represented by any one of formulae (VIIa) to (VIId) include a repeating unit where at least one of R₁₃′ to R₁₆′ in formula (II-AB1) or (II-AB2) has a group represented by any one of formulae (VIIa) to (VIId) (for example, R₅ of —COOR₅ is a group represented by any one of formulae (VIIa) to (VIId)), and repeating units represented by the following formulae (AIIa) to (AIId):

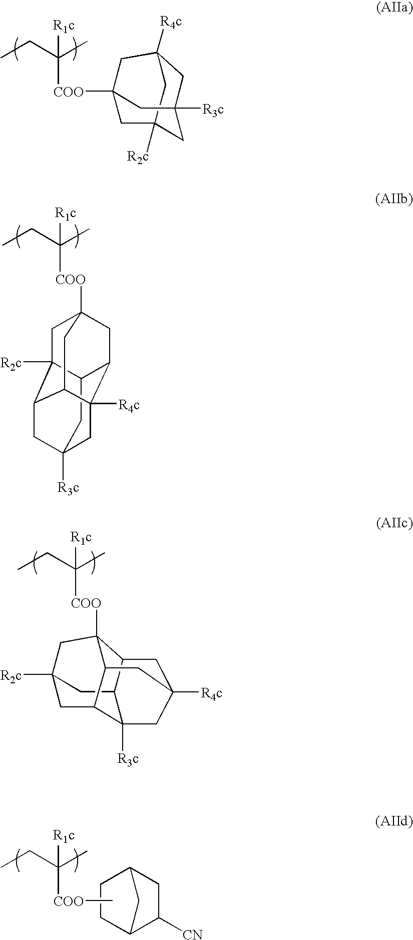

In formulae (AIIa) to (AIId), R_{1c} represents a hydrogen atom, a methyl group, a trifluoromethyl group or a hydroxymethyl group.

R₂ₐ to R_{4c} have the same meanings as R_{2c} to R_{4c} in formulae (VIIa) to (VIIc).

Specific examples of the repeating unit having a structure represented by any one of formulae (AIIa) to (AIId) are set forth below, but the present invention is not limited thereto.

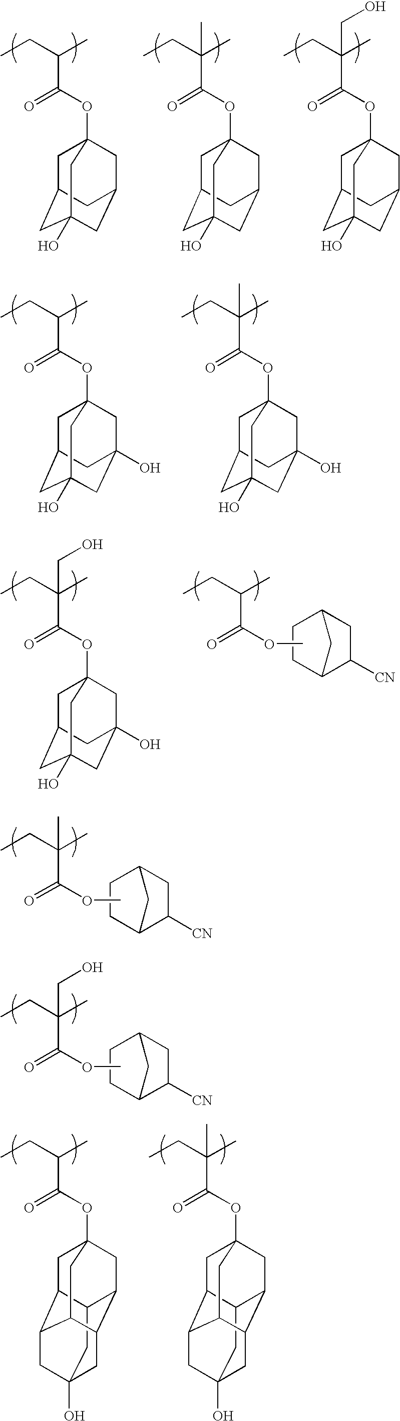

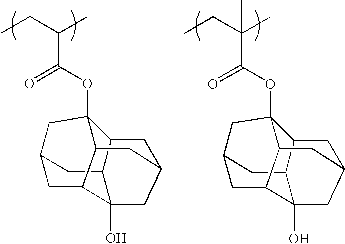

The acid-decomposable resin (A) for use in the present invention may contain a repeating unit represented by the following formula (VIII):

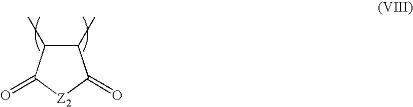

In formula (VIII), Z₂ represents —O— or —N(R₄₁)—. R₄₁ represents a hydrogen atom, a hydroxyl group, an alkyl group or —OSO₂—R₄₂. R₄₂ represents an alkyl group, a cycloalkyl group or a camphor residue. The alkyl group of R₄₁ and R₄₂ may be substituted by a halogen atom (preferably fluorine atom) or the like.

Specific examples of the repeating unit represented by formula (VIII) are set forth below, but the present invention is not limited thereto.

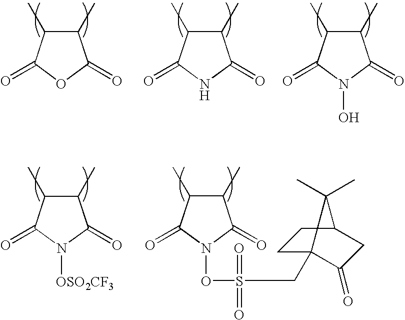

The acid-decomposable resin (A) for use in the present invention preferably contains a repeating unit having an alkali-soluble group, more preferably a repeating unit having a carboxyl group. By virtue of containing such a repeating unit, the resolution increases in the usage of forming contact holes. As for the repeating unit having a carboxyl group, a repeating unit where a carboxyl group is directly bonded to the resin main chain, such as repeating unit by an acrylic acid or a methacrylic acid, a repeating unit where a carboxyl group is bonded to the resin main chain through a linking group, and a repeating unit where a carboxyl group is introduced into the terminal of the polymer chain by using a polymerization initiator or chain transfer agent having an alkali-soluble group at the polymerization, all are preferred. The linking group may have a monocyclic or polycyclic hydrocarbon structure. A repeating unit by an acrylic acid or a methacrylic acid is particularly preferred.

The acid-decomposable resin (A) for use in the present invention may further contain a repeating unit having from 1 to 3 groups represented by formula (F1). By virtue of this repeating unit, the performance in terms of line edge roughness is enhanced.

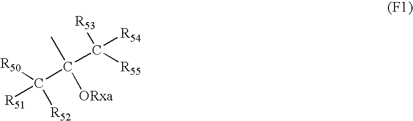

In formula (F1), R₅₀ to R₅₅ each independently represents a hydrogen atom, a fluorine atom or an alkyl group, provided that at least one of R₅₀ to R₅₅ is a fluorine atom or an alkyl group with at least one hydrogen atom being substituted by a fluorine atom.

Rxa represents a hydrogen atom or an organic group (preferably an acid-decomposable protective group, an alkyl group, a cycloalkyl group, an acyl group or an alkoxycarbonyl group).

The alkyl group of R₅₀ to R₅₅ may be substituted by a halogen atom (e.g., fluorine), a cyano group or the like, and the alkyl group is preferably an alkyl group having a carbon number of 1 to 3, such as methyl group and trifluoromethyl group.

It is preferred that R₅₀ to R₅₅ all are a fluorine atom.

The organic group represented by Rxa is preferably an acid-decomposable protective group or an alkyl, cycloalkyl, acyl, alkylcarbonyl, alkoxycarbonyl, alkoxycarbonylmethyl, alkoxymethyl or 1 -alkoxyethyl group which may have a substituent.

The repeating unit having a group represented by formula (F1) is preferably a repeating unit represented by the following formula (F2):

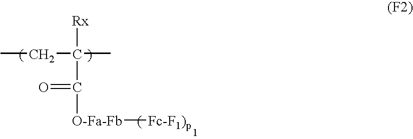

In formula (F2), Rx represents a hydrogen atom, a halogen atom or an alkyl group having a carbon number of 1 to 4. Preferred examples of the substituent which the alkyl group of Rx may have include a hydroxyl group and a halogen atom.

Fa represents a single bond or a linear or branched alkylene group (preferably represents a single bond).

Fb represents a monocyclic or polycyclic cyclohydrocarbon group.

Fc represents a single bond or a linear or branched alkylene group (preferably represents a single bond or a methylene group).

F₁ represents a group represented by formula (F1).

p₁ represents a number of 1 to 3.

The cyclohydrocarbon group of Fb is preferably a cyclopentylene group, a cyclohexylene group or a norbornylene group.

Specific examples of the repeating unit having a group represented by formula (F1) are set forth below, but the present invention is not limited thereto.

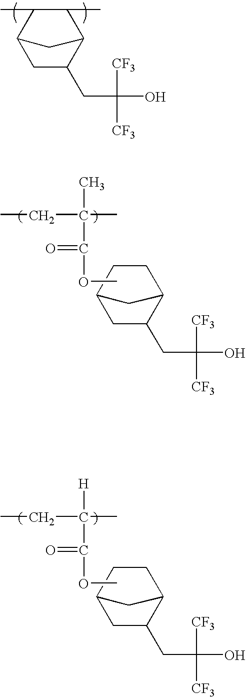

The acid-decomposable resin (A) for use in the present invention may further contain a repeating unit having an alicyclic hydrocarbon structure and not exhibiting acid decomposability. By containing such a repeating unit, the dissolving out of low molecular components from the resist film to the immersion liquid at the immersion exposure can be reduced. Examples of such a repeating unit include 1-adamantyl (meth)acrylate, tri-cyclodecanyl(meth)acrylate and cyclohexyl(meth)acrylate.

The acid-decomposable resin (A) for use in the present invention preferably contains a repeating unit represented by formula (IIIa) having neither a hydroxyl group nor a cyano group as the repeating unit having an alicyclic hydrocarbon structure and not exhibiting acid decomposability;

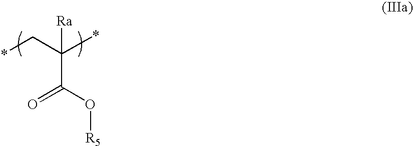

In formula (IIIa), R₅ represents a hydrocarbon group having at least one cyclic structure and having neither a hydroxyl group nor a cyano group.

Ra represents a hydrogen atom, an alkyl group or a —CH₂—O—Ra₂ group, wherein Ra₂ represents a hydrogen atom, an alkyl group or an acyl group. Ra is preferably a hydrogen atom, a methyl group, a hydroxymethyl group or a trifluoromethyl group, particularly preferably a hydrogen atom or a methyl group.

The cyclic structure possessed by R₅ includes a monocyclic hydrocarbon group and a polycyclic hydrocarbon group. Examples of the monocyclic hydrocarbon group include a cycloalkyl group having a carbon number of 3 to 12, such as cyclopentyl group, cyclohexyl group, cycloheptyl group and cyclooctyl group, and a cycloalkenyl group having a carbon number of 3 to 12, such as cyclohexenyl group. As the monocyclic hydrocarbon group, a monocyclic hydrocarbon group having a carbon number of 3 to 7 is preferred, and a cyclopentyl group and a cyclohexyl group are more preferred.

The polycyclic hydrocarbon group includes a ring gathered hydrocarbon group and a crosslinked cyclic hydrocarbon group. Examples of the ring gathered hydrocarbon group include a bicyclohexyl group and a perhydronaphthalenyl group. Examples of the crosslinked cyclic hydrocarbon ring include a bicyclic hydrocarbon ring such as pinane, bornane, norpinane, norbornane and bicyclooctane rings (e.g., bicyclo[2.2.2]octane ring, bicyclo[3.2.1]octane ring), a tricyclic hydrocarbon ring such as homobredane, adamantane, tricyclo[5.2.1.0^{2.6}]decane and tricyclo[4.3.1.1^{2.5}]undecane rings, and a tetracyclic hydrocarbon ring such as tetracyclo[4.4.0.1^{2.5}.1^{7.10}]dodecane and perhydro-1,4-methano-5,8-methanonaphthalene rings. The crosslinked cyclic hydrocarbon ring also includes a condensed cyclic hydrocarbon ring, and examples thereof include a condensed ring formed by condensing a plurality of 5- to 8-membered cycloalkane rings such as perhydronaphthalene (decalin), perhydroanthracene, perhydrophenanthrene, perhydroacenaphthene, perhydrofluorene, perhydroindene and perhydrophenanthrene rings.

As the crosslinked cyclic hydrocarbon ring, a norbornyl group, an adamantyl group, a bicyclooctanyl group, a tricyclo[5.2.1.0^{2.6}]decanyl group are preferred, and a norbornyl group and an adamantyl group are more preferred.

Such an alicyclic hydrocarbon group may have a substituent, and preferred examples of the substituent include a halogen atom, an alkyl group, a hydroxyl group protected by a protective group, and an amino group protected by a protective group. Preferred halogen atoms include bromine, chlorine and fluorine atoms, and preferred alkyl groups include methyl, ethyl, butyl and tert-butyl groups. This alkyl group may further have a substituent, and the substituent which the alkyl group may further have includes a halogen atom, an alkyl group, a hydroxyl group protected by a protective group, and an amino group protected by a protective group.

Examples of the protective group include an alkyl group, a cycloalkyl group, an aralkyl group, a substituted methyl group, a substituted ethyl group, an alkoxycarbonyl group and an aralkyloxycarbonyl group. For example, the alkyl group is preferably an alkyl group having a carbon number of 1 to 4, the substituted methyl group is preferably a methoxymethyl, methoxythiomethyl, benzyloxymethyl, tert-butoxymethyl or 2-methoxyethoxymethyl group, the substituted ethyl group is preferably a 1-ethoxyethyl or 1-methyl-1-methoxyethyl group, the acyl group is preferably an aliphatic acyl group having a carbon number of 1 to 6, such as formyl, acetyl, propionyl, butyryl, isobutyryl, valeryl and pivaloyl groups, and the alkoxycarbonyl group is preferably an alkoxycarbonyl group having a carbon number of 1 to 4.

The content of the repeating unit represented by formula (IIIa) having neither a hydroxyl group nor a cyano group is preferably from 0 to 40 mol %, more preferably front 0 to 20 mol %, based on all repeating units in the resin (A).

Specific examples of the repeating unit represented by formula (IIIa) are set forth below, but the present invention is not limited thereto.

In formulae, Ra represents H, CH₃, CH₂OH or CF₃.

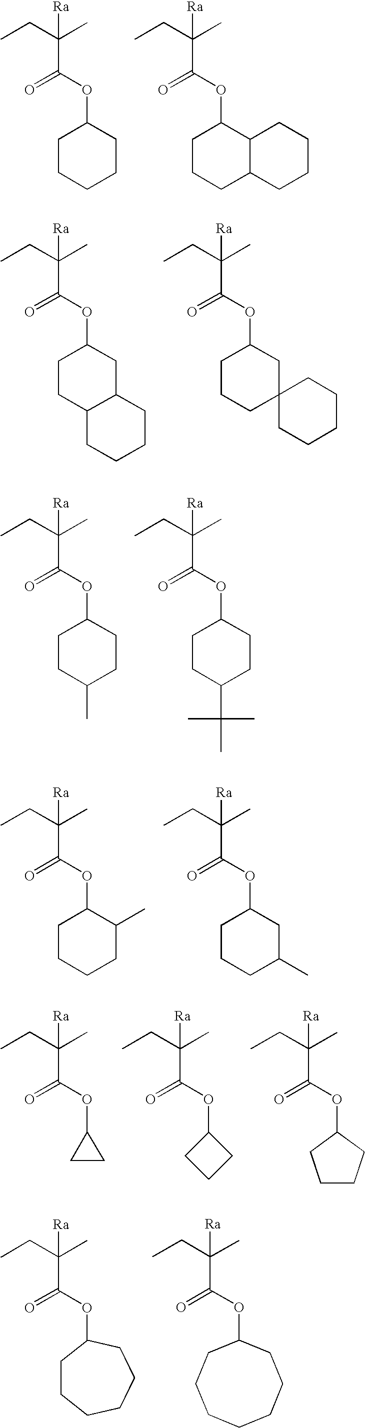

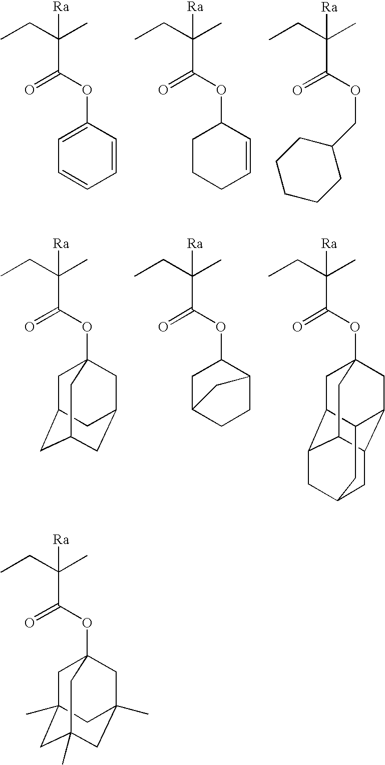

The acid-decomposable resin (A) for use in the present invention may contain, in addition to the above-described repeating units, various repeating structural units for the purpose of controlling the dry etching resistance, suitability for standard developer, adhesion to substrate, resist profile and properties generally required of the resist such as resolving power, heat resistance and sensitivity.

Examples of such a repeating structural unit include, but are not limited to, repeating structural units corresponding to the monomers described below.

By virtue of such a repeating structural unit, the performance required of the acid-decomposable resin (A), particularly, (1) solubility in the coating solvent, (2) film-forming property (glass transition point), (3) alkali developability, (4) film loss (selection of hydrophilic, hydrophobic or alkali-soluble group), (5) adhesion of unexposed area to substrate, (6) dry etching resistance, and the like, can be subtly controlled.

Examples of the monomer include a compound having one addition-polymerizable unsaturated bond selected from acrylic acid esters, methacrylic acid esters, acrylamides, methacrylamides, allyl compounds, vinyl ethers and vinyl esters.

Other than these, an addition-polymerizable unsaturated compound copolymerizable with the monomers corresponding to the above-described various repeating structural units may be copolymerized.

In the acid-decomposable resin (A), the molar ratio of respective repeating structural units contained is appropriately determined to control the dry etching resistance of resist, suitability for standard developer, adhesion to substrate, resist profile and performances generally required of the resist, such as resolving power, heat resistance and sensitivity.

The preferred embodiment of the acid-decomposable resin (A) for use in the present invention includes the followings:

(1) a resin containing a repeating unit having an alicyclic hydrocarbon-containing partial structure represented by any one of formulae (pI) to (pV) (side chain type),

preferably a resin containing a (meth)acrylate repeating unit having a structure represented by any one of formulae (pI) to (pV), and

(2) a resin containing a repeating unit represented by formula (II-AB) (main chain type).

The embodiment of (2) further includes:

(3) a resin having a repeating unit represented by formula (II-AB), a maleic anhydride derivative and a (meth)acrylate structure (hybrid type).

In the acid-decomposable resin (A), the content of the repeating unit having an acid-decomposable group is preferably from 10 to 60 mol %, more preferably from 20 to 50 mol %, still more preferably from 25 to 40 mol %, based on all repeating structural units,

In the acid-decomposable resin (A), the content of the repeating unit having an acid-decomposable group is preferably from 10 to 60 mol %, more preferably from 20 to 50 mol %, still more preferably from 25 to 40 mol %, based on all repeating structural units.

In the acid-decomposable resin (A), the content of the repeating unit having an alicyclic hydrocarbon-containing partial structure represented by any one of formulae (pI) to (pV) is preferably from 20 to 70 mol %, more preferably from 20 to 50 mol %, still more preferably from 25 to 40 mol %, based on all repeating structural units.

In the acid-decomposable resin (A), the content of the repeating unit represented by formula (II-AB) is preferably from 10 to 60 mol %, more preferably from 15 to 55 mol %, still more preferably from 20 to 50 mol %, based on all repeating structural units.

In the acid-decomposable resin (A), the content of the repeating unit having a lactone ring is preferably from 10 to 70 mol %, more preferably from 20 to 60 mol %, still more preferably from 25 to 40 mol %, based on all repeating structural units.

In the acid-decomposable resin (A), the content of the repeating unit having a polar group-containing organic group is preferably from 1 to 40 mol %, more preferably from 5 to 30 mol %, still more preferably from 5 to 20 mol %, based on all repeating structural units.

The content of the repeating structural unit based on the monomer as the further copolymerization component in the resin can also be appropriately selected according to the desired resist performance but in general, the content thereof is preferably 99 mol % or less, more preferably 90 mol % or less, still more preferably 80 mol % or less, based on the total molar number of the repeating structural unit having an alicyclic hydrocarbon-containing partial structure represented by any one of formulae (pI) to (pV) and the repeating unit represented by formula (II-AB).

In the case of using the positive resist composition of the present invention for ArF exposure, the resin preferably has no aromatic group in view of transparency to ArF light.

The acid-decomposable resin (A) for use in the present invention is preferably a resin where all repeating units comprise a (meth)acrylate-based repeating unit. In this case, the repeating units may be all a methacrylate-based repeating unit, all an acrylate-based repeating unit, or all a mixture of methacrylate-based repeating unit/acrylate-based repeating unit, but the content of the acrylate-based -repeating unit is preferably 50 mol % or less based on all repeating units.

The acid-decomposable resin (A) is preferably a copolymer having at least three kinds of repeating units, that is, a (meth)acrylate-based repeating unit, a (meth)acrylate-based repeating unit having an organic group substituted by either a hydroxyl group or a cyano group, and a (meth)acrylate-based repeating unit having an acid-decomposable group.

The acid-decomposable resin is more preferably a ternary copolymerization polymer comprising from 20 to 50 mol % of the repeating unit having an alicyclic hydrocarbon-containing partial structure represented by any one of formulae (pI) to (pV), from 20 to 50 mol % of the repeating unit having a lactone structure and from 5 to 30% of the repeating unit having an alicyclic hydrocarbon structure substituted by a polar group, or a quaternary copolymerization polymer additionally comprising from 0 to 20% of other repeating units.

The resin is more preferably a ternary copolymerization polymer comprising from 20 to 50 mol % of the repeating unit having an acid-decomposable group represented by any one of the following formulae (ARA-1) to (ARA-5), from 20 to 50 mol % of the repeating unit having a lactone group represented by any one of the following formulae (ARL-1) to (ARL-6), and from 5 to 30 mol % of the repeating unit having an alicyclic hydrocarbon structure substituted by a polar group represented by any one of the following formulae (ARH-1) to (ARH-3), or a quaternary copolymerization polymer further comprising from 5 to 20 mol % of the repeating unit containing a carboxyl group or a structure represented by formula (F1) and the repeating unit having an alicyclic hydrocarbon structure and not exhibiting acid decomposability.

(In the formulae, Rxy₁ represents a hydrogen atom or a methyl group, and Rxa₁ and Rxb₁ each represents a methyl group or an ethyl group).

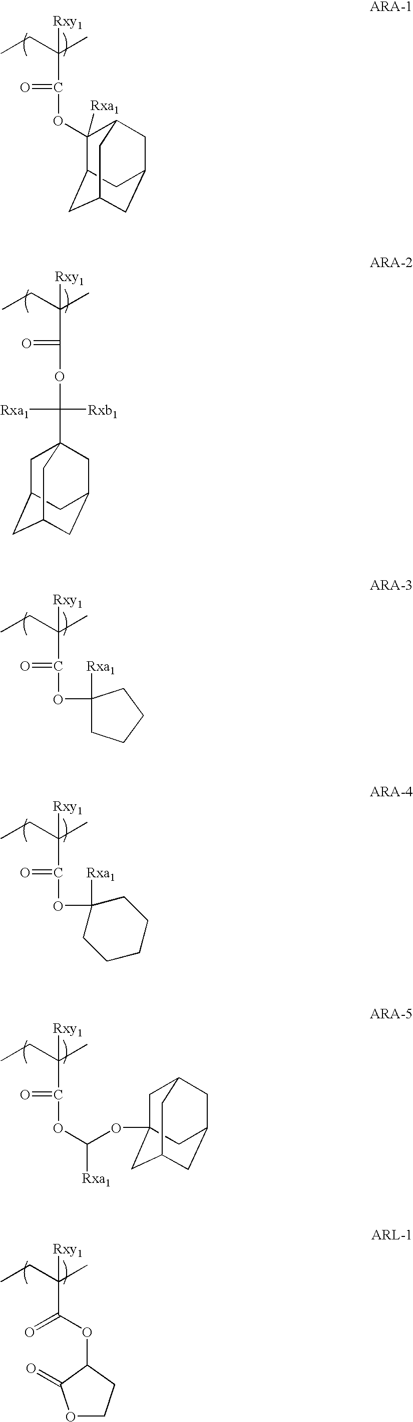

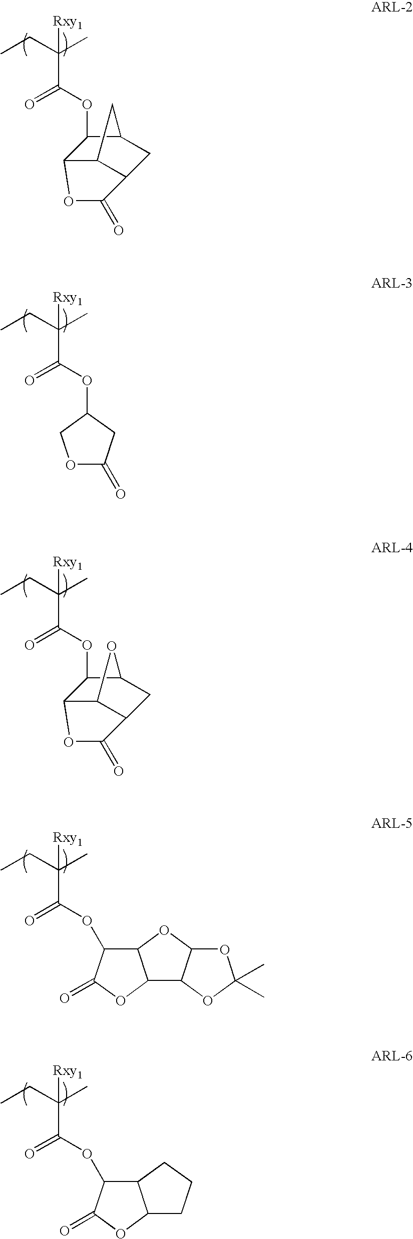

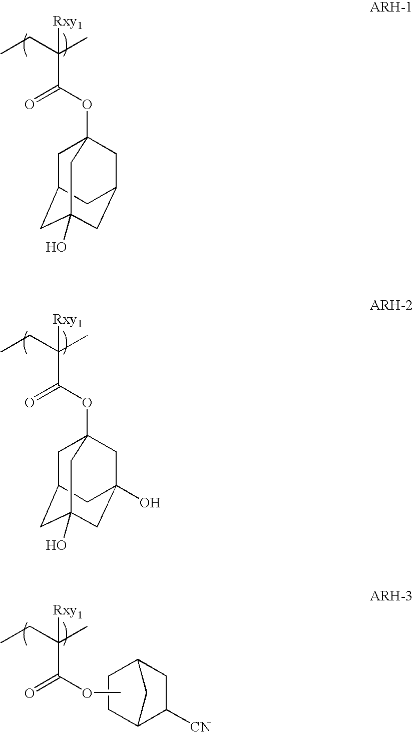

The acid-decomposable resin (A) for use in the present invention can be synthesized by an ordinary method (for example, radical polymerization). Examples of the synthesis method in general include a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred. Examples of the reaction solvent include tetrahydrofuran, 1,4-dioxane, ethers (e.g., diisopropyl ether), ketones (e.g., methyl ethyl ketone, methyl isobutyl ketone), an ester solvent (e.g., ethyl acetate), an amide solvent (e.g., dimethylformamide, diethylacetamide), and a solvent capable of dissolving the composition of the present invention, which is described later, such as propylene glycol monomethyl ether acetate, propylene glycol monomethyl ether and cyclohexanone. The polymerization is more preferably performed using the same solvent as the solvent used in the resist composition of the present invention. By the use of this solvent, production of particles during storage can be suppressed.

The polymerization reaction is preferably performed in an inert gas atmosphere such as nitrogen and argon. As for the polymerization initiator, the polymerization is started using a commercially available radical initiator (e.g., azo-based initiator, peroxide). The radical initiator is preferably an azo-based initiator, and an azo-based initiator having an ester group, a cyano group or a carboxyl group is preferred. Preferred examples of the initiator include azobisisobutyronitrile, azobisdimethylvaleronitrile and dimethyl 2,2′-azobis(2-methyl-propionate). The initiator is added additionally or in parts, if desired. After the completion of reaction, the reactant is charged into a solvent, and the desired polymer is recovered by a method such as powder or solid recovery. The reaction concentration is from 5 to 50 mass %, preferably from 10 to 30 mass %, and the reaction temperature is usually from 10 to 150° C., preferably from 30 to 120° C., more preferably from 60 to 100° C. (In this specification, mass ratio is equal to weight ratio.)

The weight average molecular weight of the resin (A) for use in the present invention is preferably from 1,000 to 200,000, more preferably from 3,000 to 20,000, even more preferably from 5,000 to 15,000, and most preferably from 5,000 to 10,000, in terms of polystyrene by the GPC method. When the weight average molecular weight is from 1,000 to 200,000, this enables preventing deterioration of heat resistance, dry etching resistance and developability as well as deterioration of film-forming property due to increase in the viscosity.

The dispersity (molecular weight distribution) is usually from 1 to 5, preferably from 1 to 3, more preferably from 1.2 to 3.0, still more preferably from 1.2 to 2.0. As the dispersity is smaller, the resolution and resist profile are more excellent, the side wall of the resist pattern is smoother, and the roughness property is more improved.

In the positive resist composition of the present invention, the amount of all resins for use in the present invention blended in the entire composition is preferably from 50 to 99.9 mass %, more preferably from 60 to 99.0 mass %, based on me entire solid content.

In the present invention, one resin may be used or a plurality of resins may be used in combination.

The acid-decomposable resin (A) for use in the present invention preferably contains no fluorine atom and no silicon atom in view of compatibility with the hydrophobic resin (C).

(B) Compound Capable of Generating an Acid upon Irradiation with Actinic Rays or Radiation

The positive resist composition of the present invention contains a compound capable of generating an acid upon irradiation with actinic rays or radiation (sometimes referred to as a “photoacid generator” or “component (B)”).

The photoacid generator may be appropriately selected from a photoinitiator for photocationic polymerization, a photoinitiator for photoradical polymerization, a photo-decoloring agent for coloring matters, a photo-discoloring agent, a known compound used for microresist or the like and capable of generating an acid upon irradiation with actinic rays or radiation, and a mixture thereof.

Examples thereof include a diazonium salt, a phosphonium salt, a sulfonium salt, an iodonium salt, imidosulfonate, oxime sulfonate, diazodisulfone, disulfone and o-nitrobenzyl sulfonate.

Also, a compound where such a group or compound capable of generating an acid upon irradiation with actinic rays or radiation is introduced into the main or side chain of the polymer, for example, compounds described in U.S. Pat. No. 3,849,137, German Patent 3,914,407, JP-A-63-26653, JP-A-55-164824, JP-A-62-69263, JP-A-63-146038, JP-A-63-163452, JP-A-62-153853 and JP-A-63-146029, may be used.

Furthermore, compounds capable of generating an acid by the effect of light described, for example, in U.S. Pat. No. 3,779,778 and European Patent 126,712 may also be used.

Among the compounds capable of decomposing upon irradiation with actinic rays or radiation to generate an acid, preferred are the compounds represented by the following formulae (ZI), (ZII) and (ZIII):

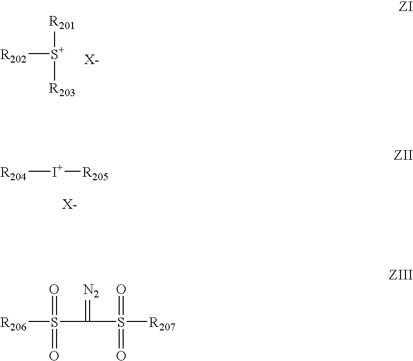

In formula (ZI), R₂₀₁, R₂₀₂ and R₂₀₃ each independently represents an organic group.

X⁻ represents a non-nucleophilic anion, and preferred examples thereof include sulfonate anion, carboxylate anion, bis(alkylsulfonyl)amide anion, tris(alkylsulfonyl)methide anion, BF₄⁻, PF₆⁻ and SbF₆⁻. The anion is preferably an organic anion containing a carbon atom.

The preferred organic anion includes the organic anions represented by the following formulae:

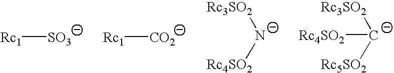

In the formulae, Rc₁ represents an organic group.

The organic group of Rc₁ includes an organic group having a carbon number of 1 to 30, and preferred examples thereof include an alkyl group which may be substituted, an aryl group, and a group where a plurality of these groups are connected through a single bond or a linking group such as —O—, —CO₂—, —S—, —SO₃— and —SO₂N(Rd₁)-. Rd₁ represents a hydrogen atom or an alkyl group.

Rc₃, Rc₄ and Rc₅ each independently represents an organic group. Preferred organic groups of Rc₃, Rc₄ and Rc₅ are the same as the preferred organic groups of Rc₁. The organic group is most preferably a perfluoroalkyl group having a carbon number of 1 to 4.

Rc₃ and Rc₄ may combine to form a ring. The group formed by combining Rc₃ and Rc₄ includes an alkylene group and an arylene group and is preferably a perfluoroalkylene group having a carbon number of 2 to 4.

The organic group of Rc₁ and Rc₃ to Rc₅ is particularly preferably an alkyl group with the 1-position being substituted by a fluorine atom or a fluoroalkyl group, or a phenyl group substituted by a fluorine atom or a fluoroalkyl group. By virtue of having a fluorine atom or a fluoroalkyl group, the acidity of the acid generated upon irradiation with light increases and the sensitivity is enhanced. Also, when Rc₃ and Rc₄ are combined to form a ring, the acidity of the acid generated upon irradiation with light increases and the sensitivity is enhanced.

The carbon number of the organic group as R₂₀₁, R₂₀₂ and R₂₀₃ is generally from 1 to 30, preferably from 1 to 20.

Two members out of R₂₀₁ to R₂₀₃ may combine to form a ring structure, and the ring may contain an oxygen atom, a sulfur atom, an ester bond, an amide bond or a carbonyl group. Examples of the group formed by combining two members out of R₂₀₁ to R₂₀₃ include an alkylene group (e.g., butylene, pentylene).

Specific examples of the organic group as R₂₀₁, R₂₀₂ and R₂₀₃ include corresponding groups in the compounds (ZI-1), (ZI-2) and (ZI-3) which are described later.

The compound may be a compound having a plurality of structures represented by formula (ZI). For example, the compound may be a compound having a structure where at least one of R₂₀₁ to R₂₀₃ in the compound represented by formula (ZI) is bonded to at least one of R₂₀₁ to R₂₀₃ in another compound represented by formula (ZI).

The component (ZI) is more preferably a compound (ZI-1), (ZI-2) or (ZI-3) described below.

The compound (ZI-1) is an arylsulfonium compound where at least one of R₂₀₁ to R₂₀₃ in formula (Z1) is an aryl group, that is, a compound having an arylsulfonium as the cation.

In the arylsulfonium compound, R₂₀₁ to R₂₀₃ all may be an aryl group or a part of R₂₀₁ to R₂₀₃ may be an aryl group with the remaining being an alkyl group or a cycloalkyl group.

Examples of the arylsulfonium compound include a triarylsulfonium compound, a diarylalkylsulfonium compound, an aryldialkylsulfonium compound, a diarylcycloalkyl-sulfonium compound and an aryldicycloalkylsulfonium compound.

The aryl group in the arylsulfonium compound is preferably an aryl group such as phenyl group and naphthyl group, or a heteroaryl group such as indole residue and pyrrole residue, more preferably a phenyl group or an indole residue. In the case where the arylsulfonium compound has two or more aryl groups, these two or more aryl groups may be the same of different.

The alkyl group which is present, if desired, in the arylsulfonium compound is preferably a linear or branched alkyl group having a carbon number of 1 to 15, and examples thereof include a methyl group, an ethyl group, a propyl group, an n-butyl group, a sec-butyl group and a tert-butyl group.

The cycloalkyl group which is present, if desired, in the arylsulfonium compound is preferably a cycloalkyl group having a carbon number of 3 to 15, and examples thereof include a cyclopropyl group, a cyclobutyl group and a cyclohexyl group.

The aryl group, alkyl group and cycloalkyl group of R₂₀₁ to R₂₀₃ each may have, as the substituent, an alkyl group (for example, an alkyl group having a carbon number of 1 to 15), a cycloalkyl group (for example, a cycloalkyl group having a carbon number of 3 to 15), an aryl group (for example, an aryl group having a carbon number of 6 to 14), an alkoxy group (for example, an alkoxy group having a carbon number of 1 to 15), a halogen atom, a hydroxyl group or a phenylthio group. The substituent is preferably a linear or branched alkyl group having a carbon number of 1 to 12, a cycloalkyl group having a carbon number of 3 to 12, or a linear, branched or cyclic alkoxy group having a carbon number of 1 to 12, more preferably an alkyl group having a carbon number of 1 to 4 or an alkoxy group having a carbon number of 1 to 4, The substituent may be substituted to any one of three members R₂₀₁ to R₂₀₃ or may be substituted to all of these three members. In the case where R₂₀₁ to R₂₀₃ are an aryl group, the substituent is preferably substituted at the p-position of the aryl group.

The compound (ZI-2) is described below. The compound (ZI-2) is a compound where R₂₀₁ to R₂₀₃ in formula (ZI) each independently represents an aromatic ring-free organic group. The aromatic ring as used herein includes an aromatic ring containing a heteroatom.

The aromatic ring-free organic group as R₂₀₁ to R₂₀₃ generally has a carbon number of 1 to 30, preferably from 1 to 20.

R₂₀₁ to R₂₀₃ each is independently preferably an alkyl group, a cycloalkyl group, an allyl group or a vinyl group, more preferably a linear, branched or cyclic 2-oxoalkyl group or an alkoxycarbonylmethyl group, still more preferably a linear or branched 2-oxoalkyl group.

The alkyl group as R₂₀₁ to R₂₀₃ may be either linear or branched and preferably includes a linear or branched alkyl group having a carbon number of 1 to 10 (e.g., methyl, ethyl, propyl, butyl, pentyl). The alkyl group as R₂₀₁ to R₂₀₃ is preferably a linear or branched 2-oxoalkyl group or an alkoxycarbonylmethyl group.

The cycloalkyl group as R₂₀₁ to R₂₀₃ preferably includes a cycloalkyl group having a carbon number of 3 to 10 (e.g., cyclopentyl, cyclohexyl, norbornyl). The cycloalkyl group as R₂₀₁ to R₂₀₃ is preferably a cyclic 2-oxoalkyl group.

The linear, branched or cyclic 2-oxoalkyl group as R₂₁₀ to R₂₀₃ preferably includes a group having >C═O at the 2-position of the above-described alkyl or cycloalkyl group.

The alkoxy group in the alkoxycarbonylmethyl group as R₂₀₁ to R₂₀₃ preferably includes an alkoxy group having a carbon number of 1 to 5 (e.g., methoxy, ethoxy, propoxy, butoxy, pentoxy).

R₂₀₁ to R₂₀₃ each may be further substituted by a halogen atom, an alkoxy group (for example, an alkoxy group having a carbon number of 1 to 5), a hydroxyl group, a cyano group or a nitro group.

The compound (ZI-3) is a compound represented by the following formula (ZI-3), and this is a compound having a phenacylsulfonium salt structure.

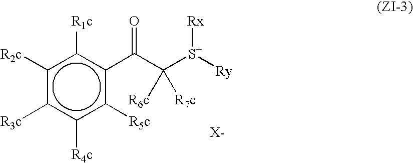

In formula (ZI-3), R_{1c} to R_{5c} each independently represents a hydrogen atom, an alkyl group, a cycloalkyl group, an alkoxy group or a halogen atom.

R_{6c} and R_{7c} each independently represents a hydrogen atom, an alkyl group or a cycloalkyl group.

Rₓ and R_{y} each independently represents an alkyl group, a cycloalkyl group, an allyl group or a vinyl group.

Any two or more members out of R_{1c} to R_{7c} or a pair of Rₓ and R_{y} may combine with each other to form a ring structure, and the ring structure may contain an oxygen atom, a sulfur atom, an ester bond or an amide bond. Examples of the group formed by combining any two or more members out of R_{1c} to R_{7c} or a pair of Rₓ and R_{y} include a butylene group and a pentylene group.

X⁻ represents a non-nucleophilic anion, and examples thereof are the same as those of the non-nucleophilic anion of X⁻ in formula (ZI).

The alkyl group as R_{1c} to R_{7c} may be either linear or branched and is, for example, a linear or branched alkyl group having a carbon number of 1 to 20, preferably a linear or branched alkyl group having a carbon number of 1 to 12 (e.g., methyl, ethyl, linear or branched propyl, linear or branched butyl, linear or branched pentyl).

The cycloalkyl group as R_{1c} to R_{7c} is preferably a cycloalkyl group having a carbon number of 3 to 8 (e.g., cyclopentyl, cyclohexyl).

The alkoxy group as R_{1c} to R_{5c} may be linear, branched or cyclic and is, for example, an alkoxy group having a carbon number of 1 to 10, preferably a linear or branched alkoxy group having a carbon number of 1 to 5 (e.g., methoxy, ethoxy, linear or branched propoxy, linear or branched butoxy, linear or branched pentoxy) or a cyclic alkoxy group having a carbon number of 3 to 8 (e.g., cyclopentyloxy, cyclohexyloxy).

A compound where any one of R_{1c} to R_{5c} is a linear or branched alkyl group, a cycloalkyl group or a linear, branched or cyclic alkoxy group is preferred, and a compound where the sum of carbon numbers of R_{1c} to R_{5c} is from 2 to 15 is more preferred. By virtue of this construction, the solubility in a solvent is more enhanced and generation of particles during storage is suppressed.

Examples of the alkyl group as Rₓ and R_{y} are the same as those of the alkyl group as R_{1c} to R_{7c}. The alkyl group as Rₓ and R_{y} is preferably a linear or branched 2-oxoalkyl group or an alkoxycarbonylmethyl group.

Examples of the cycloalkyl group as Rₓ and R_{y} are the same as those of the cycloalkyl group as R_{1c} to R_{7c}. The cycloalkyl group as Rₓ to R_{y} is preferably a cyclic 2-oxoalkyl group.

Examples of the linear, branched or cyclic 2-oxoalkyl group include a group having >C═O at the 2-position of the alkyl group or cycloalkyl group as R_{1c} to R_{7c}.

Examples of the alkoxy group in the alkoxycarbonylmethyl group are the same as those of the alkoxy group as R_{1c} to R_{5c}.

Rₓ and R_{y} each is preferably an alkyl group having a carbon number of 4 or more, more preferably 6 or more, still more preferably 8 or more.

In formulae (ZII) and (ZIII), R₂₀₄ to R₂₀₇ each independently represents an aryl group, an alkyl group or a cycloalkyl group.

The aryl group of R₂₀₄ to R₂₀₇ is preferably a phenyl group or a naphthyl group, more preferably a phenyl group.

The alkyl group of R₂₀₄ to R₂₀₇ may be either linear or branched and is preferably a linear or branched alkyl group having a carbon number of 1 to 10 (e.g., methyl, ethyl, propyl, butyl, pentyl).

The cycloalkyl group of R₂₀₄ to R₂₀₇ is preferably a cycloalkyl group having a carbon number of 3 to 10 (e.g., cyclopentyl, cyclohexyl, norbornyl).

R₂₀₄ to R₂₀₇ each may have a substituent. Examples of the substituent which R₂₀₄ to R₂₀₇ each may have include an alkyl group (for example, an alkyl group having a carbon number of 1 to 15), a cycloalkyl group (for example, a cycloalkyl group having a carbon number of 3 to 15), an aryl group (for example, an aryl group having a carbon number of 6 to 15), an alkoxy group (for example, an alkoxy group having a carbon number of 1 to 15), a halogen atom, a hydroxyl group and a phenylthio group.

X⁻ represents a non-nucleophilic anion, and examples thereof are the same as those of the non-nucleophilic anion of X⁻ in formula (ZI).

Other examples of the compound capable of generating an acid upon irradiation with actinic rays or radiation include the compounds represented by the following formulae (ZIV), (ZV) and (ZVI):

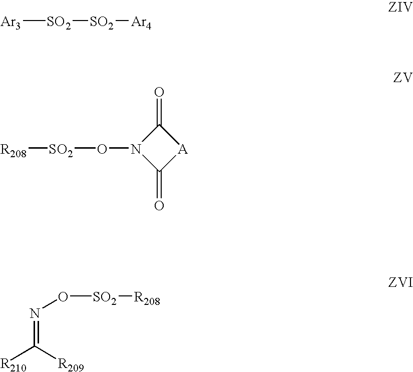

In formulae (ZIV) to (ZVI), Ar₃ and Ar₄ each independently represents an aryl group.

R₂₀₈ represents an alkyl group or an aryl group.

R₂₀₉ and R₂₁₀ each independently represents an alkyl group, an aryl group or an electron-withdrawing group. R₂₀₉ is preferably an aryl group, and R₂₁₀ is preferably an electron-withdrawing group, more preferably a cyano group or a fluoroalkyl group.

A represents an alkylene group, an alkenylene group or an arylene group.

The compound capable of generating an acid upon irradiation with actinic rays or radiation is preferably a compound represented by any one of formulae (ZI) to (ZIII).

The compound (B) is preferably a compound capable of generating a fluorine atom-containing aliphatic sulfonic acid or a fluorine atom-containing benzenesulfonic acid upon irradiation with actinic rays or radiation.

The compound (B) preferably has a triphenylsulfonium structure.

The compound (B) is preferably a triphenylsulfonium salt compound having a non-fluorine-substituted alkyl or cycloalkyl group in the cation moiety.

Out of the compounds capable of generating an acid upon irradiation with actinic rays or radiation, particularly preferred examples are set forth below.

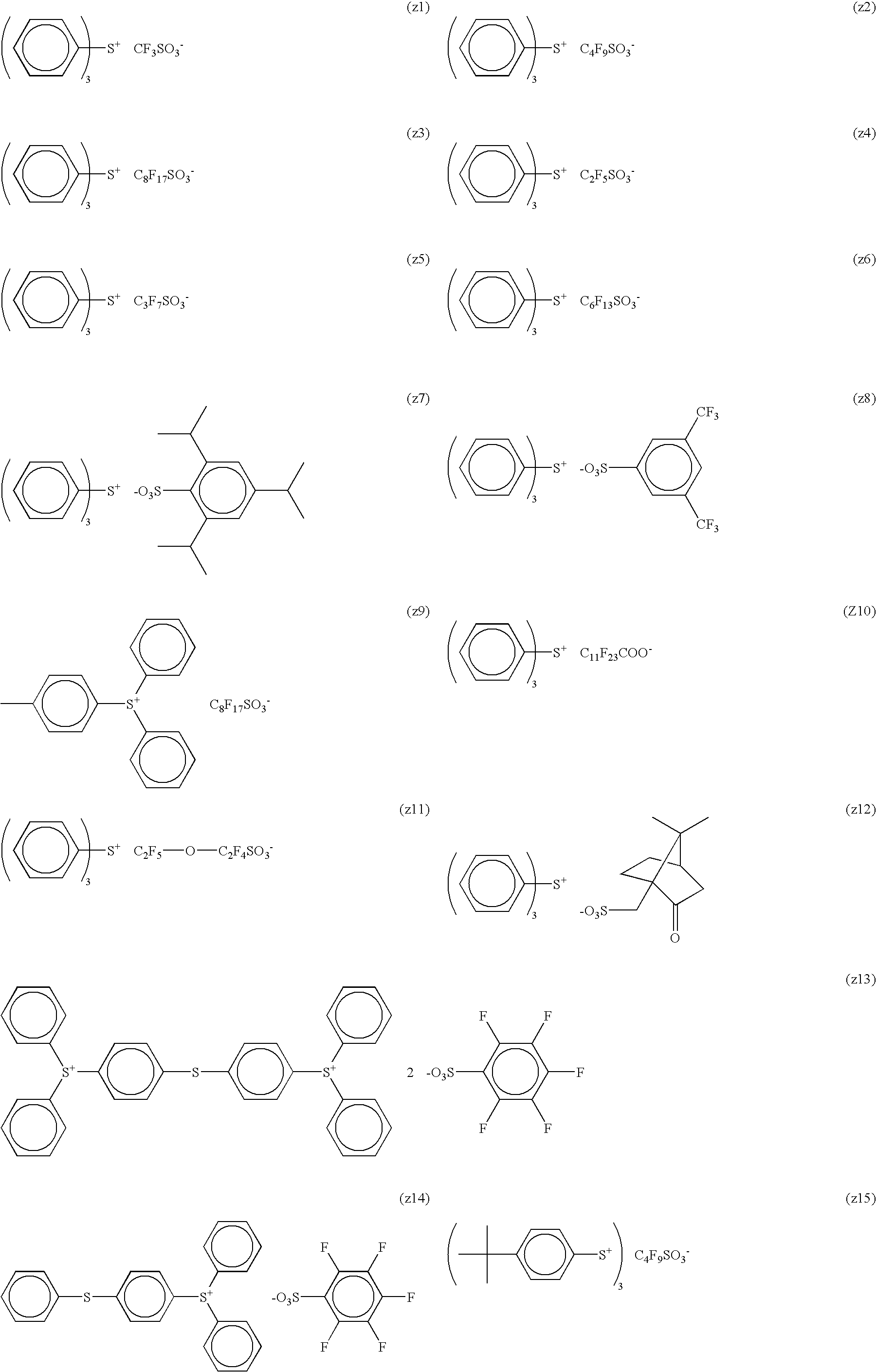

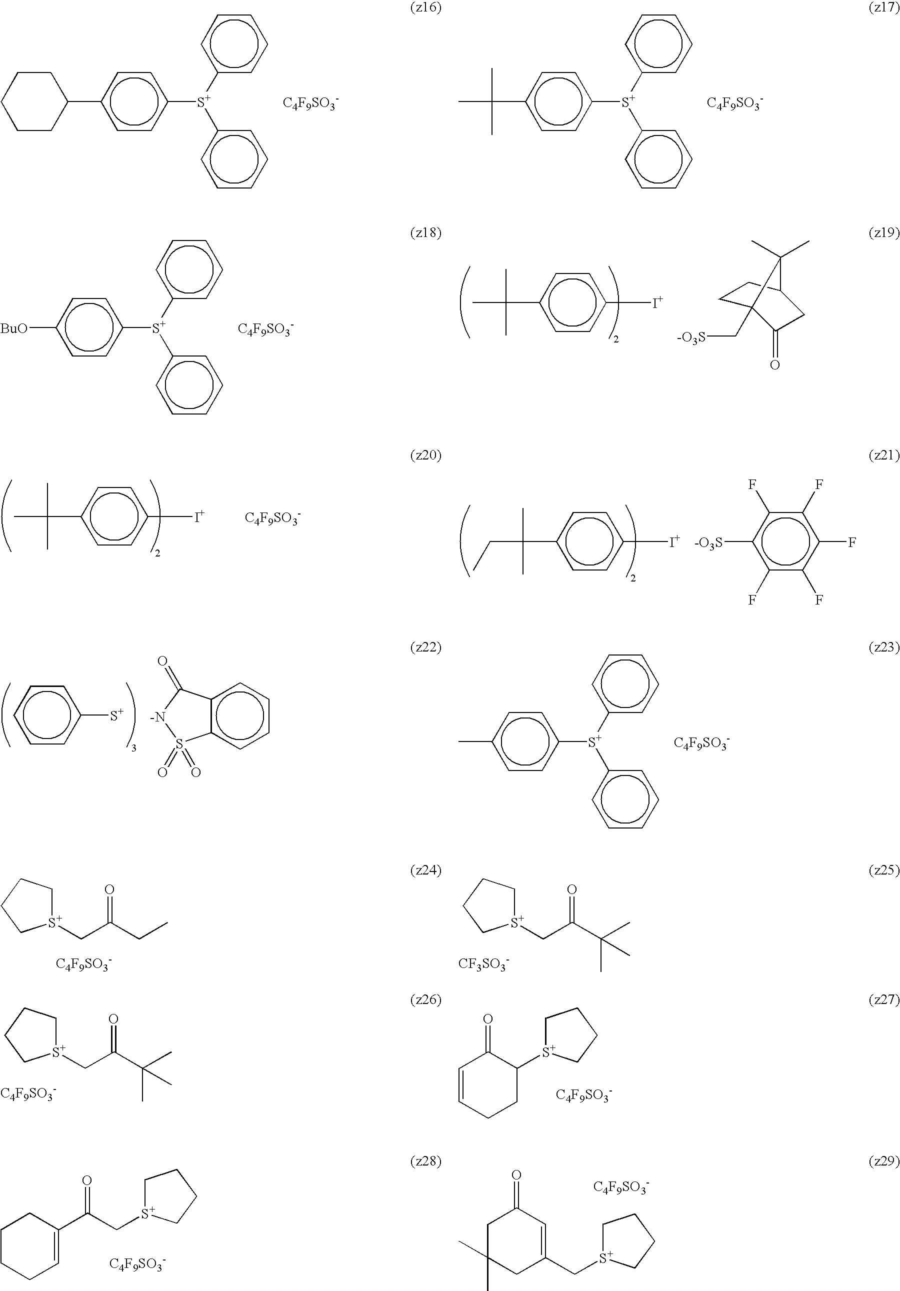

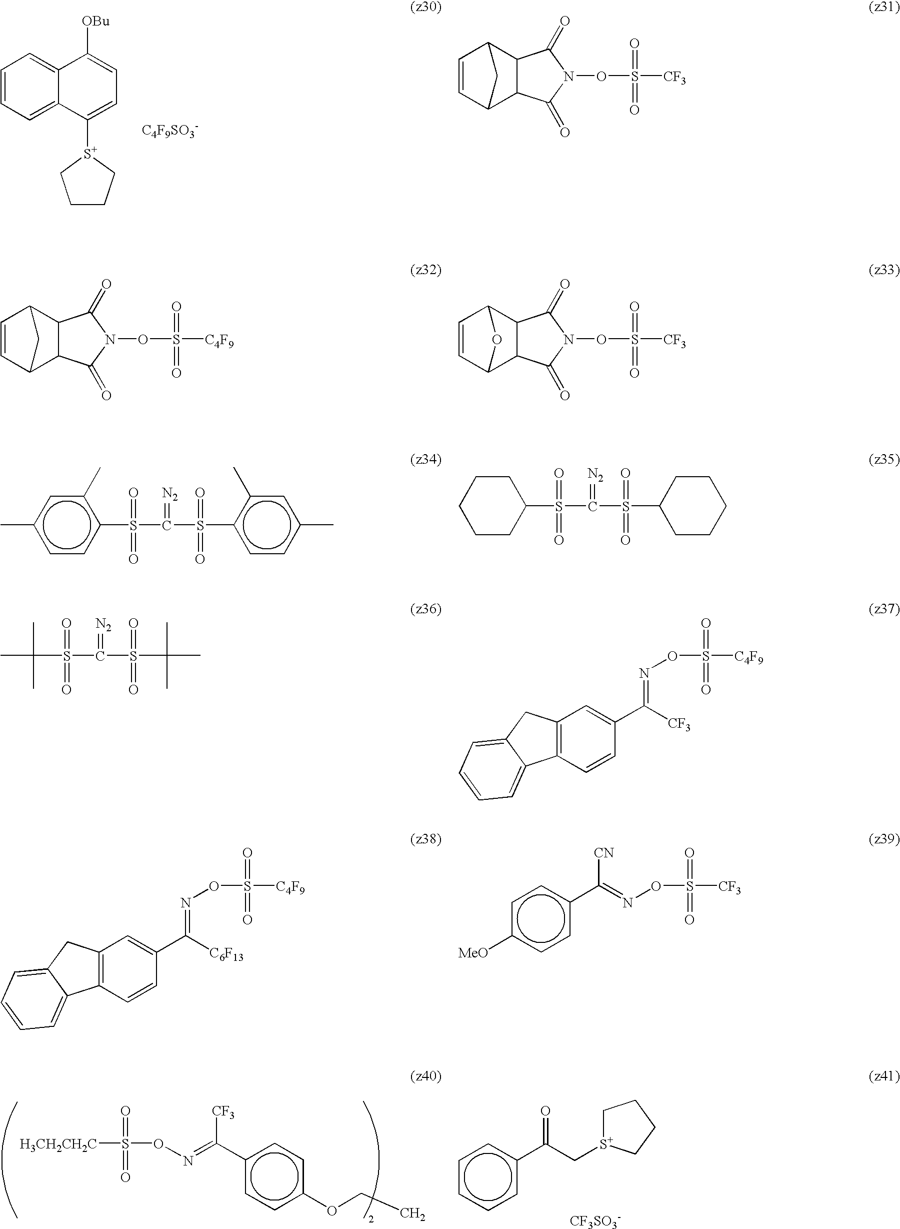

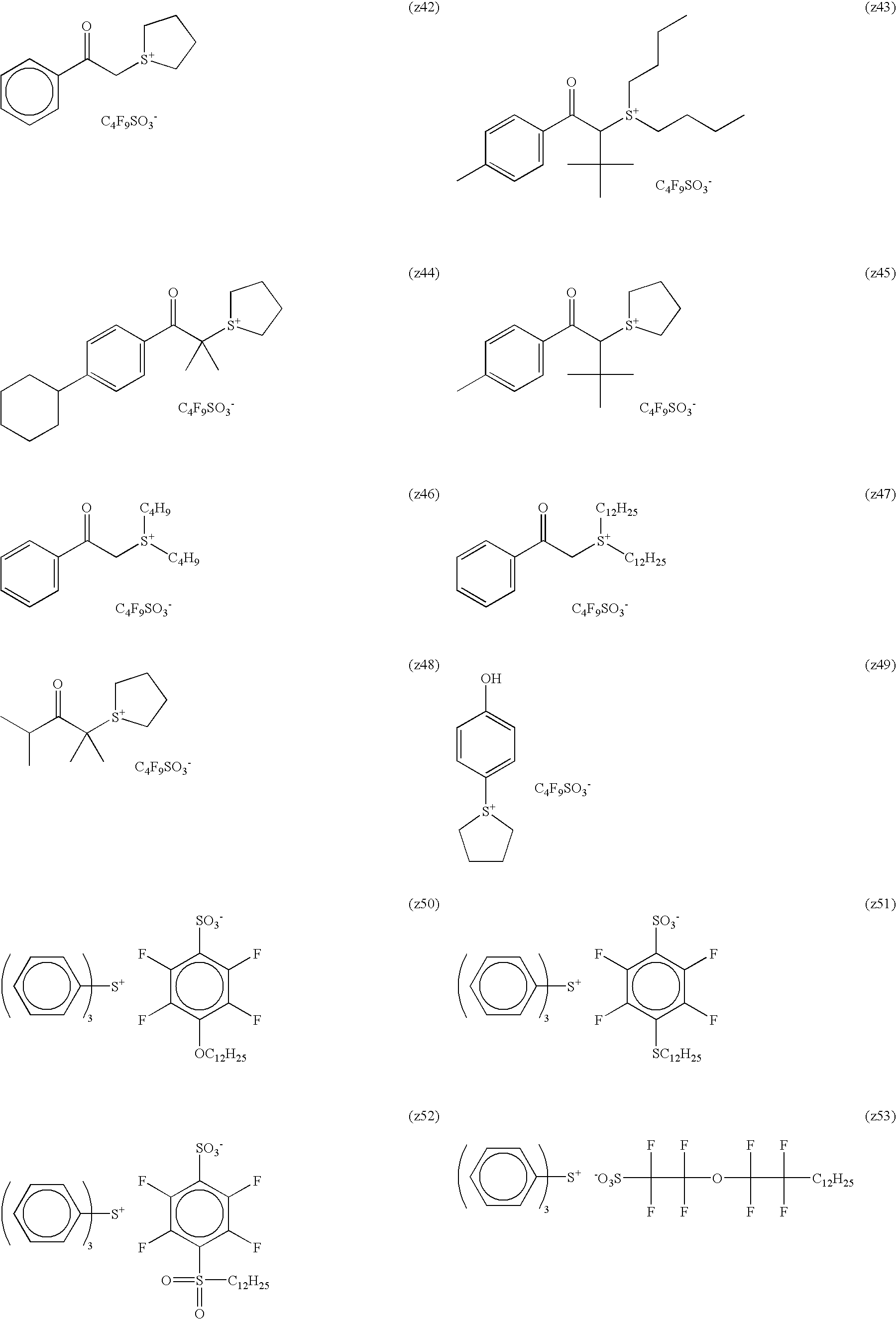

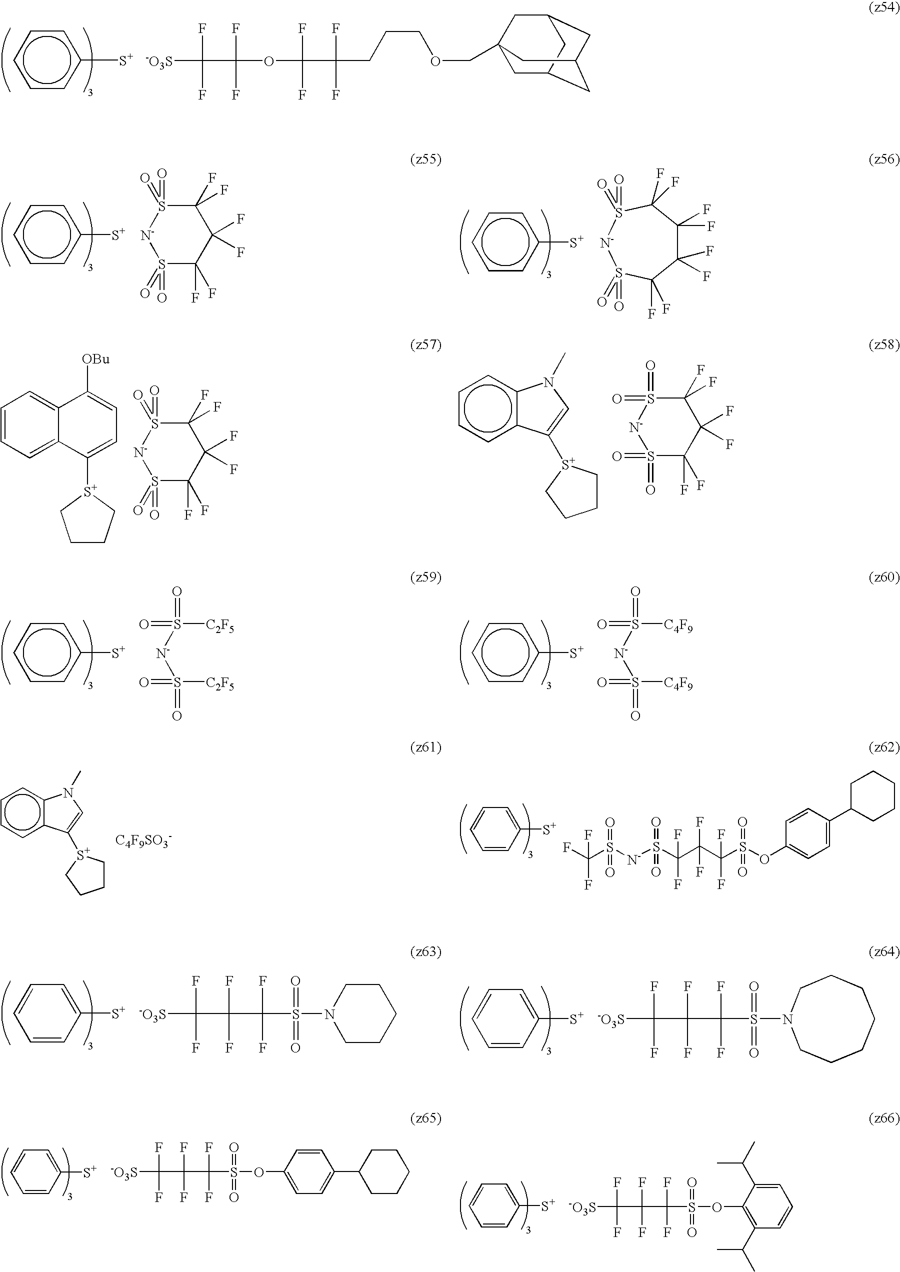

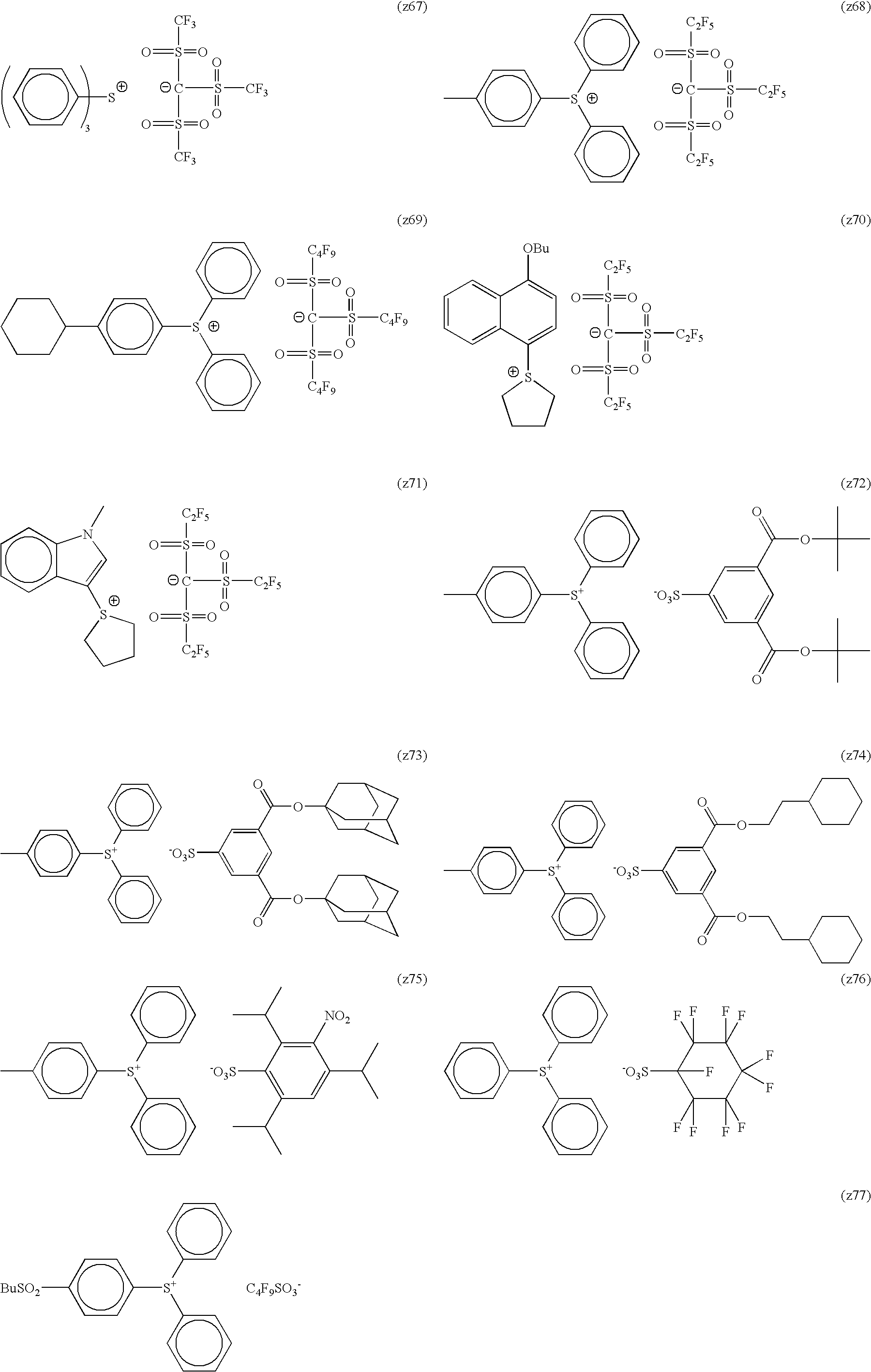

One of these photoacid generators may be used alone, or two or more thereof may be used in combination In the case of using two or more species in combination, compounds capable of generating two kinds of organic acids differing in the total atom number except for hydrogen atom by 2 or more are preferably combined.

The content of the photoacid generator is preferably from 0.1 to 20 mass %, more preferably from 0.5 to 10 mass %, still more preferably from 1 to 7 mass %, based on the entire solid content of the positive resist composition.

### (C) Hydrophobic Resin

The resist composition of the present invention contains a hydrophobic resin (C). The hydrophobic resin (C) is unevenly distributed in the resist film surface layer, so that in the case of using water as the immersion medium, when a resist film is formed, the receding contact angle of the resist film surface for water and in turn the followability of immersion liquid can be enhanced. The hydrophobic resin (C) may be any resin as long as the receding contact angle of the surface can be enhanced by adding the resin, but a rein having at least either a fluorine atom or a silicon atom is preferred. The receding contact angle of the resist film is preferably from 60 to 90°, more preferably from 70° or more. The amount of the resin added may be appropriately adjusted so that the receding contact angle of the resist film can fall in the above-described resin, but the amount added is preferably from 0.1 to 10 mass %, more preferably from 0.1 to 5 mass %, based on the entire solid content of the resist composition.

The hydrophobic resin (C) is unevenly distributed in the interface as described above, but unlike a surfactant, the resin is not necessarily required to have a hydrophilic group in the molecule and may not contribute to uniform mixing of a polar/nonpolar substance.

The hydrophobic resin (C) is preferably a resin having at least either a fluorine atom or a silicon atom.

In the hydrophobic resin (C), the fluorine atom and silicon atom may be present in the main chain of the resin or may be substituted to the side chain.

The hydrophobic resin (C) is preferably a resin having, as the fluorine atom-containing partial structure, a fluorine atom-containing alkyl group, a fluorine atom-containing cycloalkyl group or a fluorine atom-containing aryl group.

The fluorine atom-containing alkyl group (preferably having a carbon number of 1 to 10, more preferably from 1 to 4) is a linear or branched alkyl group with at least one hydrogen atom being substituted by a fluorine atom and may further have another substituent.

The fluorine atom-containing cycloalkyl group is a monocyclic or polycyclic cycloalkyl group with at least one hydrogen atom being substituted by a fluorine atom and may further have another substituent.

The fluorine atom-containing aryl group is an aryl group (e.g., phenyl, naphthyl) with at least one hydrogen atom being substituted by a fluorine atom and may further have another substituent.

Preferred examples of the fluorine atom-containing all group, fluorine atom-containing cycloalkyl group and fluorine atom-containing aryl group include the groups represented by the following formulae (F2) to (F4), but the present invention is not limited thereto.

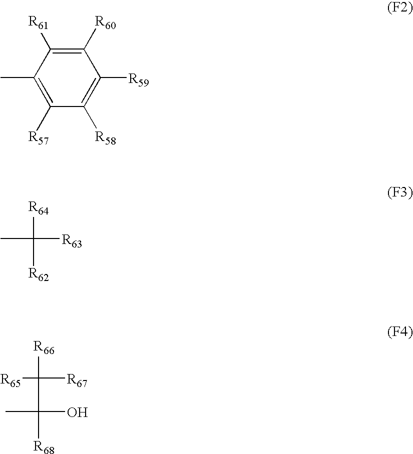

In formulae (F2) to (F4), R₅₇ to R₆₈ each independently represents a hydrogen atom, a fluorine atom or an alkyl group, provided that at least one of R₅₇ to R₆₁, at least one of R₆₂ to R₆₄ and at least one of R₆₅ to R₆₈ are a fluorine atom or an alkyl group (preferably having a carbon number of 1 to 4) with at least one hydrogen atom being substituted by a fluorine atom. It is preferred that R₅₇ to R₆₁ all are a fluorine atom. Also, it is preferred that R₆₅ to R₆₇ all are a fluorine atom and R₆₈ is a trifluoromethyl group. R₆₂, R₆₃ and R₆₈ each is preferably an alkyl group preferably having a carbon number of 1 to 4) with at least one hydrogen atom being substituted by a fluorine atom, more preferably a perfluoroalkyl group having a carbon number of 1 to 4. R₆₂ and R₆₃ may combine with each other to form a ring.

Specific examples of the group represented by formula (F2) include a p-fluorophenyl group, a pentafluorophenyl group and a 3,5-di(trifluoromethyl)phenyl group.

Specific examples of the group represented by formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-tert-butyl group, a perfluoroisopentyl group, a perfluorooctyl group, a perfluoro(trimethyl)hexyl group, a 2,2,3,3-tetrafluorocyclobutyl group and a perfluorocyclohexyl group. Among these, preferred are a hexafluoroisopropyl group, a heptafluoroisopropyl group, a hexafluoro(2-methyl)isopropyl group, an octafluoroisobutyl group, a nonafluoro-tert-butyl group and a perfluoroisopentyl group, more preferred are a hexafluoroisopropyl group and a heptafluoroisopropyl group.

Specific examples of the group represented by formula (F4) include —C(CF₃)₂OH, —C(C₂F₅)₂OH, —C(CF₃)(CH₃)OH and —CH(CF₃)OH, with —C(CF₃)₂OH being preferred.

Specific examples of the repeating unit having a fluorine atom are set forth below, but the present invention is not limited thereto.

In specific examples, X₁ represents a hydrogen atom, —CH₃, —F or —CF₃.

X₂ represents —F or —CF₃.

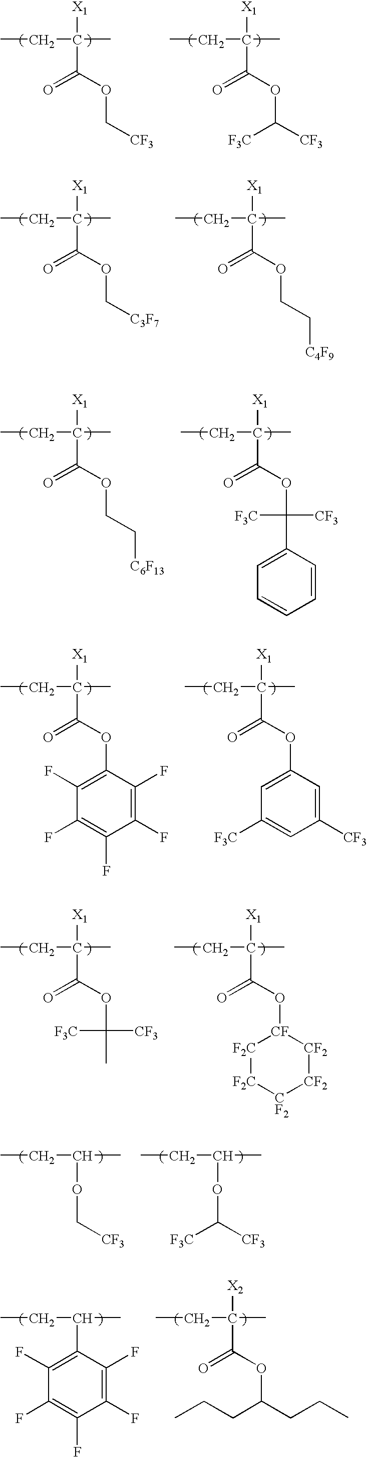

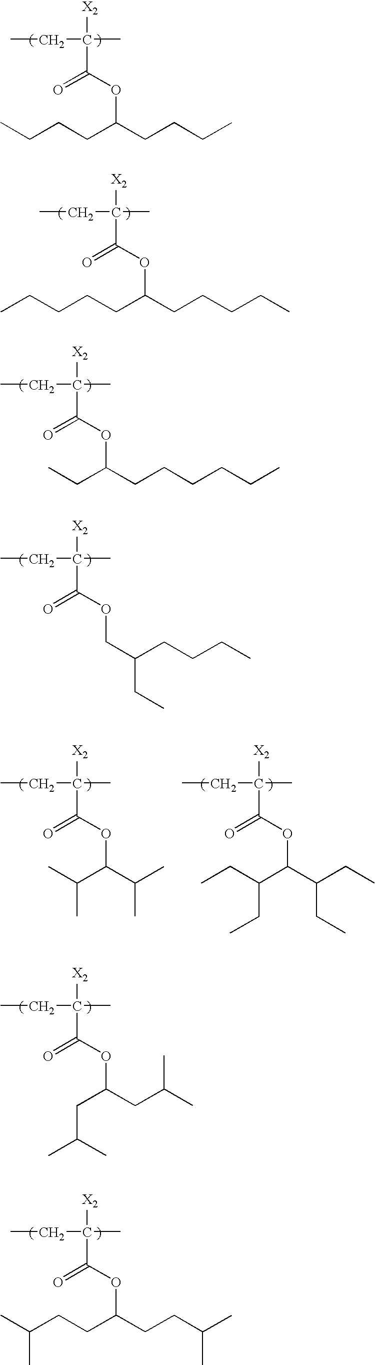

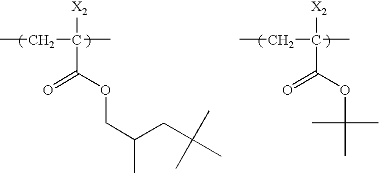

The hydrophobic resin (C) is preferably a resin having, as the silicon atom-containing partial structure, an alkylsilyl structure (preferably a trialkylsilyl group) or a cyclic siloxane structure.

Specific examples of the alkylsilyl structure and cyclic siloxane structure include the groups represented by the following formulae (CS-1) to (CS-3):

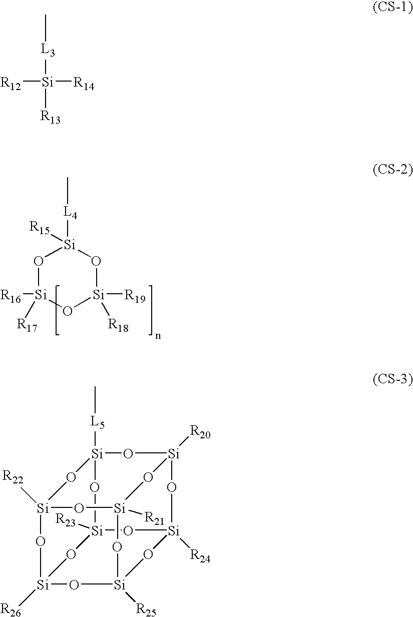

In formulae (CS-1) to (CS-3), R₁₂ to R₂₆ each independently represents an alkyl group (preferably having a carbon number of 1 to 20) or a cycloalkyl group (preferably having a carbon number of 3 to 20).

L₃ to L₅ each represents a single bond or a divalent linking group. The divalent linking group is a sole group or a combination of two or more groups selected from the group consisting of an alkylene group, a phenylene group, an ether group, a thioether group, a carbonyl group, an ester group, an amide group, a urethane group and a ureylene group.

n represents an integer of 1 to 5.

Specific examples of the repeating unit having a silicon atom are set forth below, but the present invention is not limited thereto.

In specific examples, X₁ represents a hydrogen atom, —CH₃, —F or —CF₃.

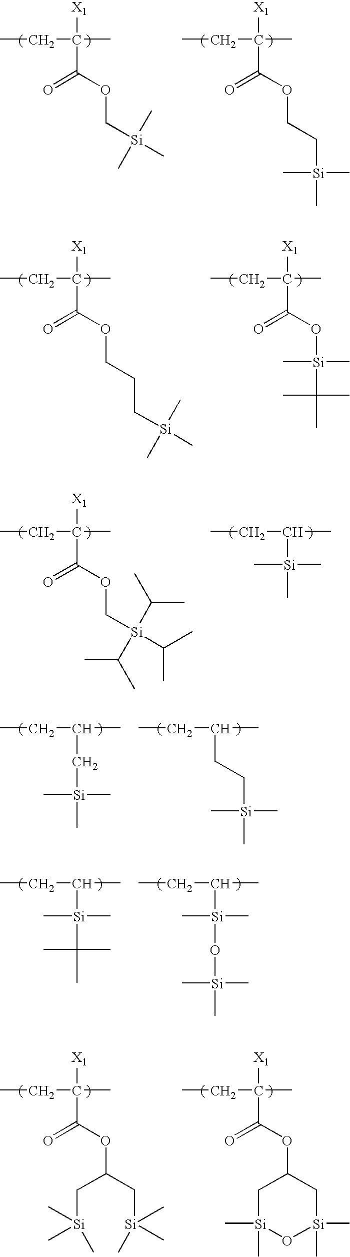

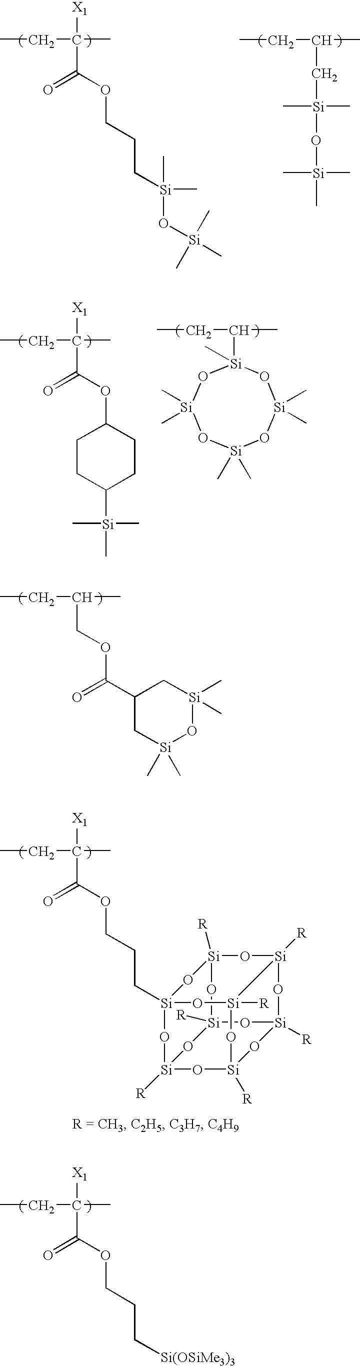

The hydrophobic resin (C) may further contain at least one group selected from the group consisting of the following (x) to (z):

(x) an alkali-soluble group,

(y) a group which decomposes under the action of an alkali developer to increase the solubility in an alkali developer, and

(z) a group which decomposes under the action of an acid.

Examples of the (x) alkali-soluble group include a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkyl-sulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)-imide group, a tris(alkylcarbonyl)methylene group and a tris(alkylsulfonyl)methylene group.

Preferred alkali-soluble groups are a fluorinated alcohol group (preferably a hexafluoroisopropanol group), a sulfonimide group and a bis(carbonyl)methylene group.

As for the repeating unit having (x) an alkali-soluble group, all of a repeating unit where an alkali-soluble group is directly bonded to the resin main chain, such as repeating unit by an acrylic acid or a methacrylic acid, a repeating unit where an alkali-soluble group is bonded to the resin main chain through a linking group, and a repeating unit where an alkali-soluble group is introduced into the polymer chain terminal by using an alkali-soluble group-containing polymerization initiator or chain transfer agent at the polymerization, are preferred.

The content of the repeating unit having (x) an alkali-soluble group is preferably from 1 to 50 mol %, more preferably from 3 to 35 mol %, still more preferably from 5 to 20 mol %, based on all repeating units in the polymer.

Specific examples of the repeating unit having (x) an alkali-soluble group ate set forth below, but the present invention is not limited thereto.

In the formulae, Rx represents H, CH₃, CF₃ or CH₂OH.

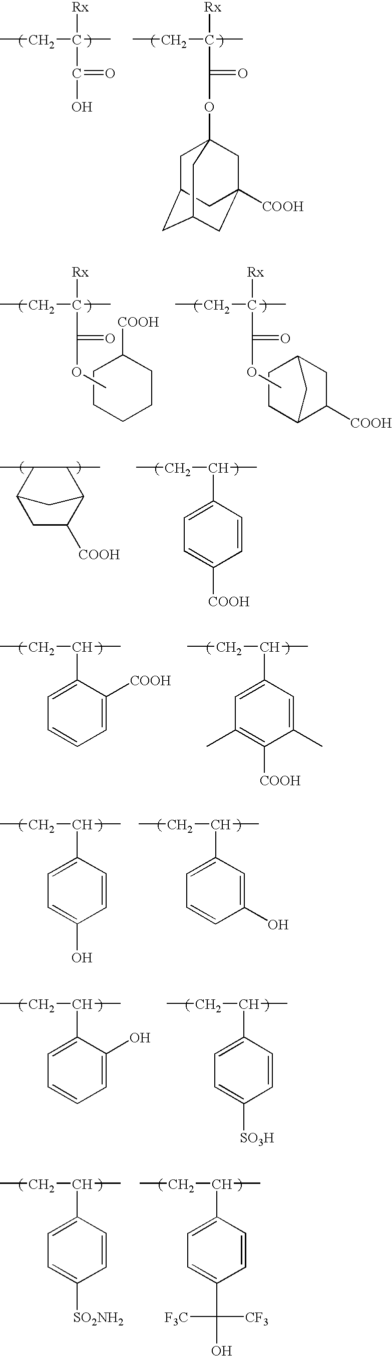

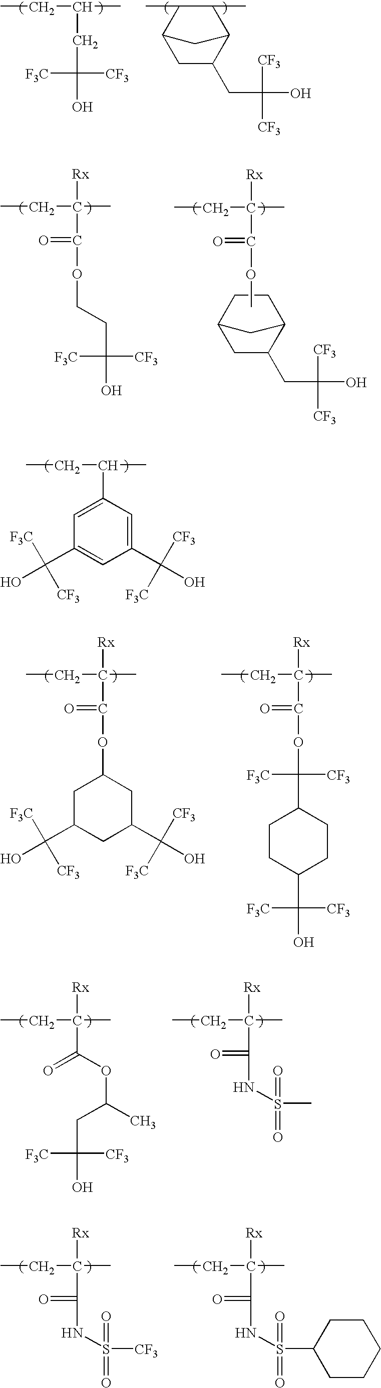

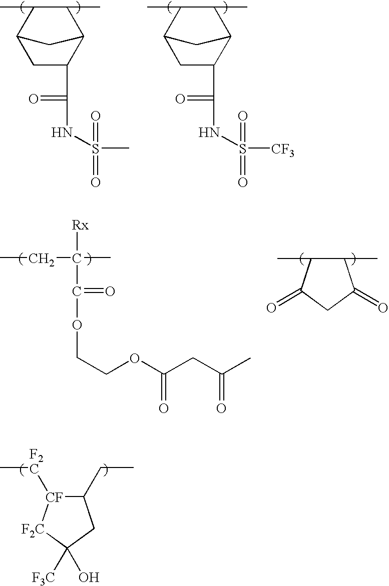

Examples of the (y) group which decomposes under the action of an alkali developer to increase the solubility in an alkali developer include a lactone group, an acid anhydride and an acid imide group, with a lactone group being preferred.

As for the repeating unit having (y) a group which decomposes under the action of an alkali developer to increase the solubility in an alkali developer, both a repeating unit where (y) a group which decomposes under the action of an alkali developer to increase the solubility in an alkali developer is bonded to the resin main chain (for example, a repeating unit by an acrylic acid ester having (y) a group which decomposes under the action of an alkali developer to increases the solubility in an alkali developer, and a repeating unit by a methacrylic acid ester having (y) a group which decomposes under the action of an alkali developer to increase the solubility in an alkali developer), and a repeating unit where (y) a group which decomposes under the action of an alkali developer to increase the solubility in an alkali developer is introduced into the polymer chain terminal by using a polymerization initiator or chain transfer agent having the group at the polymerization, are preferred.

The content of the repeating unit having (y) a group which decomposes under the action of an alkali developer to increase the solubility in an alkali developer is preferably from 1 to 40 mol %, more preferably from 3 to 30 mol %, still more preferably from 5 to 15 mol %, based on all repeating units in the polymer.

Specific examples of the repeating unit having (y) a group which increases in the solubility in an alkali developer are the same as those of the lactone structure described for the resin (A) and the structure represented by formula (VIII).

Examples of the (z) group which decomposes under the action of an acid are the same as those of the acid-decomposable group described for the resin (A). Examples of the repeating unit having (z) a group which decomposes under the action of an acid are the same as those of the repeating unit having an acid-decomposable group described for the resin (A). The content of the repeating unit having (z) a group which decomposes under the action of an acid is preferably from 1 to 80 mol %, more preferably from 10 to 80 mol %, still more preferably from 20 to 60 mol %, based on all repeating units in the hydrophobic resin (C).

The hydrophobic resin (C) may further contain a repeating unit represented by the following formula (III).

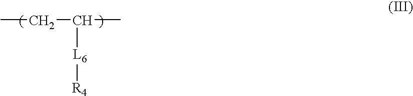

In formula (III), R₄ represents a group having an alkyl group, a cycloalkyl group, an alkenyl group or a cycloalkenyl group.

L₆ represents a single bond or a divalent linking group.

In formula (III), the alkyl group of R₄ is preferably a linear or branched alkyl group having a carbon number of 3 to 20.

The cycloalkyl group is preferably a cycloalkyl group having a carbon number of 3 to 20.

The aryl group is preferably an aryl group having a carbon number of 6 to 20.

The alkenyl group is preferably an alkenyl group having a carbon number of 3 to 20.

The cycloalkenyl group is preferably a cycloalkenyl group having a carbon number of 3 to 20.

The divalent linking group of L₆ is preferably an alkylene group (preferably having a carbon number of 2 to 5), an oxy group or a carbonyloxy group.

The hydrophobic resin (C) preferably has a group represented by the following formula (F3a):

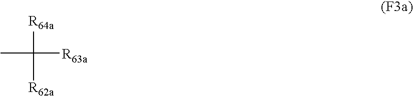

In formula (F3a), R₆₂ₐ and R₆₃ₐ each independently represents an alkyl group with at least one hydrogen atom being substituted by a fluorine atom, and R₆₂ₐ and R₆₃ₐ may combine with each other to form a ring; and

R₆₄ₐ represents a hydrogen atom, a fluorine atom or an alkyl group.

The repeating unit having a group represented by formula (F3a) includes a repeating unit by an acrylate or methacrylate having a group represented by formula (F3a).

The hydrophobic resin (C) preferably contains a repeating unit represented by the following formula (Ia):

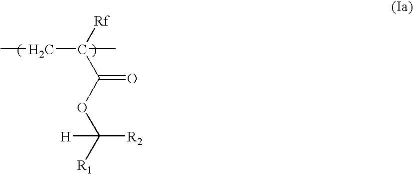

In formula (Ia), Rf represents a fluorine atom or an alkyl group with at least one hydrogen atom being substituted by a fluorine atom.

R₁ represents an alkyl group.

R₂ represents a hydrogen atom or an alkyl group.

In formula (Ia), the alkyl group with at least one hydrogen atom being substituted by a fluorine atom of Rf is preferably an alkyl group having a carbon number of 1 to 3, more preferably a trifluoromethyl group.

The alkyl group of R₁ is preferably a linear or branched alkyl group having a carbon number of 3 to 10, more preferably a branched alkyl group having a carbon number of 3 to 10.

The alkyl group of R₂ is preferably a linear or branched alkyl group having a carbon number of 1 to 10.

Specific examples of the repeating unit represented by formula (Ia) are set forth below, but the present invention is not limited thereto.

X represents —H, —CH₃, —F or —CF₃.

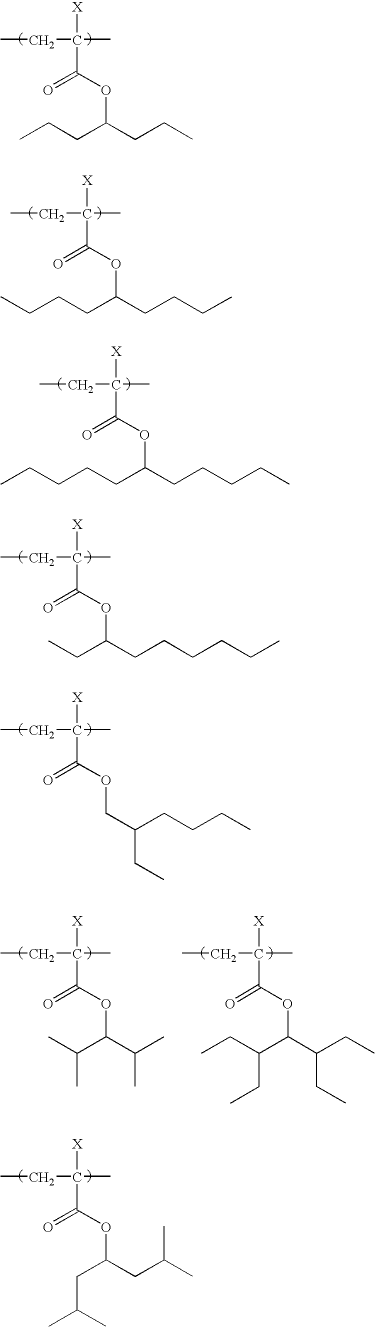

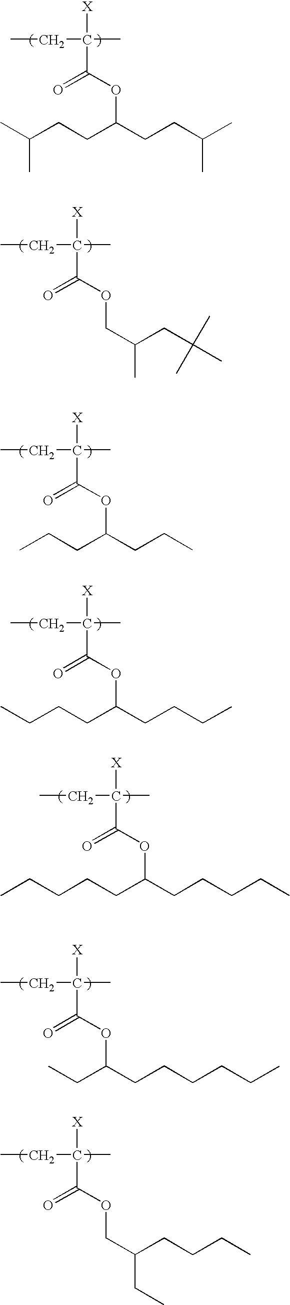

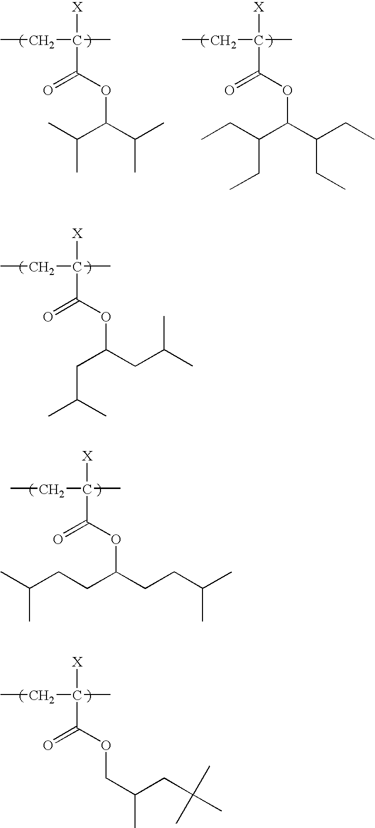

The repeating unit represented by formula (Ia) can be formed by polymerizing a compound represented by the following formula (I):

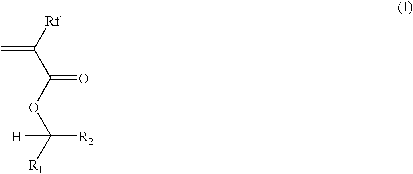

In formula (I), Rf represents a fluorine atom or an alkyl group with at least one hydrogen atom being substituted by a fluorine atom.

R₁ represents an alkyl group.

R₂ represents a hydrogen atom or an alkyl group.

Rf, R₁ and R₂ in formula (I) have the same meanings as Rf, R₁ and R₂ in formula (Ia).

As for the compound represented by formula (I), a commercially available product or a compound synthesized may be used. In the case of synthesizing the compound, the compound can be obtained by converting a 2-trifluoromethyl methacrylic acid into an acid chloride and then esterifying the acid chloride.

The hydrophobic resin (C) is preferably a resin containing a repeating unit represented by the following formula (II) and a repeating unit represented by the following formula (III):

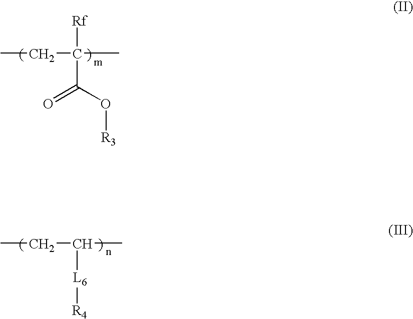

In formulae (II) and (III), Rf represents a fluorine atom or an alkyl group with at least one hydrogen atom being substituted by a fluorine atom.

R₃ represents an alkyl group, a cycloalkyl group, an alkenyl group or a cycloalkenyl group.

R₄ represents an alkyl group, a cycloalkyl group, an alkenyl group, a cycloalkenyl group, a trialkylsilyl group or a group having a cyclic siloxane structure.

L₆ represents a single bond or a divalent linking group.

m and n define the ratio of repeating units and represent numerals of 0<m<100 and 0<n<100.

In formula (II), Rf has the same meaning as Rf in formula (Ia).

The alkyl group of R₃ is preferably a linear or branched alkyl group having a carbon number of 3 to 20.

The cycloalkyl group is preferably a cycloalkyl group having a carbon number of 3 to 20.

The alkenyl group is preferably an alkenyl group having a carbon number of 3 to 20.

The cycloalkenyl group is preferably a cycloalkenyl group having a carbon number of3 to 20.

m=30 to 70 and n=30 to 70 are preferred, and m=40 to 60 and n=40 to 60 are more preferred.

Specific examples of the hydrophobic resin (C) containing a repeating unit represented by formula (II) and a repeating unit represented by formula (III) are set forth below, but the present invention is not limited thereto.

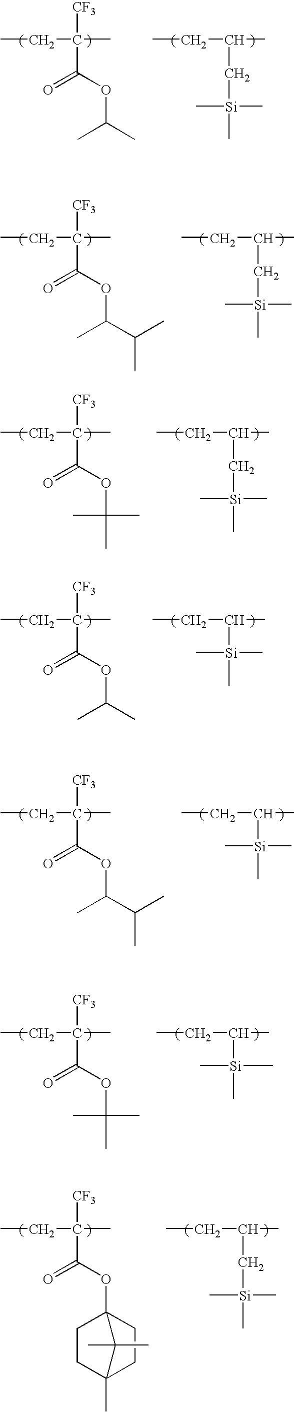

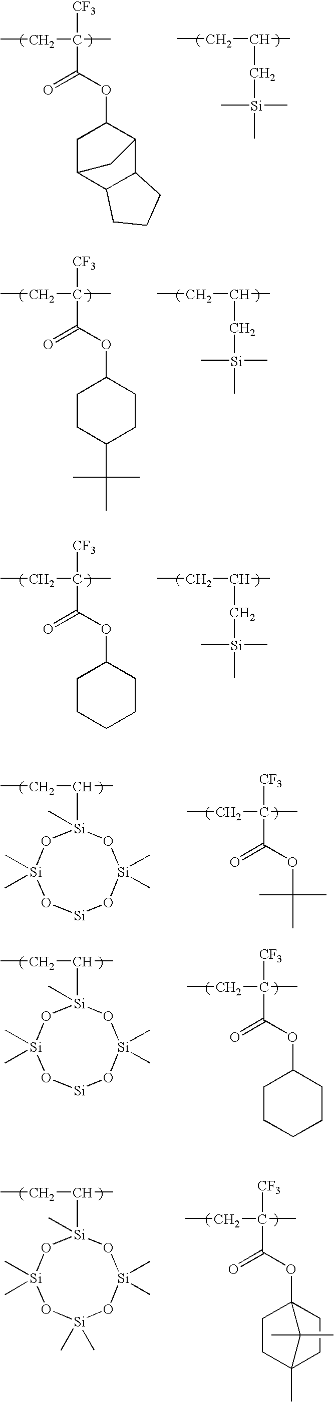

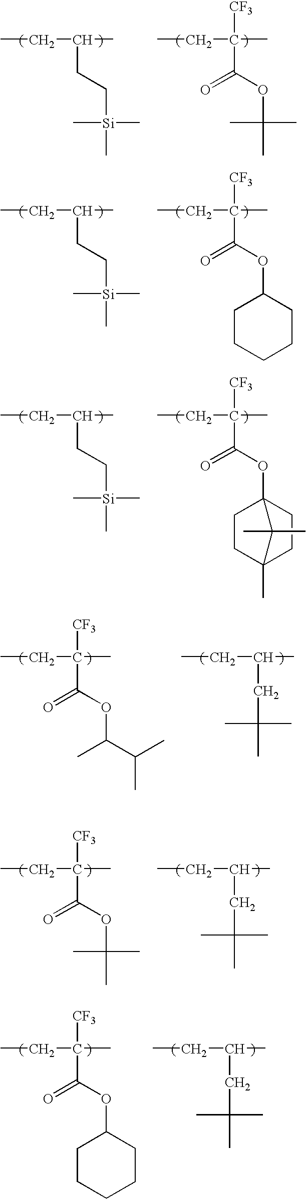

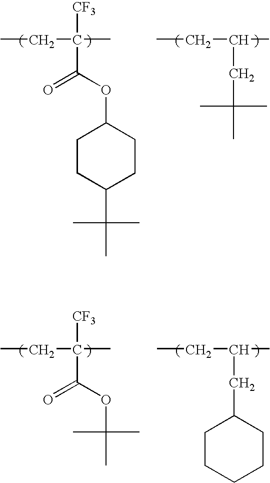

In the case where the hydrophobic resin (C) contains a fluorine atom, the fluorine atom content is preferably from 5 to 80 mass %, more preferably from 10 to 80 mass %, based on the molecular weight of the hydrophobic resin (C). Also, tie fluorine atom-containing repeating unit preferably occupies from 10 to 100 mass %, more preferably from 30 to 100 mass %, in the hydrophobic resin (C).

In the case where the hydrophobic resin (C) contains a silicon atom, the silicon atom content is preferably from 2 to 50 mass %, more preferably from 2 to 30 mass %, based on the molecular weight of the hydrophobic resin (C). Also, the silicon atom-containing repeating unit preferably occupies from 10 to 100 mass %, more preferably from 20 to 100 mass %, in the hydrophobic resin (C).

The weight average molecular of the hydrophobic resin (C) in terms of standard polystyrene is preferably from 500 to 50,000, more preferably from 1,000 to 15,000, still more preferably from 1,500 to 8,000, yet still more preferably from 2,000 to 6,000, and most preferably from 4,000 to 5,500.

Similarly to the resin (A), the hydrophobic resin (C) preferably has, of course, a small content of impurities such as metal, and the content of the residual monomer or oligomer component is preferably from 0 to 10 mass %, more preferably from 0 to 5 mass %, still more preferably from 0 to 1 mass %. When these conditions are satisfied, a resist free from foreign matters in liquid or change in the sensitivity or tle like with aging can be obtained. Also, in view of resolution, resist profile, side wall roughness of resist pattern, development scum and the like, the molecular weight distribution (Mw/Mn, also called dispersity) is preferably from 1 to 3, more preferably from 1 to 2, still more preferably from 1 to 1.6, yet still more preferably from 1 to 1.3.

As for the hydrophobic resin (C), various commercially available products may be used or the resin may be synthesized by an ordinary method (for example, radical polymerization). Examples of the synthesis method in general include a batch polymerization method of dissolving monomers and a polymerization initiator in a solvent and heating the solution, thereby effecting the polymerization, and a dropping polymerization method of adding dropwise a solution containing monomers and a polymerization initiator to a heated solvent over 1 to 10 hours. A dropping polymerization method is preferred. Examples of the solvent include tetrahydrofuran, 1,4-dioxane, ethers (e.g., diisopropyl ether), ketones (e g., methyl ethyl ketone, methyl isobutyl ketone), esters (e.g., ethyl acetate), amides (e.g., dimethylformamide, dimethylacetamide), and a solvent capable of dissolving the composition of the present invention, which is described later, such as propylene glycol monomethyl ether acetate, propylene glycol monomethyl ether and cyclohexanone. The polymerization is more preferably performed using the same solvent as the solvent used in the positive resist composition of the present invention. By the use of this solvent, generation of particles during storage can be suppressed.

The polymerization reaction is preferably performed in an inert gas atmosphere such as nitrogen and argon. As for the polymerization initiator, the polymerization is started using a commercially available radical polymerization initiator (e.g., azo-based polymerization initiator, peroxide). The radical polymerization initiator is preferably an azo-based polymerization initiator, and an azo-based polymerization initiator having an ester group, a cyano group or a carboxyl group is preferred. Preferred examples of the polymerization initiator include azobisisobutyronitrile, azobisdimethylvaleronitrile and dimethyl 2,2′-azobis(2-methylpropionate). The concentration of the solute such as monomer or polymerization initiator in the reaction solution is usually from 5 to 50 mass %, preferably from 30 to 50 mass %, and the reaction temperature is usually from 10 to 150° C., preferably from 30 to 120° C., more preferably from 60 to 100° C.

After the completion of reaction, the reaction solution is allowed to cool to room temperature and purified. The purification may be performed by a normal method, for example, a liquid-liquid extraction method of applying water washing or combining an appropriate solvent to remove residual monomers or oligomer components; a purification method in a solution sate, such as ultrafiltration of removing by extraction only polymers having a molecular weight lower than a specific molecular weight; a reprecipitation method of adding dropwise the resin solution in a bad solvent to solidify the resin in the bad solvent and thereby remove residual monomers or the like; and a purification method in a solid state, such as washing of a resin slurry separated by filtration with a bad solvent. For example, the resin is precipitated as a solid through contact with a solvent in which the resin is sparingly soluble or insoluble (bad solvent) and which is in a volume amount of 10 times or less, preferably from 10 to 5 times, the reaction solution.

The solvent used at the operation of precipitation or reprecipitation from the polymer solution (precipitation or reprecipitation solvent) may be sufficient if it is a bad solvent for the polymer, and may be appropriately selected from, for example, a hydrocarbon, a halogenated hydrocarbon, a nitro compound, an ether, a ketone, an ester, a carbonate, an alcohol, a carboxylic acid, water, and a mixed solvent containing such a solvent. Among these, the precipitation or reprecipitation solvent is preferably a solvent containing at least an alcohol particularly methanol or the like) or water.

The amount of the precipitation or reprecipitation solvent used may be appropriately selected by considering the efficiency, yield and the like, but in general, the amount used is from 100 to 10,000 parts by mass, preferably from 200 to 2,000 parts by mass, more preferably from 300 to 1,000 parts by mass, per 100 parts by mass of the polymer solution.

The temperature at the precipitation or reprecipitation may be appropriately selected by considering the efficiency or operability, but the temperature is usually on the order of 0 to 50° C., preferably in the vicinity of room temperature (for example, approximately from 20 to 35° C.). The precipitation or reprecipitation operation may be performed using a commonly employed mixing vessel such as stirring tank by a known method such as batch system and continuous system.

The precipitated or reprecipitated polymer is usually subjected to commonly employed solid-liquid separation such as filtration and centrifugation, then dried and used. The filtration is performed using a solvent-resistant filter element preferably under pressure. The drying is performed under atmospheric pressure or reduced pressure (preferably under reduced pressure) at a temperature of usually on the order of 30 to 100° C., preferably on the order of 30 to 50° C.

Incidentally, after the resin is once precipitated and separated, the resin may be again dissolved in a solvent and then put into contact with a solvent in which the resin is sparingly soluble or insoluble. More specifically, there may be used a method where after the completion of radical polymerization reaction, the polymer is put into contact with a solvent in which the polymer is sparingly soluble or insoluble, thereby precipitating a resin (step a), the resin is separated from the solution (step b), the resin is anew dissolved in a solvent to prepare a resin solution A (step c), the resin solution A is put into contact with a solvent in which the resin is sparingly soluble or insoluble and which is in a volume amount of less than 10 times (preferably a volume amount of 5 times or less) the resin solution A, thereby precipitating a resin solid (step d), and the precipitated resin is separated (step e).

The “weight average molecular weight of resin (A)−weight average molecular weight of hydrophobic resin (C)” (sometimes referred to as a “weight average molecular weight difference”) is 3,000 or more or about 3,000 or more, preferably 4,000 or more or about 4,000 or more, more preferably 5,000 or more or about 5,000 or more. The weight average molecular weight difference is preferably 20,000 or less or about 20,000 or less, more preferably 10,000 or less or about 10,000 or less, still more preferably 8,000 or less or about 8,000 or less, yet still more preferably 7,000 or less or about 7,000 or less.

When the weight average molecular weight difference is 3,000 or more or about 3,000 or more, the dissolution rate of the resist surface increases and this allows less formation of a pattern with a T-top profile and enables enhancing the performance in terms of pattern collapse and improving the development defect.

Specific examples of the hydrophobic resin (C) are set forth below, but the present invention is not limited thereto. Also, the repeating unit composition (molar ratio, corresponding to respective repeating units in sequence from the left), weight average molecular weight (Mw) and dispersity (Mw/Mn) of each resin are shown in Table 1 below.

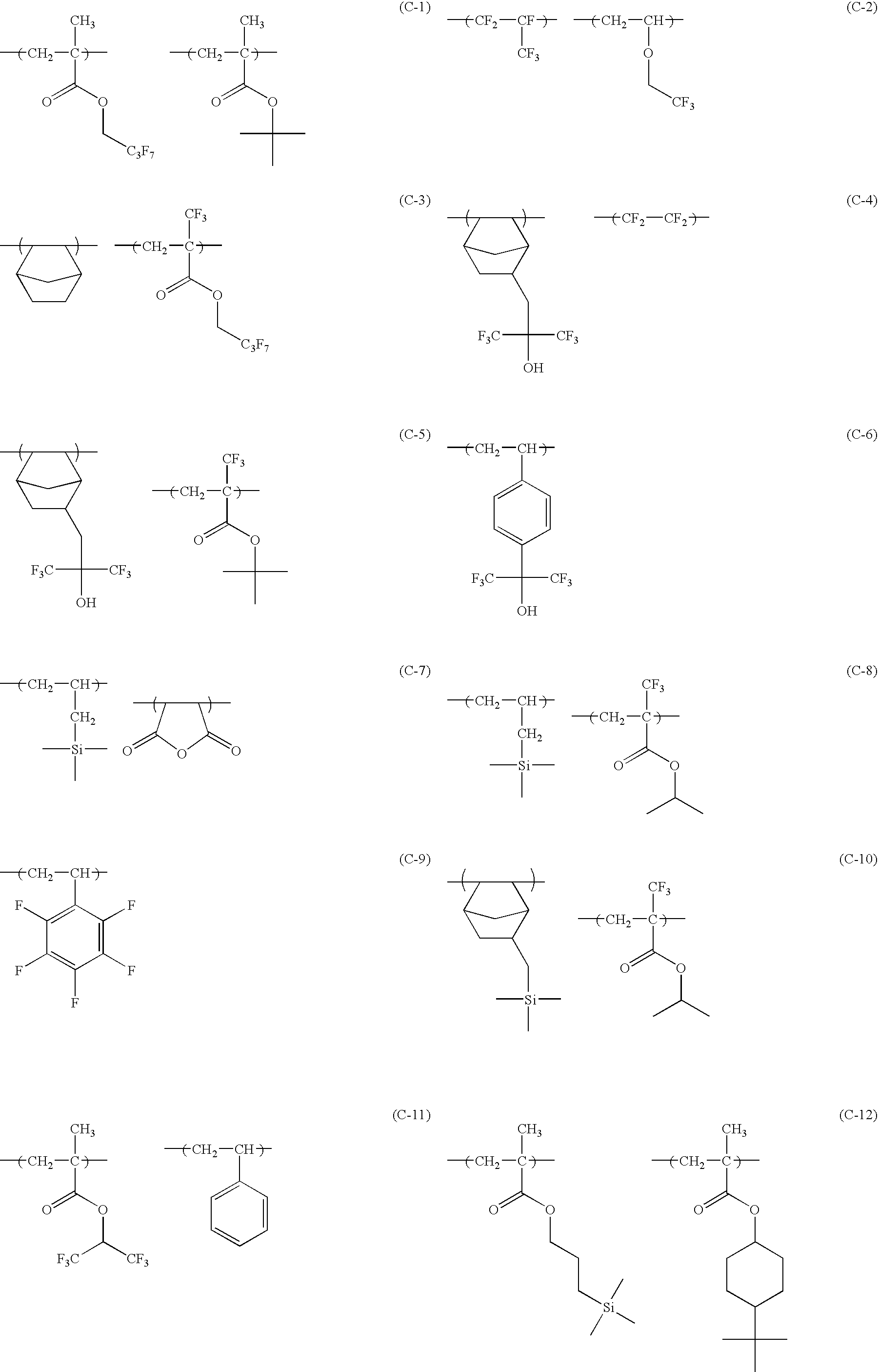

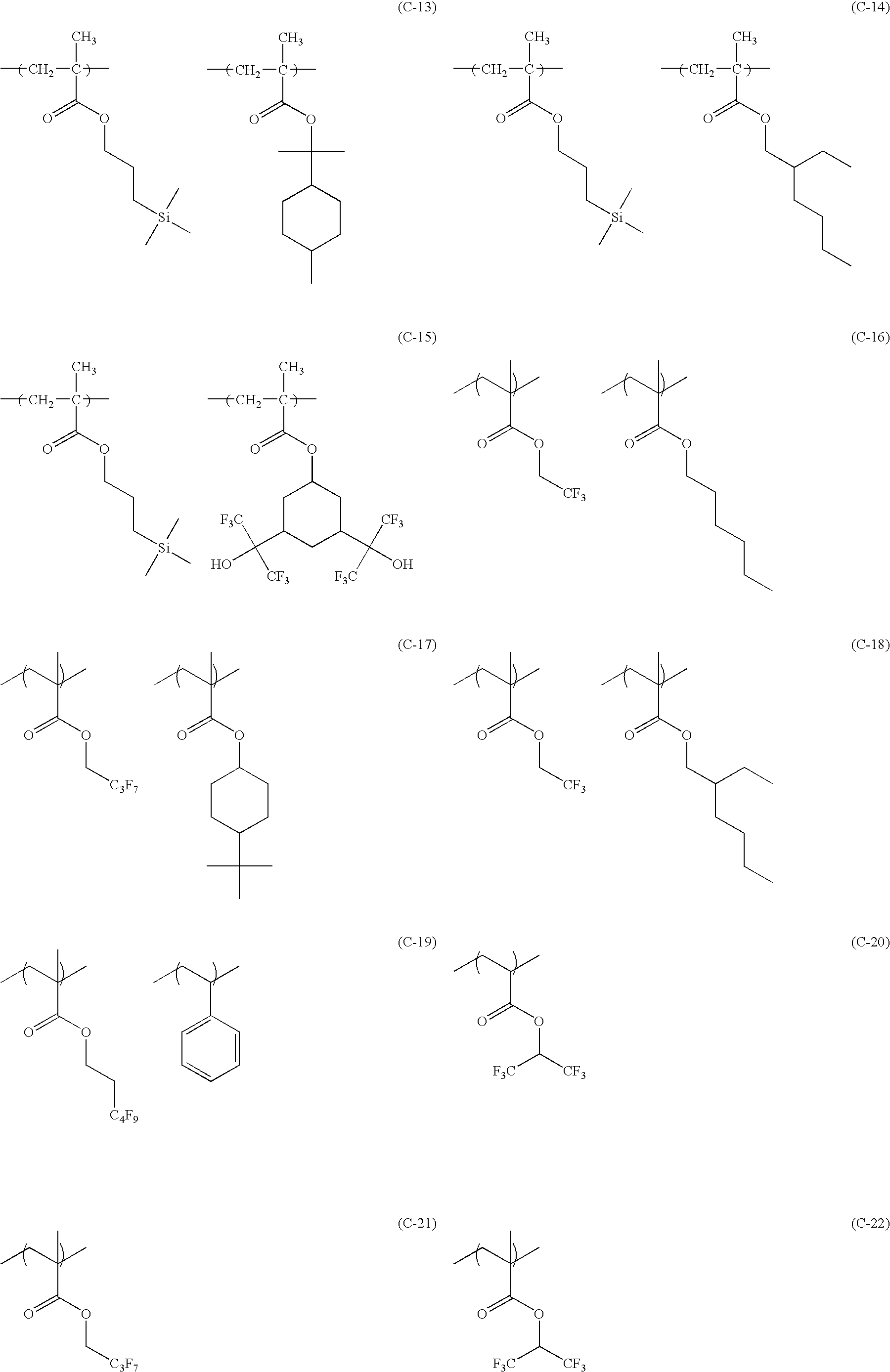

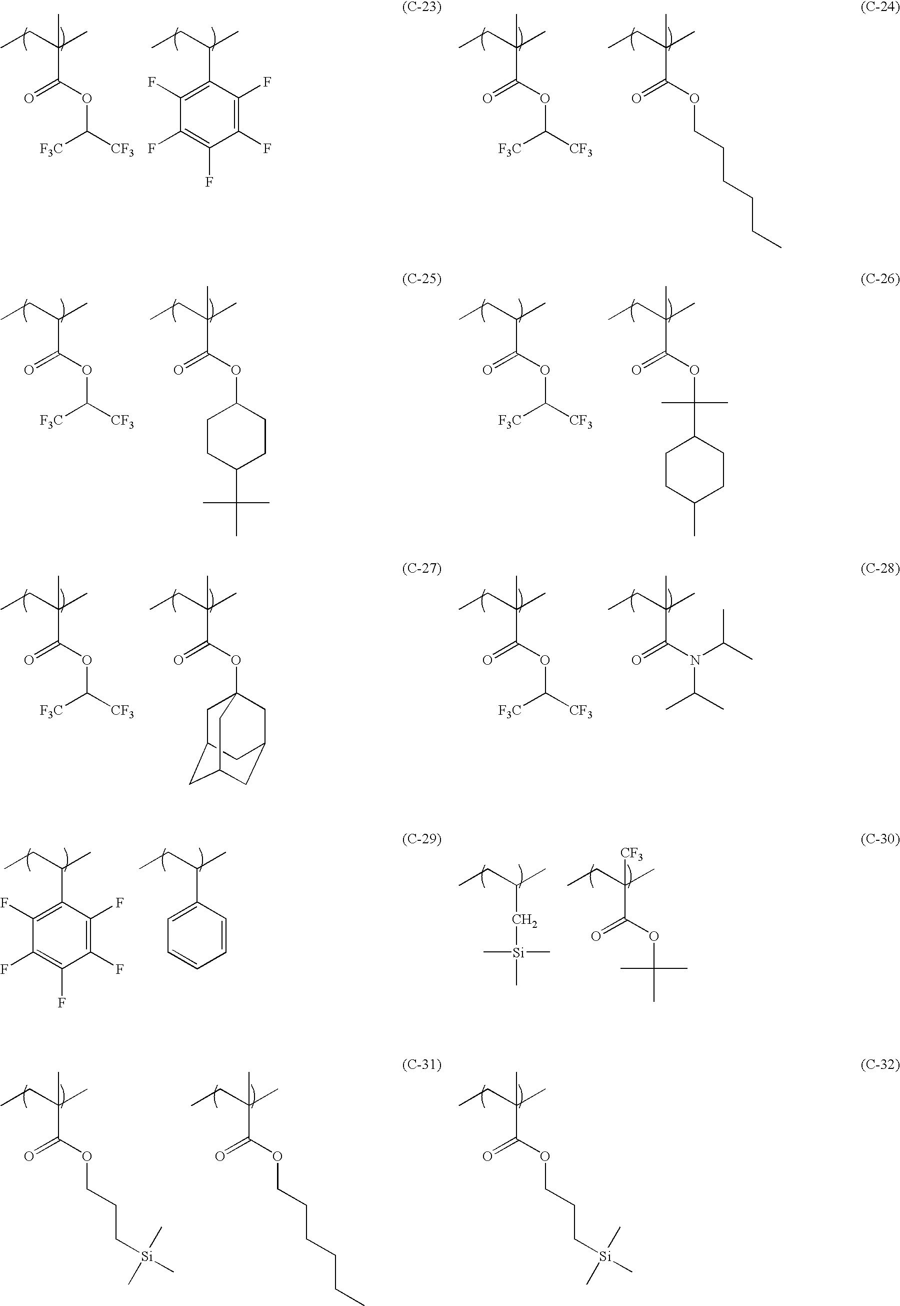

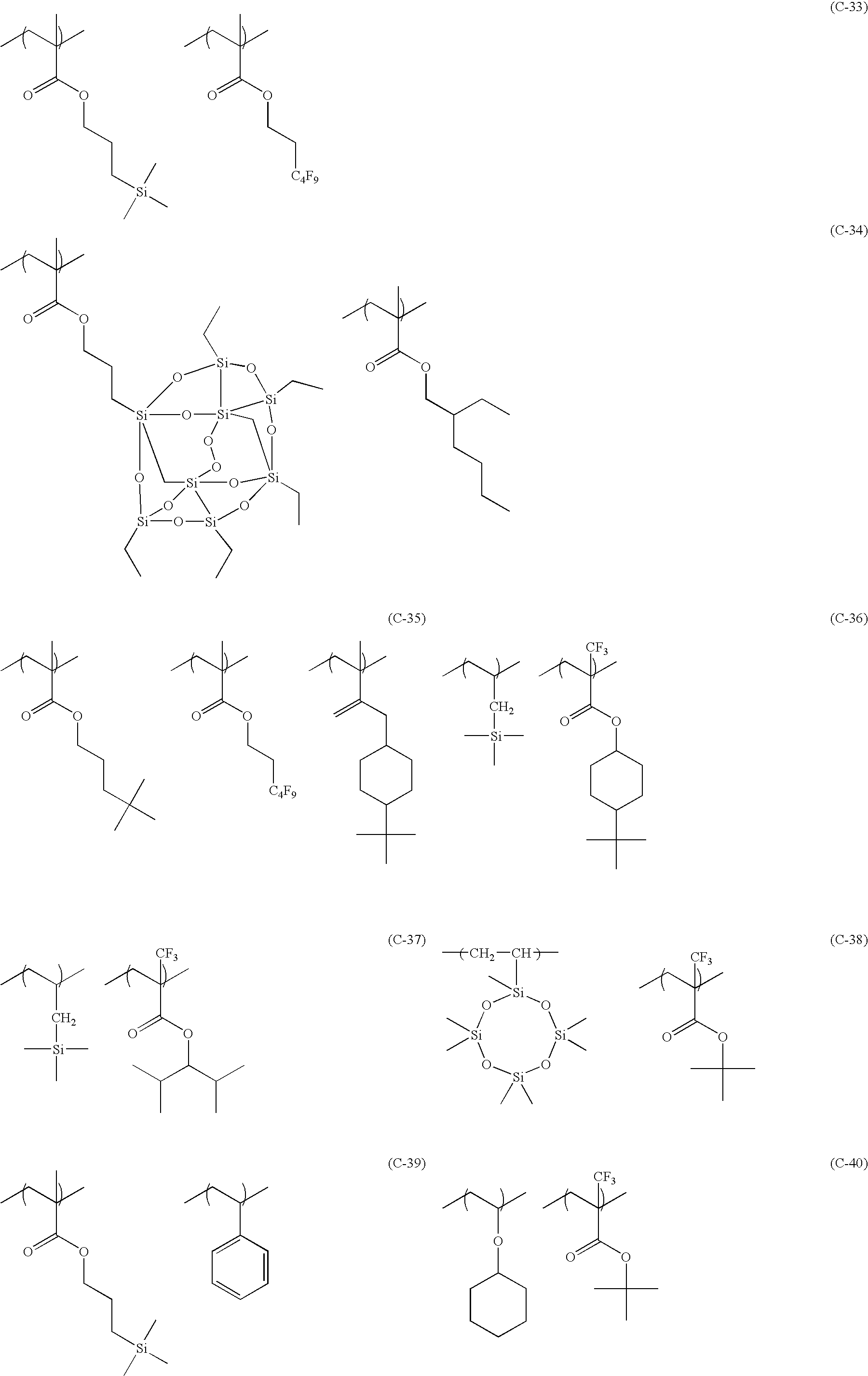

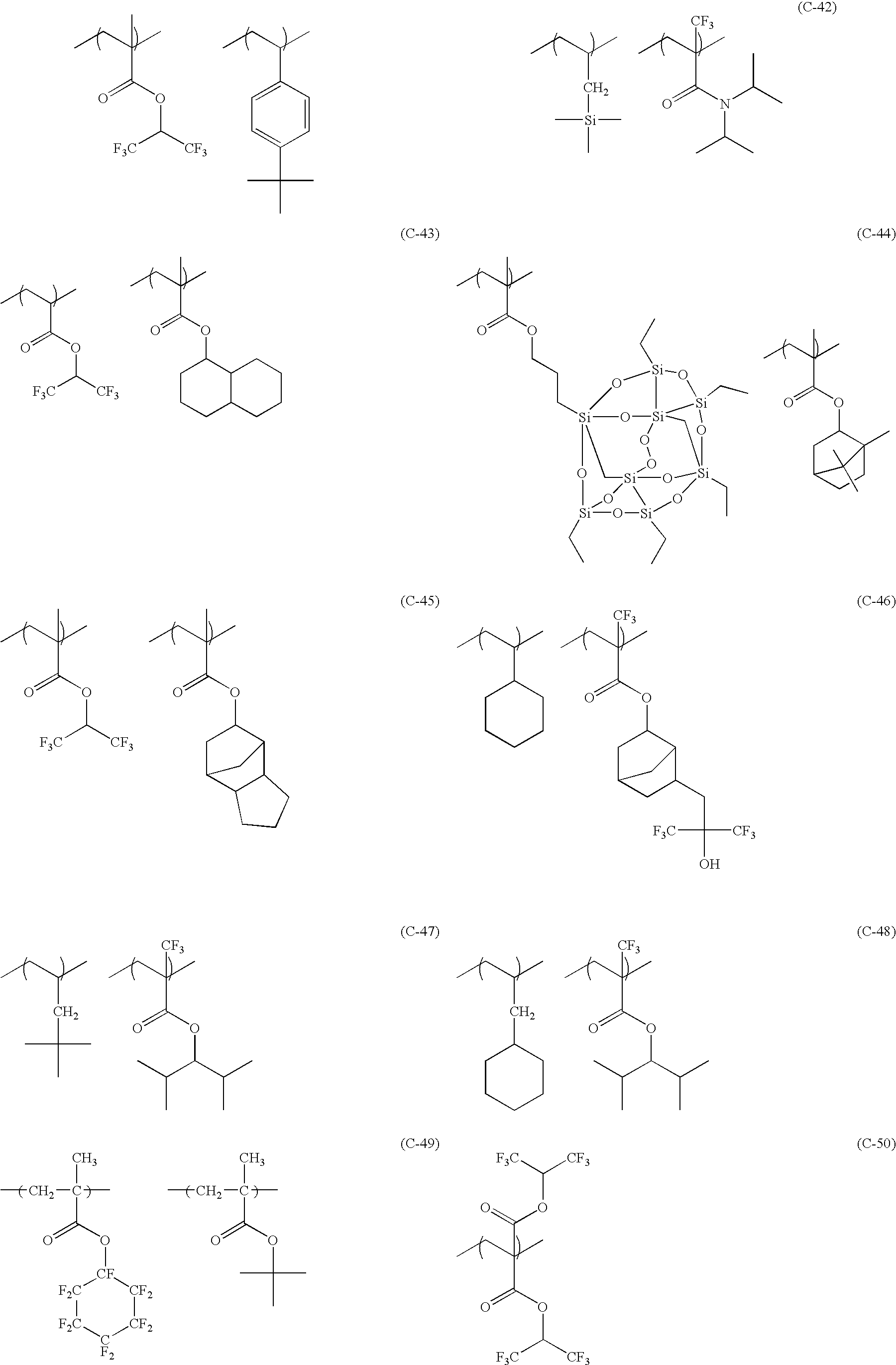

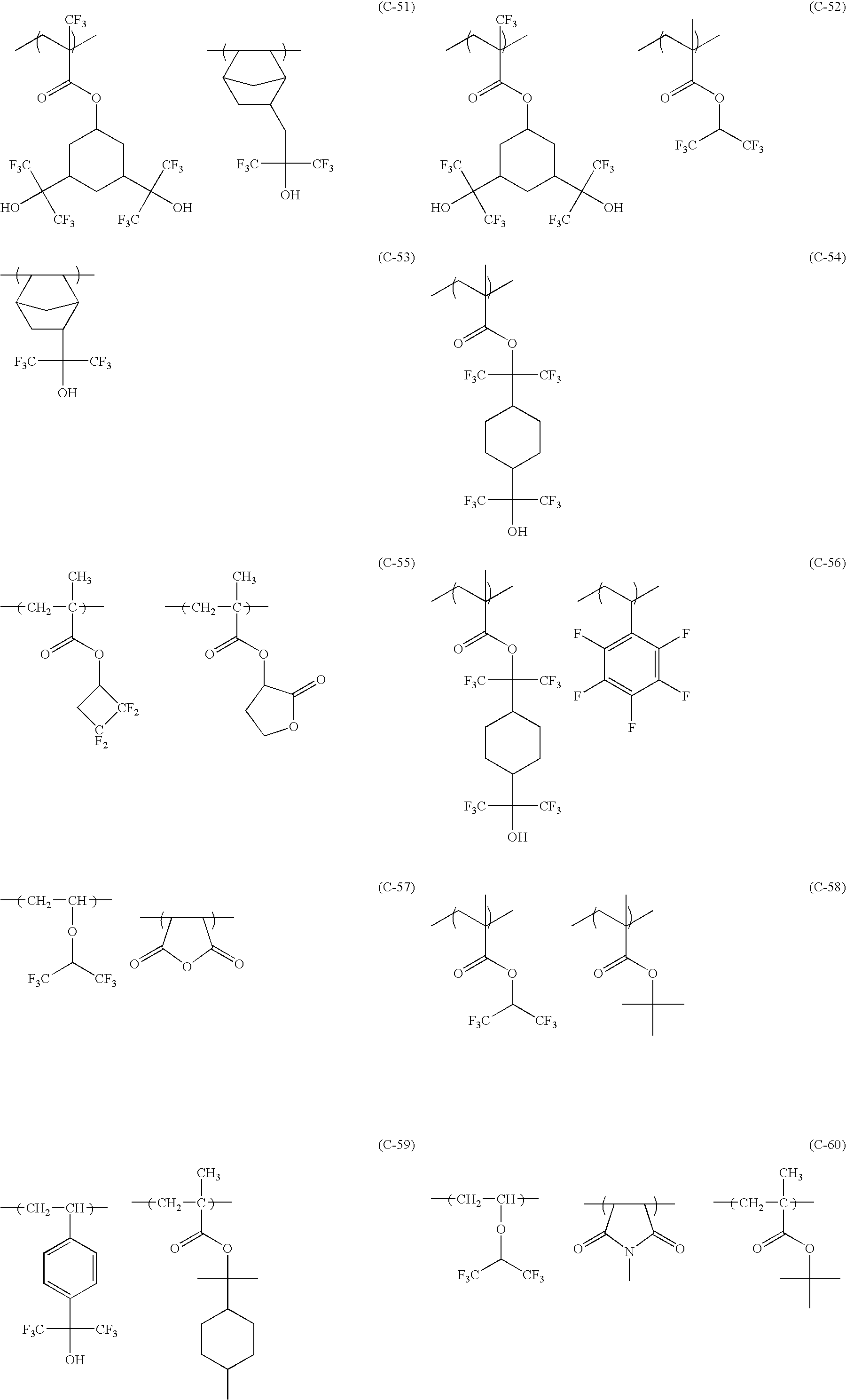

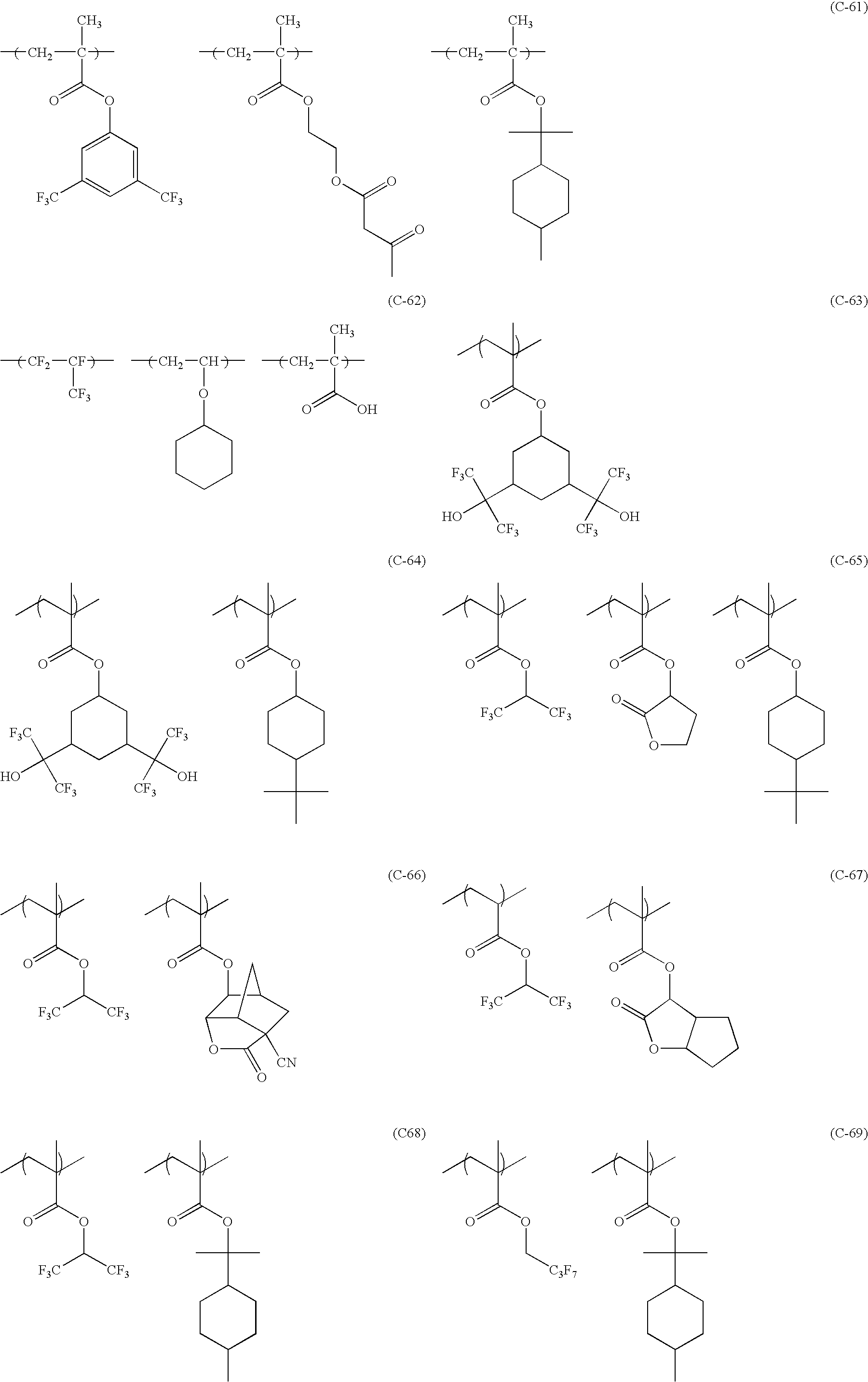

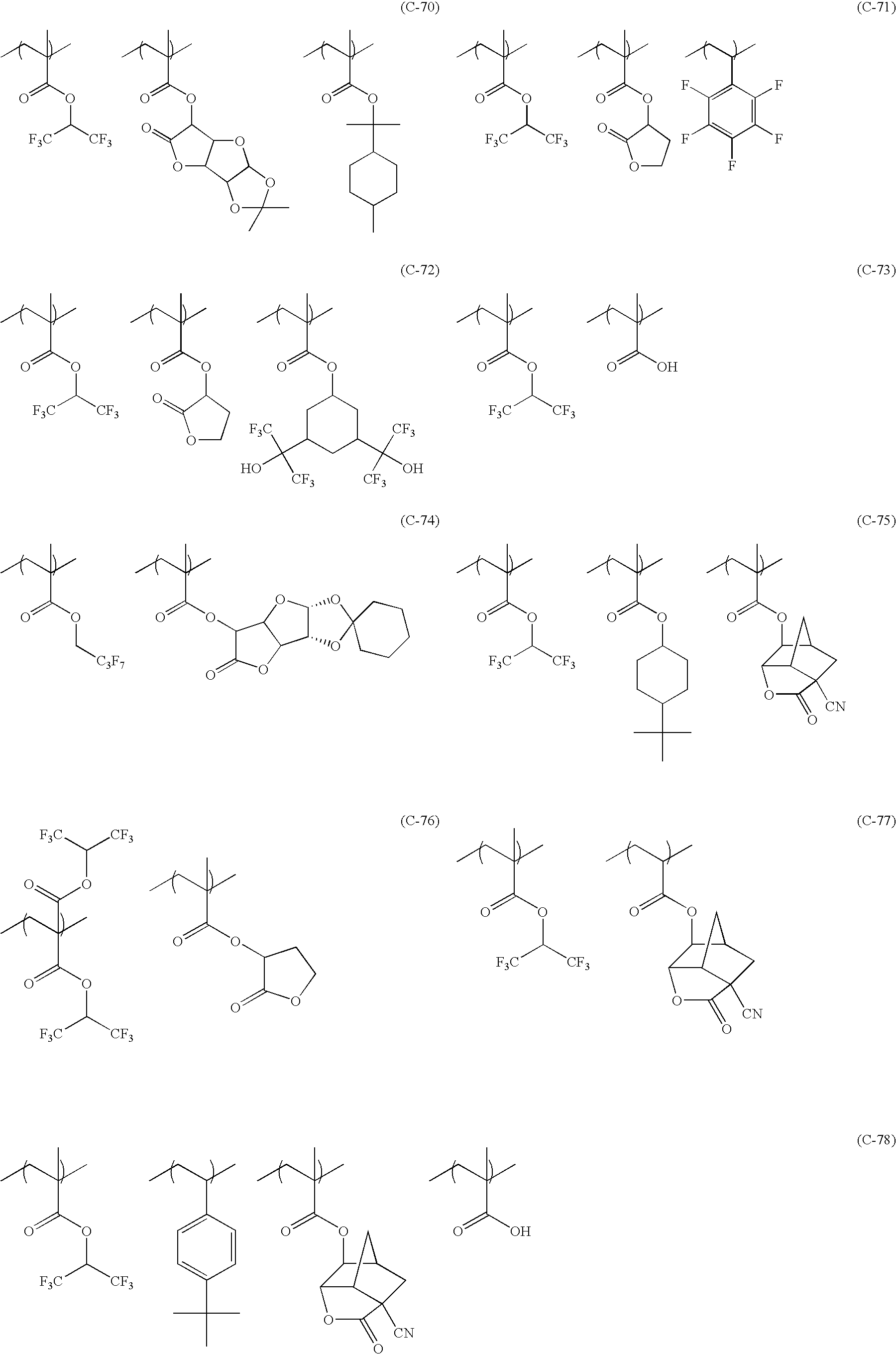

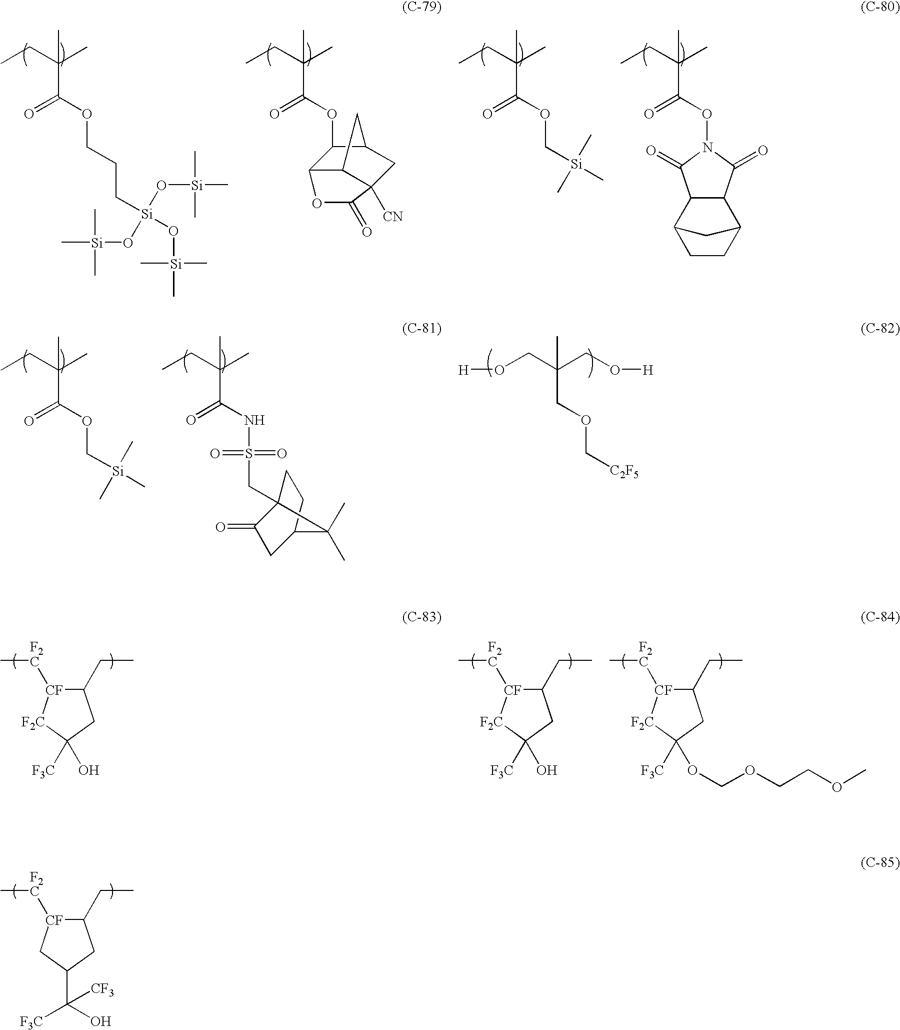

TABLE 1

| Resin | Composition | Mw | Mw/Mn |
|---|---|---|---|
| C-1 | 50/50 | 4800 | 1.6 |
| C-2 | 50/50 | 5200 | 1.8 |
| C-3 | 50/50 | 4800 | 1.9 |
| C-4 | 50/50 | 5300 | 1.9 |
| C-5 | 50/50 | 6200 | 1.9 |
| C-6 | 100 | 6000 | 1.8 |
| C-7 | 50/50 | 5800 | 1.9 |
| C-8 | 50/50 | 6300 | 1.6 |
| C-9 | 100 | 5500 | 2.0 |
| C-10 | 50/50 | 7500 | 1.9 |
| C-11 | 70/30 | 10200 | 2.2 |
| C-12 | 40/60 | 15000 | 2.2 |
| C-13 | 40/60 | 13000 | 2.2 |
| C-14 | 80/20 | 11000 | 2.2 |
| C-15 | 60/40 | 9800 | 2.2 |
| C-16 | 50/50 | 8000 | 2.2 |
| C-17 | 50/50 | 7600 | 2.0 |
| C-18 | 50/50 | 12000 | 2.0 |
| C-19 | 20/80 | 6500 | 1.8 |
| C-20 | 100 | 4000 | 1.4 |
| C-21 | 100 | 6000 | 1.6 |
| C-22 | 100 | 2500 | 1.2 |
| C-23 | 50/50 | 5000 | 1.5 |
| C-24 | 50/50 | 8800 | 1.9 |
| C-25 | 50/50 | 5000 | 1.4 |
| C-26 | 50/50 | 5500 | 1.6 |
| C-27 | 80/20 | 8000 | 1.8 |
| C-28 | 30/70 | 7000 | 1.7 |
| C-29 | 50/50 | 6500 | 1.6 |
| C-30 | 50/50 | 6500 | 1.6 |
| C-31 | 50/50 | 9000 | 1.8 |
| C-32 | 100 | 10000 | 1.6 |
| C-33 | 70/30 | 8000 | 2.0 |
| C-34 | 10/90 | 8000 | 1.8 |
| C-35 | 30/30/40 | 9000 | 2.0 |
| C-36 | 50/50 | 6000 | 1.4 |
| C-37 | 50/50 | 5500 | 1.5 |
| C-38 | 50/50 | 4800 | 1.8 |
| C-39 | 60/40 | 5200 | 1.8 |
| C-40 | 50/50 | 8000 | 1.5 |
| C-41 | 20/80 | 3000 | 1.3 |
| C-42 | 50/50 | 6200 | 1.6 |
| C-43 | 60/40 | 16000 | 1.8 |
| C-44 | 80/20 | 10200 | 1.8 |
| C-45 | 50/50 | 4000 | 1.3 |
| C-46 | 50/50 | 8400 | 1.8 |
| C-47 | 50/50 | 6000 | 1.4 |
| C-48 | 50/50 | 4500 | 1.4 |
| C-49 | 50/50 | 6900 | 1.9 |
| C-50 | 100 | 2300 | 2.6 |
| C-51 | 60/40 | 12000 | 1.9 |
| C-52 | 65/35 | 5000 | 1.6 |
| C-53 | 100 | 8000 | 1.4 |
| C-54 | 100 | 8500 | 1.4 |
| C-55 | 80/20 | 13000 | 2.1 |
| C-56 | 70/30 | 18000 | 2.3 |
| C-57 | 50/50 | 5200 | 1.9 |
| C-58 | 50/50 | 4000 | 1.4 |
| C-59 | 60/40 | 5500 | 1.6 |
| C-60 | 32/32/36 | 5600 | 2.0 |
| C-61 | 30/30/40 | 9600 | 1.6 |
| C-62 | 40/40/20 | 12000 | 2.0 |
| C-63 | 100 | 12000 | 2.1 |
| C-64 | 50/50 | 5000 | 1.3 |
| C-65 | 40/30/30 | 5600 | 2.1 |
| C-66 | 50/50 | 6800 | 1.7 |
| C-67 | 50/50 | 5900 | 1.6 |
| C-68 | 46/54 | 4500 | 1.3 |
| C-69 | 50/50 | 10000 | 1.9 |
| C-70 | 30/40/30 | 9600 | 2.3 |
| C-71 | 30/40/30 | 9200 | 2.0 |
| C-72 | 40/29/31 | 3200 | 2.1 |
| C-73 | 95/5 | 4500 | 1.4 |
| C-74 | 50/50 | 7900 | 1.9 |
| C-75 | 20/30/50 | 4800 | 1.5 |
| C-76 | 50/50 | 2200 | 1.9 |
| C-77 | 50/50 | 4500 | 1.3 |
| C-78 | 40/20/30/10 | 14000 | 2.2 |
| C-79 | 50/50 | 5500 | 1.8 |
| C-80 | 50/50 | 10600 | 1.9 |
| C-81 | 50/50 | 8600 | 2.3 |
| C-82 | 100 | 15000 | 2.1 |
| C-83 | 100 | 6900 | 2.5 |
| C-84 | 50/50 | 9900 | 2.3 |
| C-85 | 100 | 11000 | 1.9 |

### (D) Solvent

Examples of the solvent which can be used for dissolving respective components described above to prepare a positive resist composition include an organic solvent such as alkylene glycol monoalkyl ether carboxylate, alkylene glycol monoalkyl ether, alkyl lactate, alkyl alkoxypropionate, cyclic lactone having a carbon number of 4 to 10, monoketone compound having a carbon number of 4 to 10 which may contain a ring, alkylene carbonate, alkyl alkoxyacetate and alkyl pyruvate.

Preferred examples of the alkylene glycol monoalkyl ether carboxylate include propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate and ethylene glycol monoethyl ether acetate.

Preferred examples of the alkylene glycol monoalkyl ether include propylene glycol monomethyl ether, propylene glycol monoethyl ether, propylene glycol monopropyl ether, propylene glycol monobutyl ether, ethylene glycol monomethyl ether and ethylene glycol monoethyl ether.

Preferred examples of the alkyl lactate include methyl lactate, ethyl lactate, propyl lactate and butyl lactate.

Preferred examples of the alkyl alkoxypropionate include ethyl 3-ethoxypropionate, methyl 3-methoxypropionate, methyl 3-ethoxypropionate and ethyl 3-methoxypropionate.

Preferred examples of the cyclic lactone having a carbon number of 4 to 10 include β-propiolactone, β-butyrolactone, γ-butyrolactone, α-methyl-γ-butyrolactone, β-methyl-γ-butyrolactone, γ-valerolactone, γ-caprolactone, γ-octanoic lactone and α-hydroxy-γbutyrolactone.

Preferred examples of the monoketone compound having a carbon number of 4 to 10, which may contain a ring, include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-methylcyclohexanone, 2,2-dimethylcyclohexanone, 2,6-dimethylcyclohexanone, 2,2,6-trimethylcyclohexanone, cycloheptanone, 2-methylcycloheptanone and 3-methylcycloheptanone.

Preferred examples of the alkylene carbonate include propylene carbonate, vinylene carbonate, ethylene carbonate and butylene carbonate.

Preferred examples of the alkyl alkoxyacetate include 2-methoxyethyl acetate, 2-ethoxyethyl acetate, 2-(2-ethoxyethoxy)ethyl acetate, 3-methoxy-3-methylbutyl acetate and 1-methoxy-2-propyl acetate.

Preferred examples of the alkyl pyruvate include methyl pyruvate, ethyl pyruvate and propyl pyruvate.

The solvent which can be preferably used is a solvent having a boiling point of 130° C. or more at ordinary temperature under atmospheric pressure, and specific examples thereof include cyclopentanone, γ-butyrolactone, cyclohexanone, ethyl lactate, ethylene glycol monoethyl ether acetate, propylene glycol monomethyl ether acetate, ethyl 3-ethoxypropionate, ethyl pyruvate, 2-ethoxyethyl acetate, 2-(2-ethoxyethoxy)ethyl acetate and propylene carbonate.

In the present invention, one of these solvents may be used alone, or two or more species thereof may be used in combination.

In the present invention, a mixed solvent prepared by mixing a solvent containing a hydroxyl group in the structure and a solvent not containing a hydroxyl group may be used as the organic solvent.

Examples of the solvent containing a hydroxyl group include ethylene glycol, ethylene glycol monomethyl ether, ethylene glycol monoethyl ether, propylene glycol, propylene glycol monomethyl ether, propylene glycol monoethyl ether and ethyl lactate. Among these, propylene glycol monomethyl ether and ethyl lactate are preferred.

Examples of the solvent not containing a hydroxyl group include propylene glycol monomethyl ether acetate, ethyl ethoxypropionate, 2-heptanone, γ-butyrolactone, cyclohexanone, butyl acetate, N-methylpyrrolidone, N,N-dimethylacetamide and dimethylsulfoxide. Among these, propylene glycol monomethyl ether acetate, ethyl ethoxy-propionate, 2-heptanone, γ-butyrolactone, cyclohexanone and butyl acetate are preferred, and propylene glycol monomethyl ether acetate, ethyl ethoxypropionate and 2-heptanone are most preferred.

The mixing ratio (by mass) of the solvent containing a hydroxyl group and the solvent not containing a hydroxyl group is from 1/99 to 99/1, preferably from 10/90 to 90/10, more preferably from 20/80 to 60/40. A mixed solvent in which the solvent not containing a hydroxyl group is contained in an amount of 50 mass % or more is preferred in view of coating uniformity.

The solvent is preferably a mixed solvent of two or more species including propylene glycol monomethyl ether acetate.

### (E) Basic Compound

The positive resist composition of the present invention preferably comprises (E) a basic compound for reducing the change of performance with aging from exposure until heating.

Preferred examples of the basic compound include compounds having a structure represented by any one of the following formulae (A) to (E):

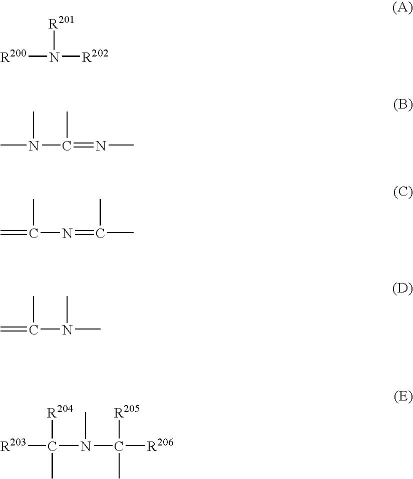

In formulae (A) and (E), R²⁰⁰, R²⁰¹ and R²⁰², which may be the same or different, each represents a hydrogen atom, an alkyl group (preferably having a carbon number of 1 to 20), a cycloalkyl group (preferably having a carbon number of 3 to 20) or an aryl group (having a carbon number of 6 to 20), and R²⁰¹ and R²⁰² may combine with each other to form a ring.

As for the alkyl group, the alkyl group having a substituent is preferably an aminoalkyl group having a carbon number of 1 to 20, a hydroxyalkyl group having a carbon number of 1 to 20, or a cyanoalkyl group having a carbon number of 1 to 20.

R²⁰³, R²⁰⁴, R²⁰⁵ and R²⁰⁶, which may be the same or different, each represents an alkyl group having a carbon number of 1 to 20.

The alkyl group in these formulae (A) and (E) is more preferably unsubstituted.

Preferred examples of the compound include guanidine, aminopyrrolidine, pyrazole, pyrazoline, piperazine, aminomorpholine, aminoalkylmorpholine and piperidine. More preferred examples of the compound include a compound having an imidazole structure, a diazabicyclo structure, an onium hydroxide structure, an onium carboxylate structure, a trialkylamine structure, an aniline structure or a pyridine structure; an alkylamine derivative having a hydroxyl group and/or an ether bond; and an aniline derivative having a hydroxyl group and/or an ether bond.

Examples of the compound having an imidazole structure include imidazole, 2,4,5-triphenylimidazole and benzimidazole. Examples of the compound having a diazabicyclo structure include 1,4-diazabicyclo[2,2,2]octane, 1,5-diazabicyclo[4,3,0]non-5-ene and 1,8-diazabicyclo[5,4,0]undec-7-ene. Examples of the compound having an onium hydroxide structure include a triarylsulfonium hydroxide, a phenacylsulfonium hydroxide, and a sulfonium hydroxide having a 2-oxoalkyl group, specifically, triphenylsulfonium hydroxide, tris(tert-butylphenyl)sulfonium hydroxide, bis(tert-butylphenyl)iodonium hydroxide, phenacylthiophenium hydroxide and 2-oxopropylthiophenium hydroxide. Examples of the compound having an onium carboxylate structure include a compound where the anion moiety of the compound having an onium hydroxide structure is converted into a carboxylate, such as acetate, adamantane-1-carboxylate and perfluoroalkyl carboxylate. Examples of the compound having a trialkylamine structure include tri(n-butyl)amine and tri(n-octyl)amine. Examples of the aniline compound include 2,6-diisopropylaniline, N,N-dimethylaniline, N,N-dibutylaniline and N,N-dihexylaniline. Examples of the alkylamine derivative having a hydroxyl group and/or an ether bond include ethanolamine, diethanolamine, triethanolamine and tris(methoxyethoxyethyl)amine. Examples of the aniline derivative having a hydroxyl group and/or an ether bond include N,N-bis(hydroxyethyl)aniline.

One of these basic compounds is used alone, or two or more species thereof are used in combination.

The amount of the basic compound used is usually from 0.001 to 10 mass %, preferably from 0.01 to 5 mass %, based on the solid content of the positive resist composition.

The ratio between the acid generator and the basic compound used in the composition is preferably acid generator/basic compound (by mol)=from 2.5 to 300. That is, the molar ratio is preferably 2.5 or more in view of sensitivity and resolution and preferably 300 or less from the standpoint of suppressing the reduction in resolution due to thickening of the resist pattern with aging after exposure until heat treatment. The acid generator/basic compound (by mol) is more preferably from 5.0 to 200, still more preferably from 7.0 to 150.

### (F) Surfactant

The positive resist composition of the present invention preferably further comprises (F) a surfactant, more preferably any one fluorine-containing and/or silicon-containing surfactant (a fluorine-containing surfactant, a silicon-containing surfactant or a surfactant containing both a fluorine atom and a silicon atom) or two or more species thereof.

When the positive resist composition of the present invention contains (F) a surfactant, a resist pattern with good sensitivity, resolution and adhesion as well as less development defects can be obtained when an exposure light source of 250 nm or less, particularly 220 nm or less, is used.

Examples of the fluorine-containing and/or silicon-containing surfactant include surfactants described in JP-A-62-36663, JP-A-61-226746, JP-A-61-226745, JP-A-62-170950, JP-A-63-44540, JP-A-7-230165, JP-A-8-62834, JP-A-9-54432, JP-A-9-5988, JP-A-2002-277862 and U.S. Pat. Nos. 5,405,720, 5,360,692, 5,529,881, 5,296,330, 5,436,098, 5,576,143, 5,294,511 and 5,824,451. The following commercially available surfactants each may also be used as it is.

Examples of the commercially available surfactant which can be used include a fluorine-containing surfactant and a silicon-containing surfactant, such as EFtop EF301 and EF303 (produced by Shin-Akita Kasei K.K.); Florad FC430, 431 and 4430 (produced by Sumitomo 3M Inc.); Megafac F171, P173, F176, F189, F113, F110, F177, F120 and R08 (produced by Dainippon Ink & Chemicals, Inc.); Surflon S-382, SC101, 102, 103, 104, 105 and 106 (produced by Asahi Glass Co., Ltd.); Troysol S-366 (produced by Troy Chemical); GF-300 and GF-150 (produced by Toagosei Chemical Industry Co., Ltd.); Surflon S-393 (produced by Seimi Chemical Co., Ltd.), Eftop EF121, EF122A, EF122B, RF122C, EF125M, EF135M, EF351, 352, EF801, EF802 and EF601 (produced by JEMCO Inc.); PF636, PF656, PF6320 and PF6520 (produced by OMNOVA); and FTX-204D, 208G, 218G, 230G, 208D, 212D, 218D and 222D (produced by NEOS Co., Ltd.). In addition, polysiloxane polymer KP-341 (produced by Shin-Etsu Chemical Co., Ltd.) may also be used as the silicon-containing surfactant.

Other than those known surfactants, a surfactant using a polymer having a fluoro-aliphatic group derived from a fluoro-aliphatic compound which is produced by a telomerization process (also called a telomer process) or an oligomerization process (also called an oligomer process), may be used. The fluoro-aliphatic compound can be synthesized by the method described in JP-A-2002-90991.

The polymer having a fluoro-aliphatic group is preferably a copolymer of a fluoro-aliphatic group-containing monomer with a (poly(oxyalkylene))acrylate and/or a (poly(oxyalkylene))methacrylate, and the polymer may have an irregular distribution or may be a block copolymer. Examples of the poly(oxyalkylene) group include a poly(oxyethylene) group, a poly(oxypropylene) group and a poly(oxybutylene) group. This group may also be a unit having alkylenes differing in the chain length within the same chain, such as block-linked poly(oxyethylene, oxypropylene and oxyethylene) and block-linked poly(oxyethylene and oxypropylene). Furthermore, the copolymer of a fluoro-aliphatic group-containing monomer and a (poly(oxyalkylene))acrylate (or methacrylate) is not limited only to a binary copolymer but may also be a ternary or greater copolymer obtained by simultaneously copolymerizing two or more different fluoro-aliphatic group-containing monomers or two or more different (poly(oxyalkylene))acrylates (or methacrylates).

Examples thereof include, as the commercially available surfactant, Megafac F178, F470, F-473, F-475, F-476 and F-472 (produced by Dainippon Ink & Chemicals, Inc.) and further include a copolymer of a C₆F₁₃ group-containing acrylate (or methacrylate) with a (poly(oxyalkylene))acrylate (or methacrylate), and a copolymer of a C₃F₇ group-containing acrylate (or methacrylate) with a (poly(oxyethylene))acrylate (or methacrylate) and a poly(oxypropylene))acrylate (or methacrylate).

In the present invention, a surfactant other than the fluorine-containing and/or silicon-containing surfactant may also be used. Specific examples thereof include a nonionic surfactant such as polyoxyethylene alkyl ethers (e.g., polyoxyethylene lauryl ether, polyoxyethylene stearyl ether, polyoxyethylene cetyl ether, polyoxyethylene oleyl ether), polyoxyethylene alkylallyl ethers (e.g., polyoxyethylene octylphenol ether, polyoxyethylene nonylphenol ether), polyoxyethylene•polyoxypropylene block copolymers, sorbitan fatty acid esters (e.g., sorbitan monolaurate, sorbitan monopalmitate, sorbitan monostearate, sorbitan monooleate, sorbitan trioleate, sorbitan tristearate) and polyoxyethylene sorbitan fatty acid esters (e.g., polyoxyethylene sorbitan monolaurate, polyoxyethylene sorbitan monopalmitate, polyoxyethylene sorbitan monostearate, polyoxyethylene sorbitan trioleate, polyoxyethylene sorbitan tristearate).

One of these surfactants may be used alone, or several species thereof may be used in combination.

The amount of the surfactant (F) used is preferably from 0.01 to 10 mass %, more preferably from 0.1 to 5 mass %, based on the entire amount of the positive resist composition (excluding the solvent).

### (G) Onium Carboxylate

The positive resist composition of the present invention may comprise (G) an onium carboxylate. Examples of the onium carboxylate include sulfonium carboxylate, iodonium carboxylate and ammonium carboxylate. In particular, the onium carboxylate (G) is preferably an iodonium salt or a sulfonium salt. Furthermore, the carboxylate residue of the onium carboxylate (G) for use in the present invention preferably contains no aromatic group and no carbon-carbon double bond. The anion moiety is preferably an anion of a linear, branched, or mono- or poly-cyclic alkylcarboxylic acid having a carbon number of 1 to 30, more preferably an anion of the carboxylic acid with the alkyl group being partially or entirely fluorine-substituted. The alkyl chain may contain an oxygen atom. By virtue of such a construction, the transparency to light of 220 nm or less is ensured, the sensitivity and resolution are enhanced, and the defocus latitude depended on line pitch and the exposure margin are improved.

Examples of the anion of a fluorine-substituted carboxylic acid include anions of fluoroacetic acid, difluoroacetic acid, trifluoroacetic acid, pentafluoropropionic acid, heptafluorobutyric acid, nonafluoropentanoic acid, perfluorododecanoic acid, perfluoro-tridecanoic acid, perfluorocyclohexanecarboxylic acid and 2,2-bistrifluoromethylpropionic acid.

These onium carboxylates (G) can be synthesized by reacting a sulfonium, iodonium or ammonium hydroxide and a carboxylic acid with silver oxide in an appropriate solvent.

The content of the onium carboxylate (G) in the composition is generally from 0.1 to 20 mass %, preferably.from 0.5 to 10 mass %, more preferably from 1 to 7 mass %, based on the entire solid content of the composition.

### (H) Other Additives

The positive resist composition of the present invention may further contain, for example, a dye, a plasticizer, a photosensitizer, a light absorbent, an alkali-soluble resin, a dissolution inhibitor, and a compound for accelerating dissolution in a developer (for example, a phenol compound having a molecular weight of 1,000 or less, or a carboxyl group-containing alicyclic or aliphatic compound), if desired.

The phenol compound having a molecular weight of 1,000 or less can be easily synthesized by one skilled in the art by referring to the methods described, for example, in JP-A-4-122938, JP-A-2-28531, U.S. Pat. No. 4,916,210 and European Patent 219294.

Specific examples of the carboxyl group-containing alicyclic or aliphatic compound include, but are not limited to, a carboxylic acid derivative having a steroid structure, such as cholic acid, deoxycholic acid and lithocholic acid, an adamantanecarboxylic acid derivative, an adamantanedicarboxylic acid, a cyclohexanecarboxylic acid and a cyclohexanedicarboxylic acid.

### (I) Pattern Forming Method

The positive resist composition of the present invention is preferably used in a film thickness of 30 to 250 nm, more preferably from 30 to 200 nm, from the standpoint of enhancing the resolving power. Such a film thickness can be obtained by setting the solid content concentration in the positive resist composition to an appropriate range, thereby giving an appropriate viscosity to enhance the coatability and film-forming property.

The entire solid content concentration in the positive resist composition is generally from 1 to 10 mass %, preferably from 1 to 8.0 mass %, more preferably from 1.0 to 6.0 mass %.

The positive resist composition of the present invention is used by dissolving the components described above in a predetermined organic solvent, preferably in the above-described mixed solvent, filtering the solution, and coating it on a predetermined support as follows. The filter used for filtering is preferably a filter made of polytetrafluoroethylene, polyethylene or nylon and having a pore size of 0.1 micron or less, more preferably 0.05 microns or less, still more preferably 0.03 microns or less.

For example, the positive resist composition is coated on such a substrate (e.g., silicon/silicon dioxide-coated substrate) as used in the production of a precision integrated circuit device, by an appropriate coating method such as spinner or coater, and then dried to form a photosensitive film. Incidentally, a known antireflection film may be previously provided by coating.

The photosensitive film is irradiated with actinic rays or radiation through a predetermined mask, then preferably baked (heated), further developed and rinsed, whereby a good pattern can be obtained.

Examples of the actinic rays or radiation include infrared light, visible light, ultraviolet light, far ultraviolet light, X-ray and electron beam, but the radiation is preferably far ultraviolet light at a wavelength of 250 nm or less, more preferably 220 nm or less, still more preferably from 1 to 200 nm. Specific examples thereof include KrF excimer laser light (248 nm), ArF excimer laser light (193 nm), F₂ excimer laser light (157 nm), X-ray and electron beam. ArF excimer laser light, F₂ excimer laser light, EUV (13 nm) and electron beam are preferred.

Before forming the resist film, an antireflection film may be previously provided by coating on the substrate.

The antireflection film used may be either an inorganic film type such as titanium, titanium dioxide, titanium nitride, chromium oxide, carbon and amorphous silicon, or an organic film type comprising a light absorbent and a polymer material. Also, the organic antireflection film may be a commercially available organic antireflection film such as DUV30 Series and DUV-40 Series produced by Brewer Science, Inc., and AR-2, AR-3 and AR-5 produced by Shipley Co., Ltd.

In the development step, an alkali developer is used as follows. The alkali developer which can be used for the resist composition is an alkaline aqueous solution of inorganic alkalis such as sodium hydroxide, potassium hydroxide, sodium carbonate, sodium silicate, sodium metasilicate and aqueous ammonia, primary amines such as ethylamine and n-propylamine, secondary amines such as diethylamine and di-n-butylamine, tertiary amines such as triethylamine and methyldiethylamine, alcohol amines such as dimetylethanolamine and triethanolamine, quaternary ammonium salts such as tetramethylammonium hydroxide and tetraethylammonium hydroxide, or cyclic amines such as pyrrole and piperidine.

Furthermore, this alkali developer may be used after adding thereto alcohols and a surfactant each in an appropriate amount.

The alkali concentration of the alkali developer is usually from 0.1 to 20 mass %.

The pH of the alkali developer is usually from 10.0 to 15.0.

Also, the above-described alkaline aqueous solution may be used after adding thereto alcohols and a surfactant each in an appropriate amount.

As for the rinsing solution, pure water is used, and the pure water may be used after adding thereto a surfactant in an appropriate amount.

After the development or rinsing, the developer or rinsing solution adhering on the pattern may removed by a supercritical fluid.

The positive resist composition of the present invention may be applied to a multilayer resist process (particularly, a three-layer resist process). The multilayer resist process comprises the following steps:

(a) forming a lower resist layer comprising an organic material on a substrate to be processed,

(b) sequentially stacking on the lower resist layer an intermediate layer and an upper resist layer comprising an organic material capable of crosslinking or decomposing upon irradiation with radiation, and

(c) forming a predetermined pattern on the upper resist layer and then sequentially etching the intermediate layer, the lower layer and the substrate.

An organopolysiloxane (silicone resin) or SiO₂ coating solution (SOG) is generally used for the intermediate layer. As for the lower layer resist, an appropriate organic polymer film is used, but various known photoresists may be used. Examples thereof include various series such as FH Series and FHi Series produced by Fujifilm Arch Co., Ltd., and PFI Series produced by Sumitomo Chemical Co., Ltd.

The film thickness of the lower resist layer is preferably from 0.1 to 4.0 μm, more preferably from 0.2 to 2.0 μm, still more preferably from 0.25 to 1.5 μm. The film thickness is preferably 0.1 μm or more in view of antireflection or dry etching resistance and preferably 4.0 μm or less in view of aspect ratio or pattern collapse of the fine pattern formed.

The exposure may be performed by filling a liquid (immersion medium) having a refractive index higher than that of air between the resist film and a lens at the irradiation with actinic rays or radiation (immersion exposure). By virtue of this exposure, the resolution can be enhanced. The immersion medium used may be any liquid as long as it has a refractive index higher than that of air, but pure water is preferred. Also, in order to prevent the immersion medium and the photosensitive film from coming into direct contact at the immersion exposure, an overcoat layer may be further provided on the photosensitive film. By virtue of providing an overcoat layer, the composition can be restrained from dissolving out into the immersion medium from the photosensitive film, and the development defects can be reduced.

The immersion liquid used in the immersion exposure is described below.

The immersion liquid is preferably a liquid transparent to light at the exposure wavelength and having as small a refractive index temperature coefficient as possible so as to minimize the distortion of an optical image projected on the resist. Particularly, when the exposure light source is an ArF excimer laser (wavelength: 193 nm), water is preferably used in view of easy availability and easy handleability in addition to the above-described aspects.

Furthermore, a medium having a refractive index of 1.5 or more can also be used because the refractive index can be more enhanced. This medium may be either an aqueous solution or an organic solvent.

In the case of using water as the immersion liquid, for the purpose of decreasing the surface tension of water and increasing the surface activity, an additive (liquid) which does not dissolve the resist layer on a wafer and at the same time, gives only a negligible effect on the optical coat at the undersurface of the lens element, may be added in a small ratio. The additive is preferably an aliphatic alcohol having a refractive index nearly equal to that of water, and specific examples thereof include methyl alcohol, ethyl alcohol and isopropyl alcohol. By virtue of adding an alcohol having a refractive index nearly equal to that of water, even when the alcohol component in water is evaporated and its content concentration is changed, the change in the refractive index of the entire liquid can be made very small, which is advantageous. On the other hand, if a substance opaque to light at 193 nm or an impurity greatly differing in the refractive index from water is mingled, this incurs distortion of the optical image projected on the resist. Therefore, the water used is preferably distilled water. Pure water obtained by further filtering the distilled water through an ion exchange filter or the like may also be used.

The electrical resistance of water is preferably 18.3 MΩcm or more, and TOC (total organic carbon) is preferably 20 ppb or less. Also, the water is preferably subjected to a deaeration treatment.

The lithography performance can be enhanced by increasing the refractive index of the immersion liquid. From such a standpoint, an additive for increasing the refractive index may be added to water, or heavy water (D₂O) may be used in place of water.

When a resist film is formed from the positive resist composition of the present invention, the receding contact angle of water for the resist film is preferably 70° or more. The receding contact angle here is a value at ordinary temperature under atmospheric pressure. The receding contact angle is a contact angle on the receding end of a liquid droplet when the liquid droplet starts sliding down after the resist film is inclined.

In order to prevent the resist film from directly contacting with the immersion liquid, an immersion liquid sparingly soluble film (hereinafter, sometimes referred to as a “topcoat”) may be provided between the immersion liquid and the resist film formed from the positive resist composition of the present invention. The functions required of the topcoat are suitability for coating on the resist upper layer parts transparency to radiation particularly at 193 nm, and difficult solubility in the immersion liquid. It is preferred that the topcoat does not intermix with the resist and can be uniformly coated on the resist upper layer.

In view of transparency to light at 193 nm, the topcoat preferably comprises an aromatic-free polymer, and specific examples thereof include a hydrocarbon polymer, an acrylic acid ester polymer, a polymethacrylic acid, a polyacrylic acid, a polyvinyl ether, a silicon-containing polymer and a fluorine-containing polymer. The hydrophobic resin (C) may also be used as the topcoat. If impurities dissolve out into the immersion liquid from the topcoat, the optical lens is contaminated. In this viewpoint, the residual monomer components of the polymer are preferably less contained in the topcoat.

On peeling off the topcoat, a developer may be used or a releasing agent may be separately used. The releasing agent is preferably a solvent less permeating into the resist. From the standpoint that the peeling step can be performed simultaneously with the resist development step, the topcoat is preferably peelable with an alkali developer and for the peeling with an alkali developer, the topcoat is preferably acidic, but in view of non-intermixing with the resist, the topcoat may be neutral or alkaline.

With no difference in the refractive index between the topcoat and the immersion liquid, the resolving power is enhanced. In the case of using water as the immersion liquid at the exposure with an ArF excimer laser (wavelength: 193 nm), the topcoat for ArF immersion exposure preferably has a refractive index close to the refractive index of the immersion liquid. From the standpoint of making the refractive index close to that of the immersion liquid, the topcoat preferably contains a fluorine atom. Also, in view of transparency and refractive index, the topcoat is preferably a thin film.

The topcoat is preferably free of intermixing with the resist and further with the immersion liquid. From this standpoint, when the immersion liquid is water, the topcoat solvent is preferably a medium which is sparingly soluble in the resist solvent and insoluble in water. Furthermore, when the immersion liquid is an organic solvent, the topcoat may be either water-soluble or water-insoluble.

### EXAMPLES

The present invention is described in greater detail below by referring to Examples, but the present invention should not be construed as being limited thereto.

### Synthesis Example 1

### Synthesis of Resin (1)

In a nitrogen stream, 8.6 g of cyclohexanone was charged into a three-neck flask and heated at 80° C. Thereto, a solution obtained by dissolving 9.8 g of 2-adamantyl-isopropyl methacrylate, 4.4 g of dihydroxyadamantyl methacrylate, 8.9 g of norbornane lactone methacrylate, and polymerization initiator V-601 (produced by Wako Pure Chemical Industries, Ltd.) in a concentration of 8 mol % based on the monomers, in 79 g of cyclohexanone was added dropwise over 6 hours. After the completion of dropwise addition, the reaction was further allowed to proceed at 80° C for 2 hours. The resulting reaction solution was left standing to cool and then, added dropwise to a mixed solution of 800 m of hexane/200 ml of ethyl acetate over 20 minutes, and the powder precipitated was collected by filtration and dried, as a result, 19 g of Resin (1) was obtained. The weight average molecular weight of the obtained Resin (1) was 8,800 in terms of standard polystyrene and the dispersity (Mw/Mn) was 1.9.

Resins (2) to (19) were synthesized in the same manner.

Monomers, molar ratio thereof (from the left in the structural formula), weight average molecular weight and dispersity in each of Resins (1) to (19) are shown in Tables 2 and 3 below.

TABLE 2

| | | | | | Compositional | | |
|---|---|---|---|---|---|---|---|
| | Monomer | Monomer | Monomer | Monomer | Ratio | | |
| No. | (1) | (2) | (3) | (4) | (by mol) | Mw | Mw/Mn |
| 1 | 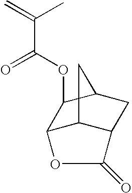 | 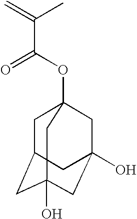 | 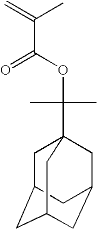 | — | 50/20/30 | 8800 | 1.9 |
| 2 | 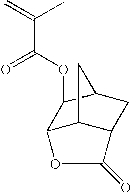 | 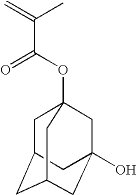 | 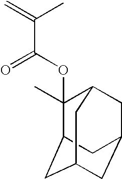 | — | 43/22/35 | 8600 | 2.0 |
| 3 | 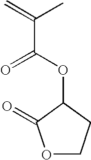 | 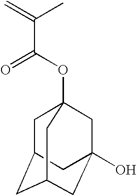 | 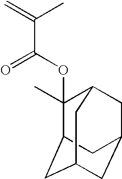 | — | 33/33/34 | 9500 | 2.3 |
| 4 | 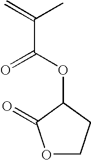 | 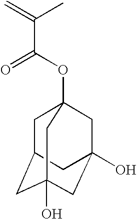 | 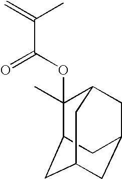 | — | 42/20/38 | 10500 | 2.1 |
| 5 | 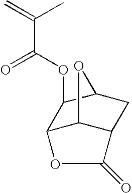 | 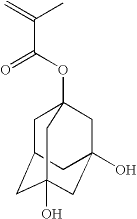 | 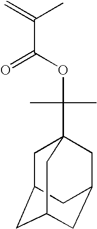 | — | 45/25/30 | 8400 | 2.3 |
| 6 | 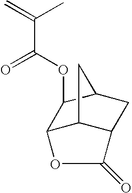 | 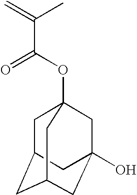 | 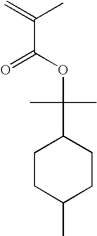 | — | 41/20/39 | 9600 | 2.1 |
| 7 | 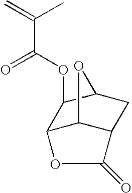 | 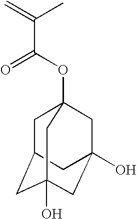 | 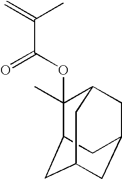 | — | 33/32/35 | 14000 | 2.6 |
| 8 | 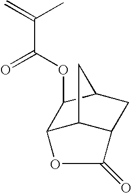 | 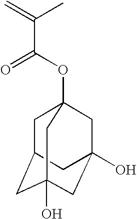 | 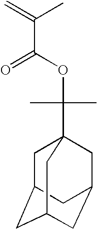 | 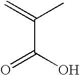 | 35/20/40/5 | 12500 | 2.4 |
| 9 | 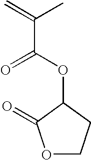 | 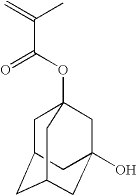 | 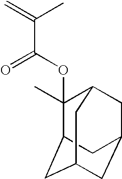 | 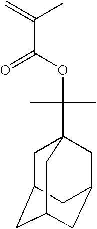 | 42/20/35/3 | 9900 | 2.3 |
| 10 | 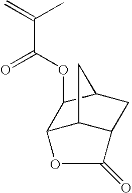 | 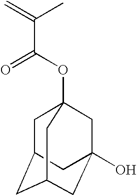 | 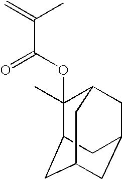 | 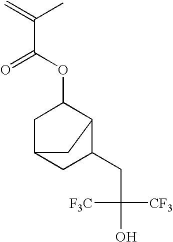 | 30/30/30/10 | 8600 | 2.5 |

TABLE 3

| | | | | | Compositional | | |
|---|---|---|---|---|---|---|---|
| | Monomer | Monomer | Monomer | Monomer | Ratio | | |
| No. | (1) | (2) | (3) | (4) | (by mol) | Mw | Mw/Mn |
| 11 | 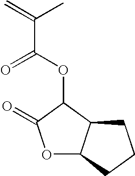 | 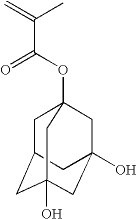 | 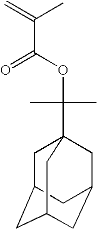 | 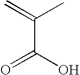 | 35/20/40/5 | 12000 | 2.1 |
| 12 | 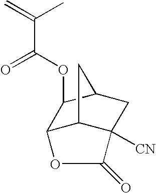 | 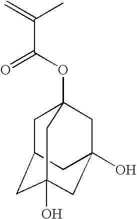 | 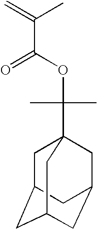 | 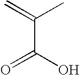 | 40/20/30/10 | 8000 | 2.0 |
| 13 | 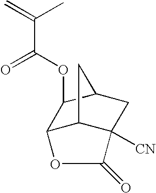 | 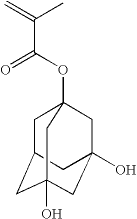 | 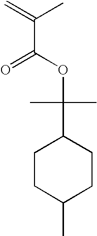 | — | 36/35/29 | 6000 | 1.8 |
| 14 | 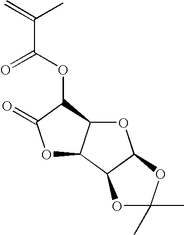 | 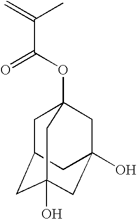 | 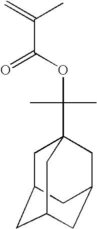 | 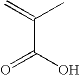 | 40/20/30/10 | 8500 | 1.5 |
| 15 | 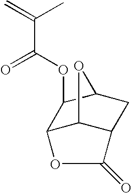 | 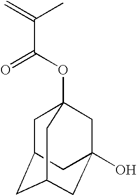 | 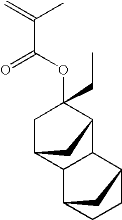 | — | 30/35/35 | 9800 | 1.8 |
| 16 | 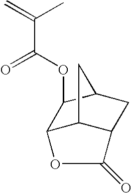 | 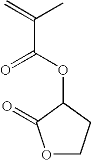 | 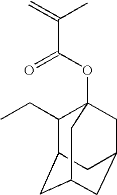 | — | 40/25/35 | 6700 | 2.0 |
| 17 | 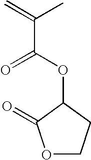 | 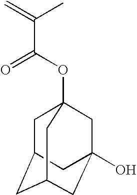 | 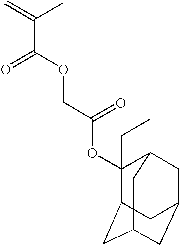 | — | 40/25/35 | 8000 | 1.8 |
| 18 | 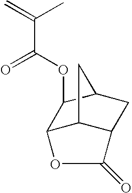 | 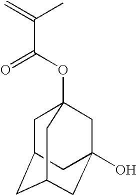 | 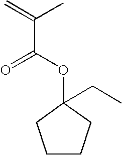 | — | 42/20/38 | 7700 | 2.0 |
| 19 | 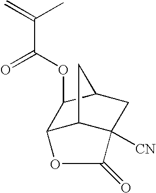 | 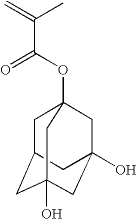 | 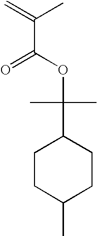 | 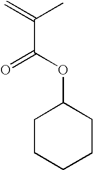 | 50/20/20/10 | 7800 | 1.8 |

### Synthesis Example 2

### Synthesis of Hydrophobic Resin (C-20)

Hexafluoroisopropyl acrylate (produced by Wako Pure Chemical Industries, Ltd.) (47.2 g) was dissolved in propylene glycol monomethyl ether acetate to prepare 170 g of a solution having a solid content concentration of 20%. To this solution, 8 mol % (3.68 g) of a polymerization initiator, V-601, produced by Wako Pure Chemical Industries, Ltd. was added. The resulting solution was added dropwise to 20.0 g of propylene glycol monomethyl ether acetate heated to 80° C., over 4 hours in a nitrogen atmosphere. After the completion of dropwise addition, the reaction solution was stirred for 2 hours to obtain a reaction solution. After the completion of reaction, the reaction solution was cooled to room temperature and added dropwise to a 20-fold amount of a methanol/water=8/1 mixed solvent. The oily compound separated was recovered by decantation to obtain 24.1 g of the objective Hydrophobic Resin (C-20).

The weight average molecular weight in terms of standard polystyrene determined by GPC was 4,000, and the dispersity was 1.4.

### Examples 1 to 19 and Comparative Examples 1 to 6

### <Preparation of Resist>

The components shown in Tables 4 to 5 below were dissolved in a solvent to prepare a solution having a solid content concentration of 6 mass %, and the obtained solution was filtered through a polyethylene filter having a pore size of 0.1 μm to prepare a positive resist solution. The positive resist solutions prepared were evaluated by the following methods, and the results are shown in the same Tables. As for each component in the Tables, when a plurality of species were used, the ratio is a ratio by mass. The “wt %” is based on the solid content. Also, the weight average molecular weight difference is a numerical value obtained by subtracting the weight average molecular weight of the hydrophobic resin (C) from the weight average molecular weight of the resin (A).

### [Image Performance Test]

### (Exposure Condition (1))

An organic antireflection film, ARC29A (produced by Nissan Chemical Industries, Ltd.), was coated on a silicon wafer and baked at 205° C. for 60 seconds to form a 78-nm antireflection film, and the positive resist solution prepared above was coated thereon and baked at 130° C. for 60 seconds to form a 250-nm resist film. The obtained wafer was subjected to pattern exposure by using an ArF excimer laser scanner (PAS5500/1100, manufactured by ASML, NA: 0.75, σo/σi: 0.85/0.55). Thereafter, the resist film was heated at 130° C. for 60 seconds, developed with an aqueous tetramethylammonium hydroxide solution (2.38 mass %) for 30 seconds, rinsed with pure water and spin-dried to obtain a resist pattern.

### (Exposure Condition (2))

This condition is for forming a resist pattern by an immersion exposure method using pure water.

An organic antireflection film, ARC29A (produced by Nissan Chemical Industries, Ltd.), was coated on a silicon wafer and baked at 205° C. for 60 seconds to form a 78-nm antireflection film, and the positive resist solution prepared above was coated thereon and baked at 130° C. for 60 seconds to form a 250-nm resist film. The obtained wafer was subjected to pattern exposure by using an ArF excimer laser immersion scanner (NA: 0.85). The immersion liquid used was ultrapure water. Thereafter, the resist film was heated at 130° C. for 60 seconds, developed with an aqueous tetramethylammonium hydroxide solution (2.38 mass %) for 30 seconds, rinsed with pure water and spin-dried to obtain a resist pattern.

### [Pattern Profile]

In Exposure Conditions (1) and (2), the exposure dose for reproducing a line-and-space pattern of 90 nm was taken as an optimal exposure dose, and the profile of a pattern obtained by exposing a dense 1:1 line-and-space pattern at the optimal exposure dose was observed through a scanning electron microscope (S-9206, manufactured by Hitachi, Ltd.) and evaluated.

### [Pattern Collapse]

In Exposure Conditions (1) and (2), the exposure dose for reproducing a line-and-space pattern of 90 nm was taken as an optimal exposure dose, and when a dense 1:1 line-and-space pattern and an isolated 1:10 line-and-space pattern each was exposed at the optimal exposure dose, the line width at which the pattern in a finer mask size was resolved without collapsing was taken as a limit line width of pattern collapse. A smaller value indicates that a finer pattern can be resolved without collapsing and the pattern collapse less occurs.

### [Evaluation of Development Defects]

In Exposure Condition (1), measurement in random mode was performed using a defect inspection apparatus, KLA2360 (trade name), manufactured by KLA Tencol K.K. by setting the pixel size of the defect inspection apparatus to 0.16 μm and the threshold to 20. Development defects extracted from the difference produced when superposing a comparison image and a pixel unit were detected, and the number of development defects per unit area was calculated. Samples were rated “A” when the value is less than 0.5, rated “B” when from 0.5 to 0.8, and rated “C” when more than 0.8. A smaller value indicates a better performance.

TABLE 4

| | Composition | | | | | |
|---|---|---|---|---|---|---|
| | Resin (A) | Photoacid Generator | | Basic Compound | Hydrophobic Resin | |
| | (2 g) | (mg) | Solvent (mass ratio) | (mg) | (C) (wt %) | Surfactant (mg) |
| Example 1 | 1 | z55/z23 (100/25) | SL-2/SL-4 (60/40) | N-5/N-1 (7/7) | C-20 (2.0) | W-4 (2) |
| Example 2 | 2 | z55/z65 (75/75) | SL-2/SL-4 (60/40) | N-5/N-1 (7/7) | C-1 (2.0) | W-4 (2) |
| Example 3 | 3 | z55 (100) | SL-2/SL-4 (60/40) | N-5/N-1 (7/7) | C-22 (0.8) | W-4 (2) |
| Example 4 | 4 | z55/z51 (45/45) | SL-2/SL-4 (60/40) | N-1 (10) | C-37 (0.7) | W-4 (2) |
| Example 5 | 5 | z2 (80) | SL-4/SL-2 (40/60) | N-5 (7) | C-39 (1.0) | W-1 (3) |
| Example 6 | 6 | z1 (50) | SL-4/SL-2 (40/60) | N-5 (7) | C-48 (1.0) | W-1 (3) |
| Example 7 | 7 | z2 (80) | SL-4/SL-2 (40/60) | N-3 (6) | C-69 (0.6) | W-1 (3) |
| Example 8 | 8 | z51 (100) | SL-2/SL-4/SL-6 (40/59/1) | N-6 (10) | C-66 (1.0) | W-3 (3) |
| Example 9 | 9 | z51 (100) | SL-2/SL-4/SL-6 (40/59/1) | N-1 (7) | C-48 (1.0) | W-3 (3) |
| Example 10 | 10 | z9 (100) | SL-2/SL-4/SL-6 (40/59/1) | N-2 (9) | C-72 (1.0) | W-3 (3) |
| Example 11 | 11 | z2/z55 (20/100) | SL-2/SL-4 (70/30) | N-3 (6) | C-27 (2.0) | W-6 (3) |
| Example 12 | 12 | z2/z15 (40/60) | SL-2/SL-4 (70/30) | N-3 (6) | C-38 (0.5) | W-6 (3) |

| | | Evaluation Results | | | | |
|---|---|---|---|---|---|---|
| | Weight Average Molecular Weight | Normal Exposure | | Immersion Exposure | | Development |
| | Difference | Profile | Collapse (nm) | Profile | Collapse (nm) | Defect |
| Example 1 | 4800 | rectangular | 60 | rectangular | 50 | A |
| Example 2 | 3800 | rectangular | 65 | rectangular | 55 | A |
| Example 3 | 7000 | rectangular | 50 | rectangular | 45 | A |
| Example 4 | 5000 | rectangular | 70 | rectangular | 65 | A |
| Example 5 | 3200 | rectangular | 60 | rectangular | 55 | A |
| Example 6 | 5100 | rectangular | 55 | rectangular | 45 | A |
| Example 7 | 4000 | rectangular | 70 | rectangular | 65 | A |
| Example 8 | 5700 | rectangular | 70 | rectangular | 65 | A |
| Example 9 | 5400 | rectangular | 70 | rectangular | 60 | A |
| Example 10 | 5400 | rectangular | 55 | rectangular | 50 | A |
| Example 11 | 4000 | rectangular | 70 | rectangular | 65 | A |
| Example 12 | 3200 | rectangular | 65 | rectangular | 60 | A |

TABLE 5

| | Composition | | | | | |
|---|---|---|---|---|---|---|
| | Resin (A) | Photoacid Generator | | Basic Compound | Hydrophobic Resin | |
| | (2 g) | (mg) | Solvent (mass ratio) | (mg) | (C) (wt %) | Surfactant (mg) |
| Example 13 | 13 | z9 (100) | SL-2/SL-4 (60/40) | — | C-22 (1.0) | W-1 (5) |
| Example 14 | 14 | z65/z9 (20/80) | SL-3/SL-4 (70/30) | N-6 (10) | C-2 (1.5) | W-5 (4) |
| Example 15 | 15 | z44/z65 (25/80) | SL-2/SL-4/SL-5 (40/58/2) | N-1 (7) | C-22 (2.0) | W-1 (4) |
| Example 16 | 16 | z55/z47 (30/60) | SL-1/SL-2 (60/40) | N-4 (13) | C-76 (1.5) | W-6 (4) |
| Example 17 | 17 | z44/z65 (50/50) | SL-1/SL-2 (60/40) | N-3 (6) | C-22 (2.0) | W-2 (3) |
| Example 18 | 18 | z65 (100) | SL-2/SL-4/SL-6 (40/59/1) | N-2 (9) | C-68 (2.0) | W-3 (3) |
| Example 19 | 19 | z15/z37 (80/50) | SL-2/SL-4/SL-6 (40/59/1) | N-6 (10) | C-22 (1.0) | W-4 (5) |
| Comparative | 1 | z2 (80) | SL-4/SL-2 (40/60) | N-5 (7) | — | W-1 (5) |
| Example 1 | | | | | | |
| Comparative | 7 | z55/z23 (100/25) | SL-2/SL-4 (60/40) | N-5/N-1 (7/7) | C-43 (2.0) | W-4 (2) |
| Example 2 | | | | | | |
| Comparative | 8 | z55/z23 (100/25) | SL-2/SL-4 (60/40) | N-5/N-1 (7/7) | C-80 (2.0) | W-4 (2) |
| Example 3 | | | | | | |
| Comparative | 11 | z55/z23 (100/25) | SL-2/SL-4 (60/40) | N-5/N-1 (7/7) | C-11 (1.0) | W-4 (2) |
| Example 4 | | | | | | |
| Comparative | 5 | z2 (80) | SL-4/SL-2 (40/60) | N-5 (7) | C-26 (1.0) | W-1 (3) |
| Example 5 | | | | | | |
| Comparative | 12 | z2/z15 (40/60) | SL-2/SL-4 (70/30) | N-3 (6) | C-7 (0.5) | W-6 (3) |
| Example 6 | | | | | | |

| | | Evaluation Results | | | | |
|---|---|---|---|---|---|---|
| | Weight Average Molecular Weight | Normal Exposure | | Immersion Exposure | | Development |
| | Difference | Profile | Collapse (nm) | Profile | Collapse (nm) | Defect |
| Example 13 | 3500 | rectangular | 60 | rectangular | 55 | A |
| Example 14 | 3300 | rectangular | 65 | rectangular | 60 | A |
| Example 15 | 7300 | rectangular | 60 | rectangular | 55 | A |
| Example 16 | 4500 | rectangular | 60 | rectangular | 50 | A |
| Example 17 | 5500 | rectangular | 50 | rectangular | 45 | A |
| Example 18 | 3200 | rectangular | 65 | rectangular | 60 | A |
| Example 19 | 5300 | rectangular | 50 | rectangular | 45 | A |
| Comparative | — | rectangular | 80 | rectangular | 100 | C |
| Example 1 | | | | | | |
| Comparative | 2000 | rectangular | 80 | rectangular | 80 | C |
| Example 2 | | | | | | |
| Comparative | 1900 | rectangular | 70 | rectangular | 70 | C |
| Example 3 | | | | | | |
| Comparative | 1800 | rectangular | 70 | rectangular | 70 | C |
| Example 4 | | | | | | |
| Comparative | 2900 | rectangular | 65 | rectangular | 55 | B |
| Example 5 | | | | | | |
| Comparative | 2200 | rectangular | 70 | rectangular | 60 | B |
| Example 6 | | | | | | |

The denotations in Tables 4 and 5 are as follows.

The acid generators correspond to those described above.
N-1: N,N-Dibutylaniline
N-2: N,N-Dihexylaniline
N-3: 2,6-Diisopropylaniline
N-4: Tri-n-octylamine
N-5: N,N-Dihydroxyethylaniline
N-6: 2,4,5-Triphenylimidazole
W-1: Megafac F176 (produced by Dainippon Ink & Chemicals, Inc.) (fluorine-containing)
W-2: Megafac R08 (produced by Dainippon Ink & Chemicals, Inc.) (fluorine- and silicon-containing)
W-3: Polysiloxane polymer KP-341 (produced by Shin-Etsu Chemical Co., Ltd.) (silicon-containing)
W-4: Troysol S-366 (produced by Troy Chemical)
W-5: PF656 (produced by OMNOVA, fluorine-containing)
W-6: PF6320 (produced by OMNOVA, fluorine-containing)
SL- 1: Cyclohexanone
SL-2: Propylene glycol monomethyl ether acetate
SL-3: Ethyl lactate
SL-4: Propylene glycol monomethyl ether
SL-5: γ-Butyrolactone
SL-6: Propylene carbonate

As seen from the results in Tables 4 and 5, the positive resist composition of the present invention exhibits good performance in terms of resist pattern collapse, profile deterioration and development defect not only in normal exposure but also in immersion exposure.

According to the present invention, a resist composition ensuring less profile deterioration, improved pattern collapse and suppressed scum generation not only in normal exposure (dry exposure) but also in immersion exposure and a pattern forming method using the resist composition can be provided.

The entire disclosure of each and every foreign patent application from which the benefit of foreign priority has been claimed in the present application is incorporated herein by reference, as if filly set forth.

What is claimed is:

1. A resist composition, comprising:
(A) a resin of which solubility in an alkali developer increases under an action of an acid;
(B) a compound capable of generating an acid upon irradiation with actinic rays or radiation;
(C) a hydrophobic resin; and
(D) a solvent,
wherein a difference between a weight average molecular weight of the resin (A) and a weight average molecular weight of the hydrophobic resin (C) satisfies the following formula:
weight average molecular weight of resin (A)−weight average molecular weight of hydrophobic resin (C)≧about 3,000.

2. The resist composition according to claim 1,
wherein the hydrophobic resin (C) has at least one of a fluorine atom and a silicon atom.

3. The resist composition according to claim 1,
wherein the difference between the weight average molecular weight of the resin (A) and the weight average molecular weight of the hydrophobic resin (C) satisfies the following formula:
weight average molecular weight of resin (A)−weight average molecular weight of hydrophobic resin (C)≧about 4,000.

4. The resist composition according to claim 1,
wherein the difference between the weight average molecular weight of the resin (A) and the weight average molecular weight of the hydrophobic resin (C) satisfies the following formula:
weight average molecular weight of resin (A)−weight average molecular weight of hydrophobic resin (C)≧about 5,000.

5. The resist composition according to claim 1,
wherein the hydrophobic resin (C) has a group represented by formula (F3a): 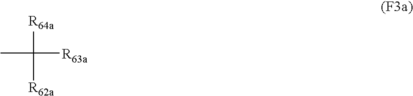
wherein R₆₂ₐ and R₆₃ₐ each independently represents an alkyl group with at least one hydrogen atom being substituted by a fluorine atom, and R₆₂ₐ and R₆₃ₐ may combine with each other to form a ring; and
R₆₄ₐ represents a hydrogen atom, a fluorine atom or an alkyl group.

6. The resist composition according to claim 5,
wherein the hydrophobic resin (C) contains a repeating unit including an acrylate or methacrylate having a group represented by formula (F3a).

7. The resist composition according to claim 1,
wherein the hydrophobic resin (C) has a group represented by any one of formulae (CS-1) to (CS-3): 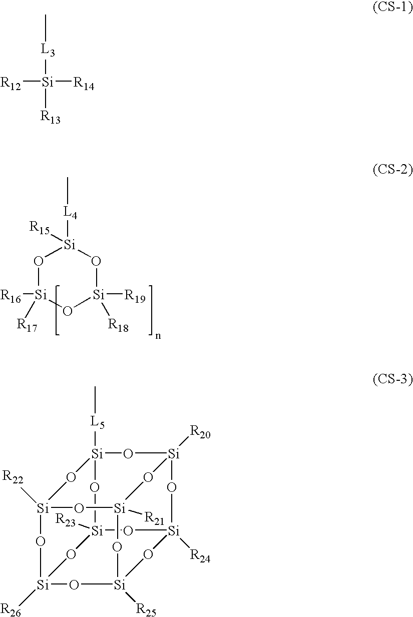
wherein R₁₂ to R₂₆ each independently represents an alkyl group or a cycloalkyl group;
L₃ to L₅ each independently represents a single bond or a divalent linking group; and
n represents an integer of 1 to 5.

8. The resist composition according to claim 1,
wherein the hydrophobic resin (C) is any one resin selected from the group consisting of the following resins (C-1) to (C-6):
(C-1) a resin containing (a) a repeating unit having a fluoroalkyl group;
(C-2) a resin containing (b) a repeating unit having a trialkylsilyl group or a cyclic siloxane structure;
(C-3) a resin containing (a) a repeating unit having a fluoroalkyl group and (c) a repeating unit having a branched alkyl group, a cycloalkyl group, a branched alkenyl group, a cycloalkenyl group or an aryl group;
(C-4) a resin containing (b) a repeating unit having a trialkylsilyl group or a cyclic siloxane structure and (c) a repeating unit having a branched alkyl group, a cycloalkyl group, a branched alkenyl group, a cycloalkenyl group or an aryl group;
(C-5) a resin containing (a) a repeating unit having a fluoroalkyl group and (b) a repeating unit having a trialkylsilyl group or a cyclic siloxane structure; and
(C-6) a resin containing (a) a repeating unit having a fluoroalkyl group, (b) a repeating unit having a trialkylsilyl group or a cyclic siloxane structure and (c) a repeating unit having a branched alkyl group, a cycloalkyl group, a branched alkenyl group, a cycloalkenyl group or an aryl group.

9. The resist composition according to claim 1,
wherein the hydrophobic resin (C) has a repeating unit represented by formula (Ia): 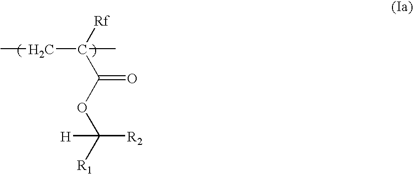
wherein Rf represents a fluorine atom or an alkyl group with at least one hydrogen atom being substituted by a fluorine atom;
R₁ represents an alkyl group; and
R₂ represents a hydrogen atom or an alkyl group.

10. The resist composition according to claim 1,
wherein the hydrophobic resin (C) has a repeating unit represented by formula (II) and a repeating unit represented by formula (III): 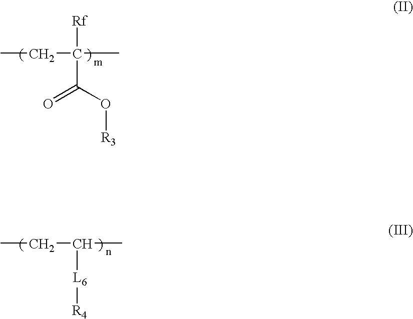
wherein Rf represents a fluorine atom or an alkyl group with at least one hydrogen atom being substituted by a fluorine atom;
R₃ represents an alkyl group, a cycloalkyl group, an alkenyl group or a cycloalkenyl group;
R₄ represents an alkyl group, a cycloalkyl group, an alkenyl group, a cycloalkenyl group, a trialkylsilyl group or a group having a cyclic siloxane structure;
L₆ represents a single bond or a divalent linking group; and
m and n define ratio of repeating units and represent numerals of 0<m<100 and 0<n<100.

11. A pattern forming method, comprising:
forming a resist film from the resist composition according to claim 1; and
exposing and developing the resist film.
